(19) United States
(12) Patent Application Publication
(10) Pub. No.: US 2025/0275130 A1
(43) Pub. Date: Aug. 28, 2025

(54) SEMICONDUCTOR MEMORY DEVICE

(71) Applicant: Kioxia Corporation, Tokyo (JP)

(72) Inventors: Nobuyoshi SAITO, Ota Tokyo (JP); Takafumi MASUDA, Kawasaki Kanagawa (JP); Mutsumi OKAJIMA, Yokkaichi Mie (JP); Keiji IKEDA, Kawasaki Kanagawa (JP); Masaharu WADA, Yokohama Kanagawa (JP)

(73) Assignee: Kioxia Corporation, Tokyo (JP)

(21) Appl. No.: 18/828,920

(22) Filed: Sep. 9, 2024

(30) Foreign Application Priority Data
Feb. 26, 2024 (JP) 2024-026937

(51) Int. Cl. H10B 41/70; H10B 41/20; H10B 41/35

(52) U.S. Cl. CPC H10B 41/70; H10B 41/20; H10B 41/35

(57) ABSTRACT

A semiconductor memory device includes: first wirings arranged in a first direction and extending in a second direction; second wirings arranged in the first direction, extending in the second direction, and arranged with the first wirings in a third direction; a first via-wiring and a second via-wiring disposed between the first wirings and the second wirings and extending in the first direction; first semiconductor layers arranged in the first direction and electrically connected to the first via-wiring; second semiconductor layers arranged in the first direction, electrically connected to the second via-wiring, and electrically connected to the second wirings; first gate electrodes arranged in the first direction, electrically connected to the first wirings, and opposed to the semiconductor layers; and second gate electrodes arranged in the first direction, electrically connected to the first semiconductor layers, and opposed to the second semiconductor layers.

### CROSS-REFERENCE TO RELATED APPLICATIONS

This application is based upon and claims the benefit of Japanese Patent Application No. 2024-026937, filed on Feb. 26, 2024, the entire contents of which are incorporated herein by reference.

### BACKGROUND

### Field

Embodiments described herein relate generally to a semiconductor memory device.

### Description of the Related Art

In accordance with an increasing high integration of a semiconductor memory device, an examination for converting the semiconductor memory device into a three-dimensional form has been in progress.

### BRIEF DESCRIPTION OF THE DRAWINGS

FIG. 1 is a schematic circuit diagram illustrating a configuration of a part of a semiconductor memory device according to a first embodiment;

FIG. 2 is a schematic perspective view illustrating a configuration of a part of the semiconductor memory device;

FIG. 3 is a schematic XY cross-sectional view illustrating a configuration of a part of the semiconductor memory device;

FIG. 4 is a schematic cross-sectional view illustrating a configuration of a part of the semiconductor memory device;

FIG. 5 is a schematic cross-sectional view for describing a method for manufacturing the semiconductor memory device;

FIG. 6 is a schematic cross-sectional view for describing the manufacturing method;

FIG. 7 is a schematic cross-sectional view for describing the manufacturing method;

FIG. 8 is a schematic cross-sectional view for describing the manufacturing method;

FIG. 9 is a schematic cross-sectional view for describing the manufacturing method;

FIG. 10 is a schematic cross-sectional view for describing the manufacturing method;

FIG. 11 is a schematic cross-sectional view for describing the manufacturing method;

FIG. 12 is a schematic cross-sectional view for describing the manufacturing method;

FIG. 13 is a schematic cross-sectional view for describing the manufacturing method;

FIG. 14 is a schematic cross-sectional view for describing the manufacturing method;

FIG. 15 is a schematic cross-sectional view for describing the manufacturing method;

FIG. 16 is a schematic cross-sectional view for describing the manufacturing method;

FIG. 17 is a schematic cross-sectional view for describing the manufacturing method;

FIG. 18 is a schematic cross-sectional view for describing the manufacturing method;

FIG. 19 is a schematic cross-sectional view for describing the manufacturing method;

FIG. 20 is a schematic cross-sectional view for describing the manufacturing method;

FIG. 21 is a schematic cross-sectional view for describing the manufacturing method;

FIG. 22 is a schematic cross-sectional view for describing the manufacturing method;

FIG. 23 is a schematic cross-sectional view for describing the manufacturing method;

FIG. 24 is a schematic cross-sectional view for describing the manufacturing method;

FIG. 25 is a schematic cross-sectional view for describing the manufacturing method;

FIG. 26 is a schematic cross-sectional view for describing the manufacturing method;

FIG. 27 is a schematic cross-sectional view for describing the manufacturing method;

FIG. 28 is a schematic cross-sectional view for describing the manufacturing method;

FIG. 29 is a schematic cross-sectional view for describing the manufacturing method;

FIG. 30 is a schematic cross-sectional view for describing the manufacturing method;

FIG. 31 is a schematic cross-sectional view for describing the manufacturing method;

FIG. 32 is a schematic cross-sectional view for describing the manufacturing method;

FIG. 33 is a schematic cross-sectional view for describing the manufacturing method;

FIG. 34 is a schematic cross-sectional view for describing the manufacturing method;

FIG. 35 is a schematic cross-sectional view for describing the manufacturing method;

FIG. 36 is a schematic cross-sectional view for describing the manufacturing method;

FIG. 37 is a schematic cross-sectional view for describing the manufacturing method;

FIG. 38 is a schematic cross-sectional view for describing the manufacturing method;

FIG. 39 is a schematic cross-sectional view for describing the manufacturing method;

FIG. 40 is a schematic cross-sectional view for describing the manufacturing method;

FIG. 41 is a schematic cross-sectional view for describing the manufacturing method;

FIG. 42 is a schematic cross-sectional view for describing the manufacturing method;

FIG. 43 is a schematic cross-sectional view for describing the manufacturing method;

FIG. 44 is a schematic cross-sectional view for describing the manufacturing method;

FIG. 45 is a schematic cross-sectional view for describing the manufacturing method;

FIG. 46 is a schematic cross-sectional view for describing the manufacturing method;

FIG. 47 is a schematic XY cross-sectional view illustrating a configuration of a part of a semiconductor memory device according to a second embodiment;

FIG. 48 is a schematic cross-sectional view illustrating a configuration of a part of the semiconductor memory device;

FIG. 49 is a schematic cross-sectional view for describing a method for manufacturing the semiconductor memory device;

FIG. 50 is a schematic cross-sectional view for describing the manufacturing method;

FIG. 51 is a schematic cross-sectional view for describing the manufacturing method;

FIG. 52 is a schematic cross-sectional view for describing the manufacturing method;

FIG. 53 is a schematic cross-sectional view for describing the manufacturing method;

FIG. 54 is a schematic cross-sectional view for describing the manufacturing method;

FIG. 55 is a schematic cross-sectional view for describing the manufacturing method;

FIG. 56 is a schematic cross-sectional view for describing the manufacturing method;

FIG. 57 is a schematic cross-sectional view for describing the manufacturing method;

FIG. 58 is a schematic cross-sectional view for describing the manufacturing method;

FIG. 59 is a schematic cross-sectional view for describing the manufacturing method;

FIG. 60 is a schematic cross-sectional view for describing the manufacturing method;

FIG. 61 is a schematic cross-sectional view for describing the manufacturing method;

FIG. 62 is a schematic cross-sectional view for describing the manufacturing method;

FIG. 63 is a schematic cross-sectional view for describing the manufacturing method;

FIG. 64 is a schematic cross-sectional view for describing the manufacturing method;

FIG. 65 is a schematic cross-sectional view for describing the manufacturing method;

FIG. 66 is a schematic cross-sectional view for describing the manufacturing method;

FIG. 67 is a schematic cross-sectional view for describing the manufacturing method;

FIG. 68 is a schematic cross-sectional view for describing the manufacturing method;

FIG. 69 is a schematic cross-sectional view for describing the manufacturing method;

FIG. 70 is a schematic cross-sectional view for describing the manufacturing method;

FIG. 71 is a schematic cross-sectional view for describing the manufacturing method;

FIG. 72 is a schematic cross-sectional view for describing the manufacturing method;

FIG. 73 is a schematic cross-sectional view for describing the manufacturing method;

FIG. 74 is a schematic cross-sectional view for describing the manufacturing method;

FIG. 75 is a schematic cross-sectional view for describing the manufacturing method;

FIG. 76 is a schematic cross-sectional view for describing the manufacturing method;

FIG. 77 is a schematic cross-sectional view for describing the manufacturing method;

FIG. 78 is a schematic cross-sectional view for describing the manufacturing method;

FIG. 79 is a schematic cross-sectional view for describing the manufacturing method;

FIG. 80 is a schematic cross-sectional view for describing the manufacturing method;

FIG. 81 is a schematic cross-sectional view for describing the manufacturing method;

FIG. 82 is a schematic cross-sectional view for describing the manufacturing method;

FIG. 83 is a schematic cross-sectional view for describing the manufacturing method;

FIG. 84 is a schematic cross-sectional view for describing the manufacturing method;

FIG. 85 is a schematic cross-sectional view for describing the manufacturing method;

FIG. 86 is a schematic cross-sectional view for describing the manufacturing method;

FIG. 87 is a schematic circuit diagram illustrating a configuration of a part of the semiconductor memory device according to the first embodiment;

FIG. 88 is a schematic circuit diagram illustrating a configuration of a part of a semiconductor memory device according to a third embodiment;

FIG. 89 is a schematic XY cross-sectional view illustrating a configuration of a part of the semiconductor memory device;

FIG. 90 is a schematic cross-sectional view illustrating a configuration of a part of the semiconductor memory device;

FIG. 91 is a schematic XY cross-sectional view illustrating a configuration of a part of a semiconductor memory device according to a fourth embodiment;

FIG. 92 is a schematic cross-sectional view illustrating a configuration of a part of the semiconductor memory device;

FIG. 93 is a schematic cross-sectional view for describing a method for manufacturing the semiconductor memory device;

FIG. 94 is a schematic cross-sectional view for describing the manufacturing method;

FIG. 95 is a schematic cross-sectional view for describing the manufacturing method;

FIG. 96 is a schematic cross-sectional view for describing the manufacturing method;

FIG. 97 is a schematic cross-sectional view for describing the manufacturing method;

FIG. 98 is a schematic cross-sectional view for describing the manufacturing method;

FIG. 99 is a schematic cross-sectional view for describing the manufacturing method;

FIG. 100 is a schematic cross-sectional view for describing the manufacturing method;

FIG. 101 is a schematic cross-sectional view for describing the manufacturing method;

FIG. 102 is a schematic cross-sectional view for describing the manufacturing method;

FIG. 103 is a schematic cross-sectional view for describing the manufacturing method;

FIG. 104 is a schematic circuit diagram illustrating a configuration of a part of a semiconductor memory device according to a fifth embodiment;

FIG. 105 is a schematic XY cross-sectional view illustrating a configuration of a part of the semiconductor memory device;

FIG. 106 is a schematic cross-sectional view illustrating a configuration of a part of the semiconductor memory device;

FIG. 107 is a schematic cross-sectional view for describing a method for manufacturing the semiconductor memory device;

FIG. 108 is a schematic cross-sectional view for describing the manufacturing method;

FIG. 109 is a schematic cross-sectional view for describing the manufacturing method;

FIG. 110 is a schematic cross-sectional view for describing the manufacturing method;

FIG. 111 is a schematic cross-sectional view for describing the manufacturing method;

FIG. 112 is a schematic cross-sectional view for describing the manufacturing method;

FIG. 113 is a schematic cross-sectional view for describing the manufacturing method;

FIG. 114 is a schematic cross-sectional view for describing the manufacturing method;

FIG. 115 is a schematic cross-sectional view for describing the manufacturing method;

FIG. 116 is a schematic cross-sectional view for describing the manufacturing method;

FIG. 117 is a schematic cross-sectional view for describing the manufacturing method;

FIG. 118 is a schematic cross-sectional view for describing the manufacturing method;

FIG. 119 is a schematic cross-sectional view for describing the manufacturing method;

FIG. 120 is a schematic cross-sectional view for describing the manufacturing method;

FIG. 121 is a schematic cross-sectional view for describing the manufacturing method;

FIG. 122 is a schematic cross-sectional view for describing the manufacturing method;

FIG. 123 is a schematic cross-sectional view for describing the manufacturing method;

FIG. 124 is a schematic cross-sectional view for describing the manufacturing method;

FIG. 125 is a schematic cross-sectional view for describing the manufacturing method;

FIG. 126 is a schematic cross-sectional view for describing the manufacturing method;

FIG. 127 is a schematic cross-sectional view for describing the manufacturing method;

FIG. 128 is a schematic cross-sectional view for describing the manufacturing method;

FIG. 129 is a schematic cross-sectional view for describing the manufacturing method;

FIG. 130 is a schematic cross-sectional view for describing the manufacturing method;

FIG. 131 is a schematic cross-sectional view for describing the manufacturing method;

FIG. 132 is a schematic circuit diagram illustrating a configuration of a part of a semiconductor memory device according to a sixth embodiment;

FIG. 133 is a schematic XY cross-sectional view illustrating a configuration of a part of the semiconductor memory device;

FIG. 134 is a schematic cross-sectional view illustrating a configuration of a part of the semiconductor memory device;

FIG. 135 is a schematic cross-sectional view for describing a method for manufacturing the semiconductor memory device;

FIG. 136 is a schematic cross-sectional view for describing the manufacturing method;

FIG. 137 is a schematic cross-sectional view for describing the manufacturing method;

FIG. 138 is a schematic cross-sectional view for describing the manufacturing method;

FIG. 139 is a schematic cross-sectional view for describing the manufacturing method;

FIG. 140 is a schematic cross-sectional view for describing the manufacturing method;

FIG. 141 is a schematic cross-sectional view for describing the manufacturing method;

FIG. 142 is a schematic cross-sectional view for describing the manufacturing method;

FIG. 143 is a schematic cross-sectional view for describing the manufacturing method;

FIG. 144 is a schematic cross-sectional view for describing the manufacturing method;

FIG. 145 is a schematic cross-sectional view for describing the manufacturing method;

FIG. 146 is a schematic cross-sectional view for describing the manufacturing method;

FIG. 147 is a schematic cross-sectional view for describing the manufacturing method;

FIG. 148 is a schematic cross-sectional view for describing the manufacturing method;

FIG. 149 is a schematic cross-sectional view for describing the manufacturing method;

FIG. 150 is a schematic cross-sectional view for describing the manufacturing method;

FIG. 151 is a schematic cross-sectional view for describing the manufacturing method;

FIG. 152 is a schematic cross-sectional view for describing the manufacturing method;

FIG. 153 is a schematic circuit diagram illustrating a configuration of a part of a semiconductor memory device according to a seventh embodiment;

FIG. 154 is a schematic cross-sectional view illustrating a configuration of a part of the semiconductor memory device; and

FIG. 155 is a schematic cross-sectional view illustrating a configuration of a part of the semiconductor memory device.

### DETAILED DESCRIPTION

A semiconductor memory device according to one embodiment comprises: a substrate; a plurality of first wirings arranged in a first direction intersecting with a surface of the substrate and extending in a second direction intersecting with the first direction; a plurality of second wirings arranged in the first direction, extending in the second direction, and arranged with the plurality of first wirings in a third direction intersecting with the first direction and the second direction; a first via-wiring and a second via-wiring disposed between the plurality of first wirings and the plurality of second wirings and extending in the first direction; a plurality of first semiconductor layers arranged in the first direction and electrically connected to the first via-wiring; a plurality of second semiconductor layers arranged in the first direction, electrically connected to the second via-wiring, and electrically connected to the plurality of second wirings respectively; a plurality of first gate electrodes arranged in the first direction, electrically connected to the plurality of first wirings respectively, and opposed to the plurality of first semiconductor layers; and a plurality of second gate electrodes arranged in the first direction, electrically connected to the plurality of first semiconductor layers respectively, and opposed to the plurality of second semiconductor layers.

Next, the semiconductor memory devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when referring to a “semiconductor memory device”, it may mean a memory die and may mean a memory system including a controller die, such as a memory chip, a memory card, and a Solid State Drive (SSD). Further, it may mean a configuration including a host computer, such as a smartphone, a tablet terminal, and a personal computer.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, when it is referred that the first configuration “is electrically connected between” the second configuration and a third configuration, it may mean that the first configuration, the second configuration, and the third configuration are connected in series and the second configuration is electrically connected to the third configuration via the first configuration.

In this specification, when it is referred that a circuit or the like “electrically conducts” two wirings or the like, it may mean, for example, that this circuit or the like includes a transistor or the like, this transistor or the like is disposed in a current path between the two wirings, and this transistor or the like is turned ON.

In this specification, a direction parallel to an upper surface of the substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, a direction along a predetermined plane may be referred to as a first direction, a direction along this predetermined plane and intersecting with the first direction may be referred to as a second direction, and a direction intersecting with this predetermined plane may be referred to as a third direction. These first direction, second direction, and third direction may each correspond to any of the X-direction, the Y-direction, and the Z-direction and need not correspond to these directions.

Expressions such as “above” and “below” in this specification are based on the substrate. For example, a direction away from the substrate along the Z-direction is referred to as above and a direction approaching the substrate along the Z-direction is referred to as below. A lower surface and a lower end of a certain configuration mean a surface and an end portion at the substrate side of this configuration. An upper surface and an upper end of a certain configuration mean a surface and an end portion on a side opposite to the substrate of this configuration. A surface intersecting with the X-direction or the Y-direction is referred to as a side surface and the like.

In this specification, a “center position” of a certain configuration may mean, for example, a position of the center of a circumscribed circle of this configuration, and may mean the centroid on an image of this configuration.

In this specification, when referring to a “semiconductor layer” and a “semiconductor portion”, the “semiconductor portion” may be a part of the “semiconductor layer”, or may be the whole “semiconductor layer”. The “semiconductor layer” may be configured of one “semiconductor portion”, or may include a plurality of “semiconductor portions”.

### First Embodiment

### [Circuit Configuration]

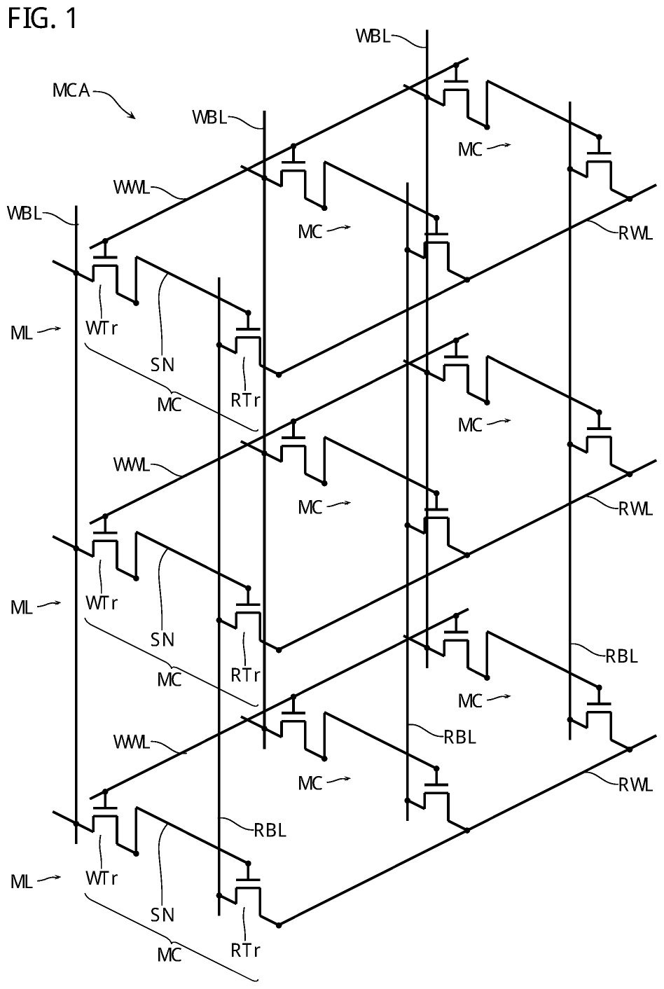

FIG. 1 is a schematic circuit diagram illustrating a configuration of a part of a semiconductor memory device according to the first embodiment. As illustrated in FIG. 1, the semiconductor memory device according to the embodiment includes a memory cell array MCA. The memory cell array MCA includes a plurality of memory layers ML, a plurality of write bit lines WBL connected to these plurality of memory layers ML, and a plurality of read bit lines RBL connected to the plurality of memory layers ML.

Each of the memory layers ML includes a write word line WWL, a read word line RWL, and a plurality of memory cells MC connected to these write word line WWL and read word line RWL. Each of the memory cells MC includes a write transistor WTr, a sense node SN, and a read transistor RTr.

The write transistor WTr is, for example, a field-effect type NMOS transistor. The write transistor WTr has one electrode connected to the write bit line WBL. The write transistor WTr has the other electrode connected to the sense node SN. The one and the other electrodes of the write transistor WTr function as a source electrode or a drain electrode corresponding to a voltage applied to the write transistor WTr. The write transistor WTr has a gate electrode connected to the write word line WWL.

The read transistor RTr is, for example, a field-effect type NMOS transistor. The read transistor RTr has one electrode connected to the read bit line RBL. The read transistor RTr has the other electrode connected to the read word line RWL. The one and the other electrodes of the read transistor RTr function as a source electrode or a drain electrode corresponding to a voltage applied to the read transistor RTr. The read transistor RTr has a gate electrode connected to the sense node SN.

In a write operation, for example, a power supply voltage Vdd is applied to a write word line WWL that is a target of the write operation and a ground voltage Vss is applied to the other write word lines WWL among the plurality of write word lines WWL. Further, the power supply voltage Vdd or the ground voltage Vss is applied to a write bit line WBL that is a target of the write operation among the plurality of write bit lines WBL corresponding to data to be written.

In the write operation, all the write bit lines WBL in the memory cell array MCA may be the target of the write operation, or a part (for example, one) of the write bit lines WBL may be the target of the write operation. In the latter case, the write bit lines WBL that are not the target of the write operation among the plurality of write bit lines WBL may be, for example, in a floating state.

In a read operation, for example, a power supply voltage Vdd is applied to a read word line RWL that is a target of the read operation and a ground voltage Vss is applied to the other read word lines RWL among the plurality of read word lines RWL. Further, the ground voltage Vss is applied to a read bit line RBL that is a target of the read operation among the plurality of read bit lines RBL, or such a read bit line is set in a floating state. Here, when the sense node SN of the memory cell MC as the target of the read operation (hereinafter referred to as a “selected memory cell MC” in some cases) is charged with the power supply voltage Vdd, the read transistor RTr turns ON, and a current flows through the read bit line RBL, or the read bit line RBL is charged. On the other hand, when the sense node SN of the selected memory cell MC is discharged to the ground voltage Vss, the read transistor RTr turns OFF, and the current does not flow through the read bit line RBL, or the read bit line RBL is not charged.

In the read operation, all the read bit lines RBL in the memory cell array MCA may be the target of the read operation, or a part (for example, one) of the read bit lines RBL may be the target of the read operation. In the latter case, for example, the power supply voltage Vdd may be applied to the read bit lines RBL that are not the target of the read operation among the plurality of read bit lines RBL.

### [Structure]

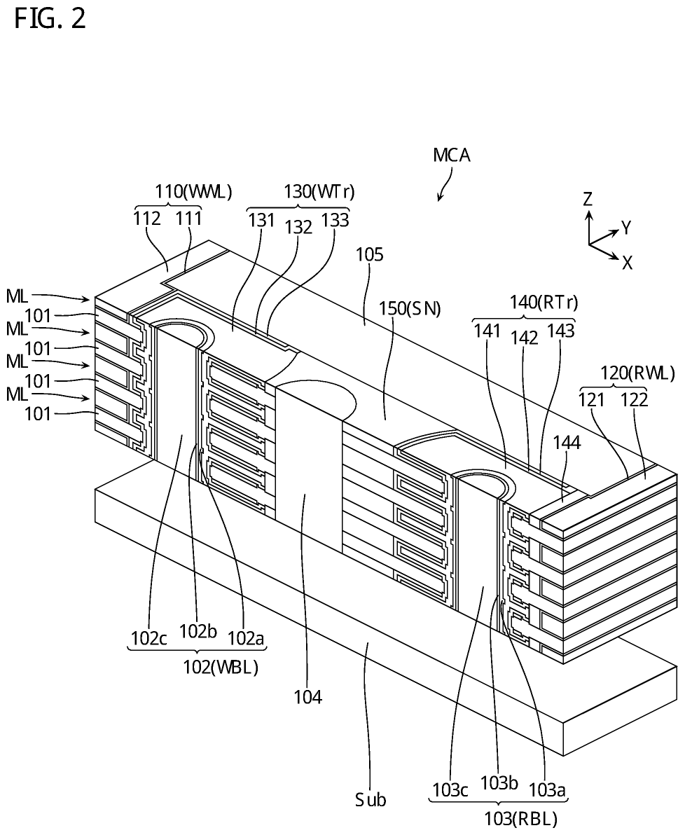

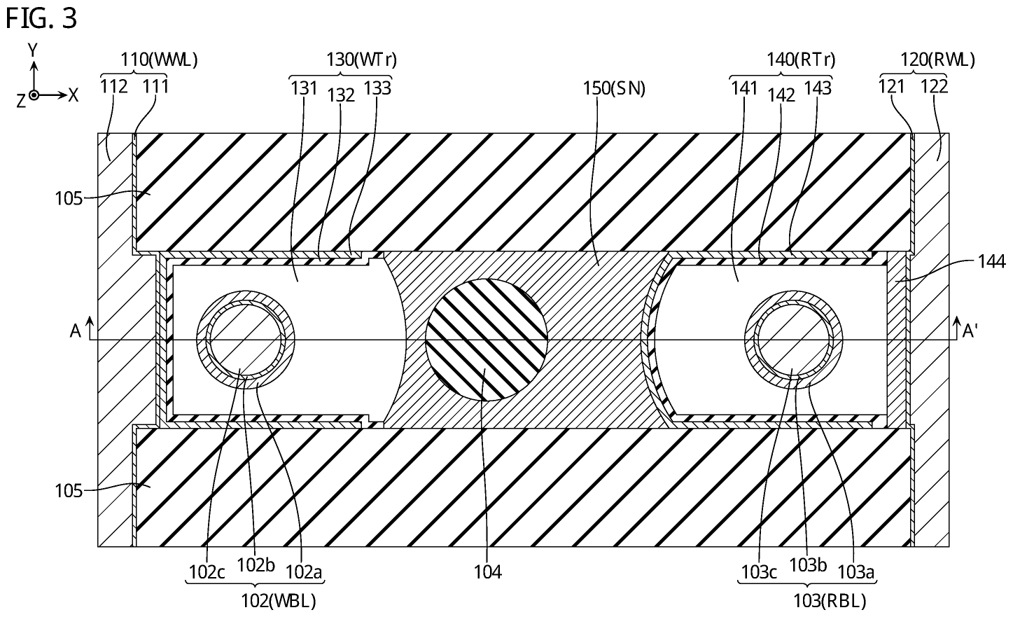

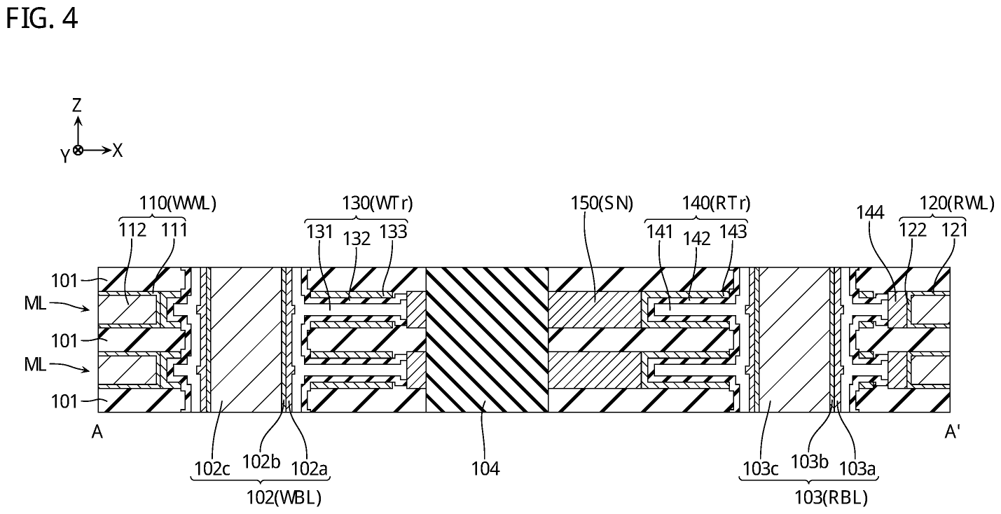

FIG. 2 is a schematic perspective view illustrating a configuration of a part of the semiconductor memory device according to the first embodiment. FIG. 3 is a schematic XY cross-sectional view illustrating a configuration of a part of the semiconductor memory device. FIG. 4 is a schematic cross-sectional view illustrating a configuration of a part of the semiconductor memory device, and illustrates a configuration of the structure illustrated in FIG. 3 taken along the line A-A′ when viewed in the arrow direction.

FIG. 2 illustrates a part of a semiconductor substrate Sub and a memory cell array MCA disposed above the semiconductor substrate Sub.

The semiconductor substrate Sub is, for example, a semiconductor substrate of silicon (Si) or the like containing P-type impurities, such as boron (B). On an upper surface of the semiconductor substrate Sub, an insulating layer and an electrode layer (not illustrated in FIG. 2) are provided. The upper surface of the semiconductor substrate Sub, and the insulating layer and electrode layer (not illustrated in FIG. 2) constitute a control circuit for controlling the semiconductor memory device. For example, in a region immediately below the memory cell array MCA, a sense amplifier circuit is disposed. The sense amplifier circuit is electrically connected to the read bit line RBL. The sense amplifier circuit can read data stored in the selected memory cell MC by detecting a voltage variation or a current of the read bit line RBL in the read operation.

The memory cell array MCA includes a plurality of memory layers ML arranged in the Z-direction. Insulating layers 101 of silicon oxide (SiO₂) or the like are each disposed between the plurality of memory layers ML.

The memory cell array MCA includes via-wirings 102, 103. The via-wiring 102 functions as the write bit line WBL. The via-wiring 103 functions as the read bit line RBL. The via-wirings 102, 103 are arranged in the X-direction, and penetrate the plurality of memory layers ML to extend in the Z-direction.

The via-wiring 102 includes, for example, a conductive oxide film 102a containing a conductive oxide, a barrier conductive film 102b of titanium nitride (TiN) or the like, and a conductive member 102c of tungsten (W) or the like. The via-wiring 102 may contain ruthenium (Ru), iridium (Ir), or another metal instead of the conductive oxide film 102a. The via-wiring 102 may contain only the conductive oxide, or may contain only ruthenium (Ru), iridium (Ir), or another metal.

In this specification, the “conductive oxide” contains, for example, indium tin oxide (ITO), indium zinc oxide (IZO), ruthenium oxide (RuOz), iridium oxide (Iroz), or another conductive material containing oxygen.

The via-wiring 103 includes, for example, a conductive oxide film 103a containing a conductive oxide, a barrier conductive film 103b of titanium nitride (TiN) or the like, and a conductive member 103c of tungsten (W) or the like. The via-wiring 103 may contain ruthenium (Ru), iridium (Ir), or another metal instead of the conductive oxide film 103a. The via-wiring 103 may contain only the conductive oxide, or may contain only ruthenium (Ru), iridium (Ir), or another metal.

Each of the conductive members 102c, 103c has an approximately columnar shape extending in the Z-direction. The barrier conductive films 102b, 103b have approximately cylindrical shapes extending in the Z-direction along outer peripheral surfaces of the conductive members 102c, 103c. The conductive oxide films 102a, 103a have approximately cylindrical shapes extending in the Z-direction along outer peripheral surfaces of the barrier conductive films 102b, 103b.

The memory cell array MCA includes an insulating member 104 of silicon oxide (SiO₂) or the like. The insulating member 104 is disposed between the via-wirings 102, 103, and penetrates the plurality of memory layers ML to extend in the Z-direction.

The memory cell array MCA includes an insulating layer 105 of silicon oxide (SiO₂) or the like. The insulating layer 105 penetrates the plurality of memory layers ML to extend in the Z-direction. The insulating layers 105 are arranged in the Y-direction, extend in the X-direction, and electrically separate the plurality of memory cells MC arranged in the Y-direction.

The memory layer ML includes wirings 110, 120 arranged in the X-direction and extending in the Y-direction, transistor structures 130, 140 disposed between these wirings 110, 120, and a conductive member 150 disposed between these transistor structures 130, 140. The transistor structures 130, 140 are provided at positions corresponding to the via-wirings 102, 103, respectively. The conductive member 150 is provided at a position corresponding to the insulating member 104. In the example of the drawing, the transistor structures 130, 140 and the conductive member 150 are arranged in the X-direction.

The wiring 110 functions as, for example, the write word line WWL (FIG. 1). The wiring 110 includes, for example, a barrier conductive film 111 of titanium nitride (TIN) or the like and a conductive film 112 of tungsten (W).

The wiring 120 functions as, for example, the read word line RWL (FIG. 1). The wiring 120 includes, for example, a barrier conductive film 121 of titanium nitride (TiN) or the like and a conductive film 122 of tungsten (W).

The transistor structure 130 includes a semiconductor layer 131 connected to an outer peripheral surface of the via-wiring 102 and extending in the X-direction, an insulating layer 132 disposed on an upper surface, a lower surface, both side surfaces in the Y-direction, and a side surface on one side (wiring 110 side) in the X-direction of the semiconductor layer 131, and a conductive layer 133 disposed on an upper surface, a lower surface, both side surfaces in the Y-direction, and a side surface on one side (wiring 110 side) in the X-direction of the insulating layer 132.

In an XY cross-sectional surface as exemplified in FIG. 3, a side surface of the semiconductor layer 131 on one side (wiring 120 side) in the X-direction may be formed along a circle with a center position of the via-wiring 102 as its center. Additionally, side surfaces of the semiconductor layer 131, the insulating layer 132, and the conductive layer 133 on the other side (wiring 110 side) in the X-direction may be formed in a straight line along a side surface of the wiring 110. Both side surfaces of the semiconductor layer 131, the insulating layer 132, and the conductive layer 133 in the Y-direction may be formed in a straight line along a side surface of the insulating layer 105.

The semiconductor layer 131 functions as, for example, a channel region of the write transistor WTr (FIG. 1). The semiconductor layer 131, for example, may be a semiconductor containing at least one element of gallium (Ga) or aluminum (Al), and containing indium (In), zinc (Zn), and oxygen (O) or may be other oxide semiconductors. The plurality of semiconductor layers 131 arranged in the Z-direction are connected to the via-wiring 102 extending in the Z-direction in common. The side surface of the semiconductor layer 131 on one side (wiring 120 side) in the X-direction is connected to the conductive member 150.

The insulating layer 132 functions as, for example, a gate insulating film of the write transistor WTr (FIG. 1). The insulating layer 132 contains, for example, silicon oxide (SiO₂).

The conductive layer 133 functions as, for example, a gate electrode of the write transistor WTr (FIG. 1). The conductive layer 133 contains, for example, a conductive material, such as titanium nitride (TiN), or a conductive oxide, such as indium tin oxide (ITO). The conductive layer 133 is opposed to the upper surface, the lower surface, both side surfaces in the Y-direction, and the side surface on one side (wiring 110 side) in the X-direction of the semiconductor layer 131 via the insulating layer 132. A side surface of the conductive layer 133 on one side (wiring 110 side) in the X-direction is connected to the wiring 110.

The transistor structure 140 includes a semiconductor layer 141 connected to an outer peripheral surface of the via-wiring 103 and extending in the X-direction, an insulating layer 142 disposed on an upper surface, a lower surface, both side surfaces in the Y-direction, and a side surface on one side (wiring 110 side) in the X-direction of the semiconductor layer 141, and a conductive layer 143 disposed on an upper surface, a lower surface, both side surfaces in the Y-direction, and a side surface on one side (wiring 110 side) in the X-direction of the insulating layer 142.

In an XY cross-sectional surface as exemplified in FIG. 3, side surfaces of the semiconductor layer 141, the insulating layer 142, and the conductive layer 143 on one side (wiring 110 side) in the X-direction may be formed along a circle with a center position of the via-wiring 103 as its center. Additionally, a side surface of the semiconductor layer 141 on the other side (wiring 120 side) in the X-direction may be formed in a straight line along a side surface of the wiring 120. Both side surfaces of the semiconductor layer 141, the insulating layer 142, and the conductive layer 143 in the Y-direction may be formed in a straight line along a side surface of the insulating layer 105.

The semiconductor layer 141 functions as, for example, a channel region of the read transistor RTr (FIG. 1). The semiconductor layer 141, for example, may be a semiconductor containing at least one element of gallium (Ga) or aluminum (Al), and containing indium (In), zinc (Zn), and oxygen (O) or may be other oxide semiconductors. The plurality of semiconductor layers 141 arranged in the Z-direction are connected to the via-wiring 103 extending in the Z-direction in common. A side surface of the conductive layer 143 on one side (wiring 110 side) in the X-direction is connected to the conductive member 150. In the example of the drawing, a side surface of the semiconductor layer 141 on the other side (wiring 120 side) in the X-direction is connected to the wiring 120 via a conductive oxide layer 144 of indium tin oxide (ITO) or the like.

The insulating layer 142 functions as, for example, a gate insulating film of the read transistor RTr (FIG. 1). The insulating layer 142 contains, for example, silicon oxide (SiO₂).

The conductive layer 143 functions as, for example, a gate electrode of the read transistor RTr (FIG. 1). The conductive layer 143 contains, for example, a conductive material, such as titanium nitride (TiN), or a conductive oxide, such as indium tin oxide (ITO). The conductive layer 143 is opposed to the upper surface, the lower surface, both side surfaces in the Y-direction, and the side surface on one side (wiring 110 side) in the X-direction of the semiconductor layer 141 via the insulating layer 142.

The conductive member 150 functions as, for example, the sense node SN (FIG. 1). The conductive member 150 contains, for example, a conductive oxide. However, the conductive member 150 may contain ruthenium (Ru), iridium (Ir), or another metal. A plurality of the conductive members 150 arranged in the Z-direction are connected to the insulating member 104 extending in the Z-direction in common.

### [Manufacturing Method]

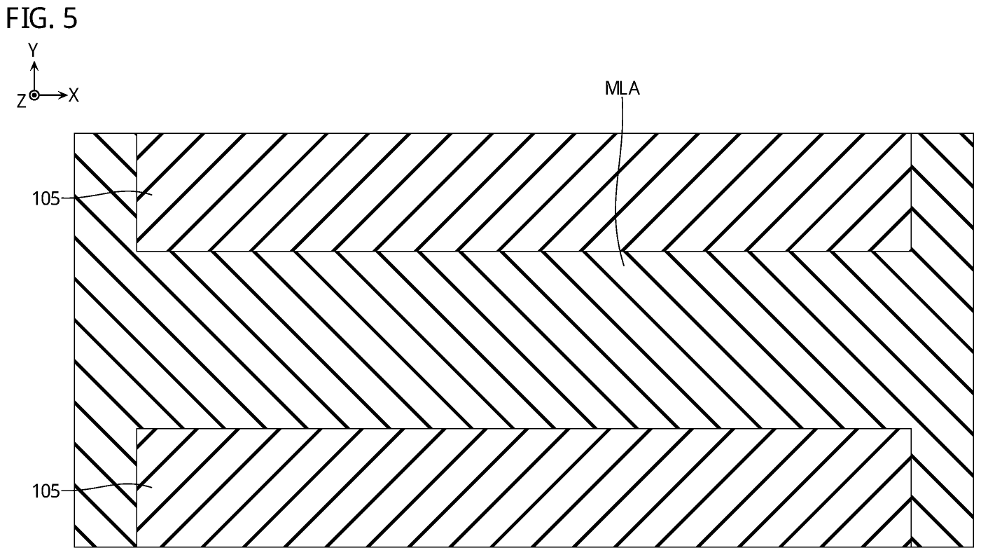

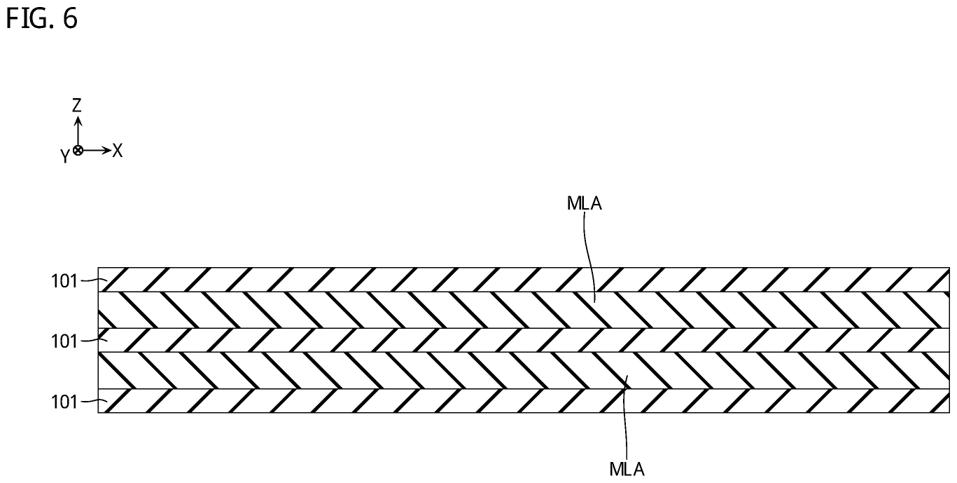

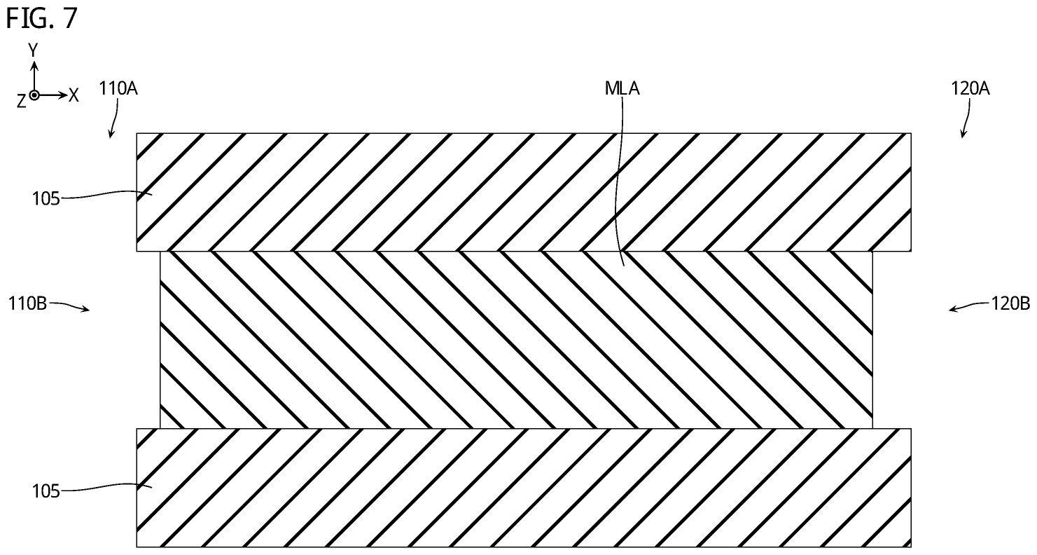

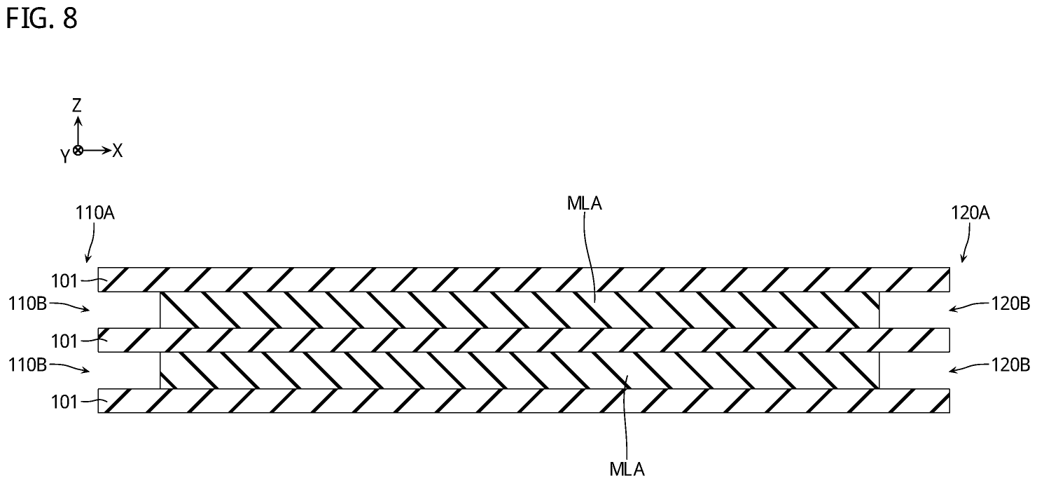

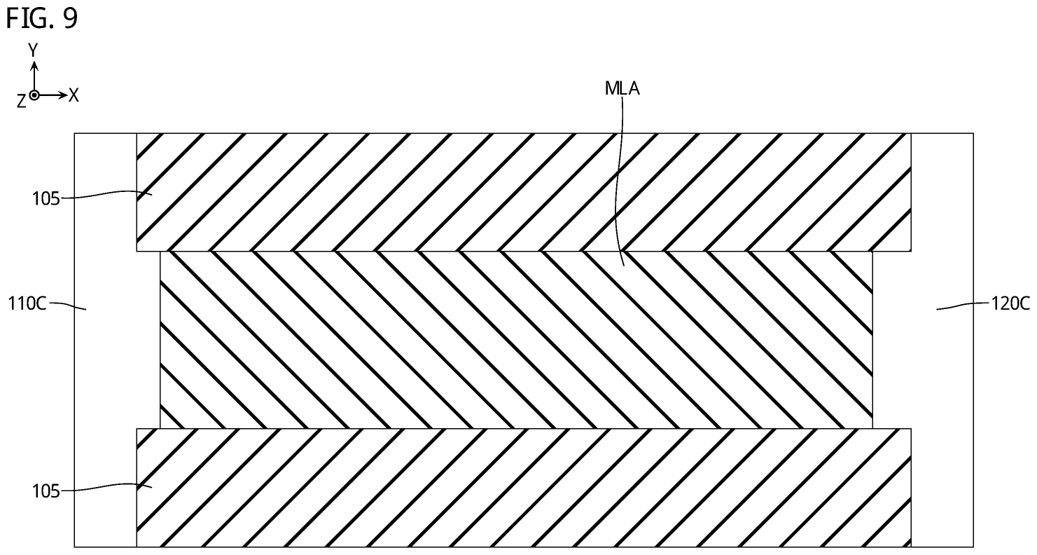

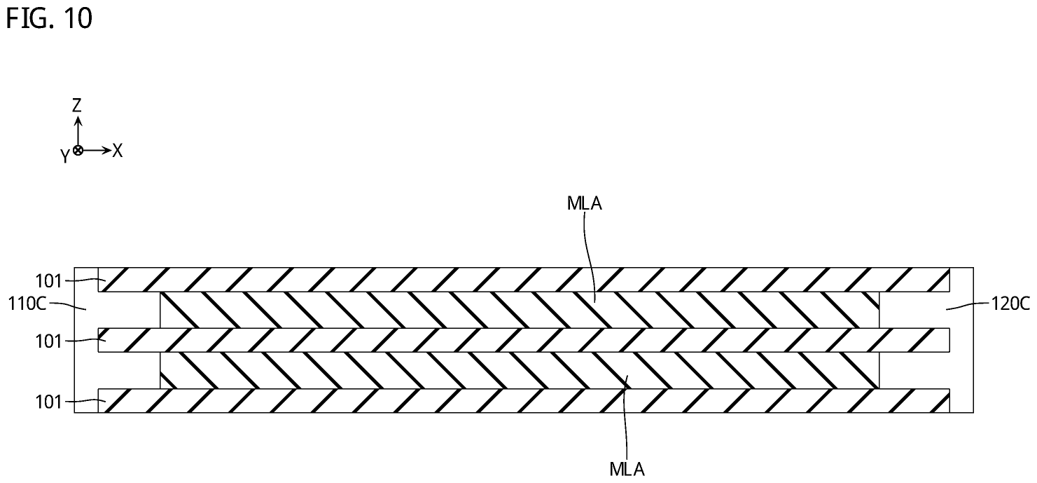

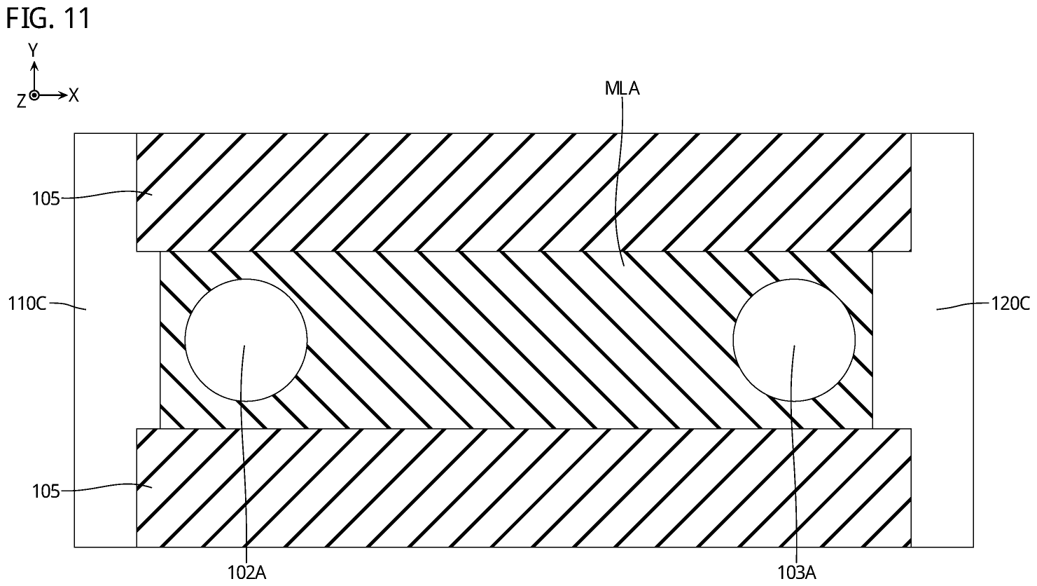

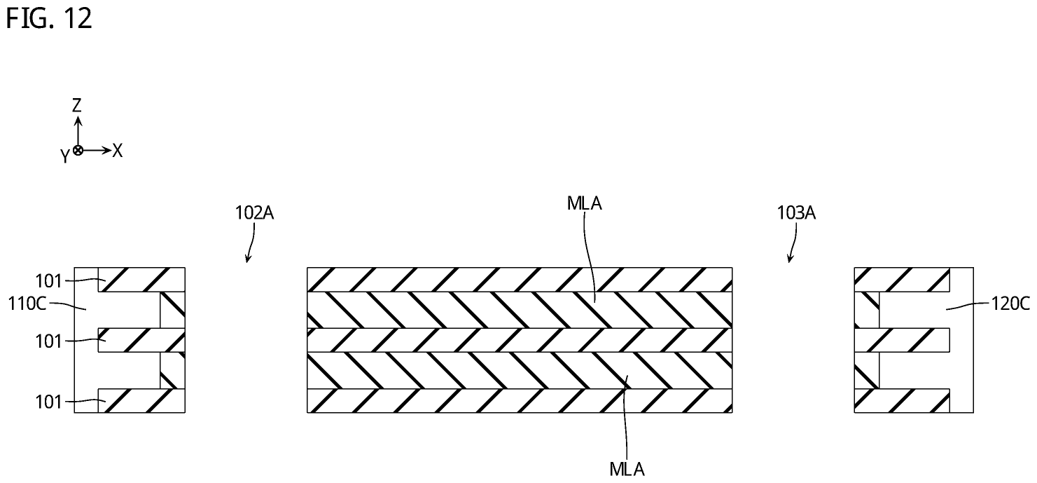

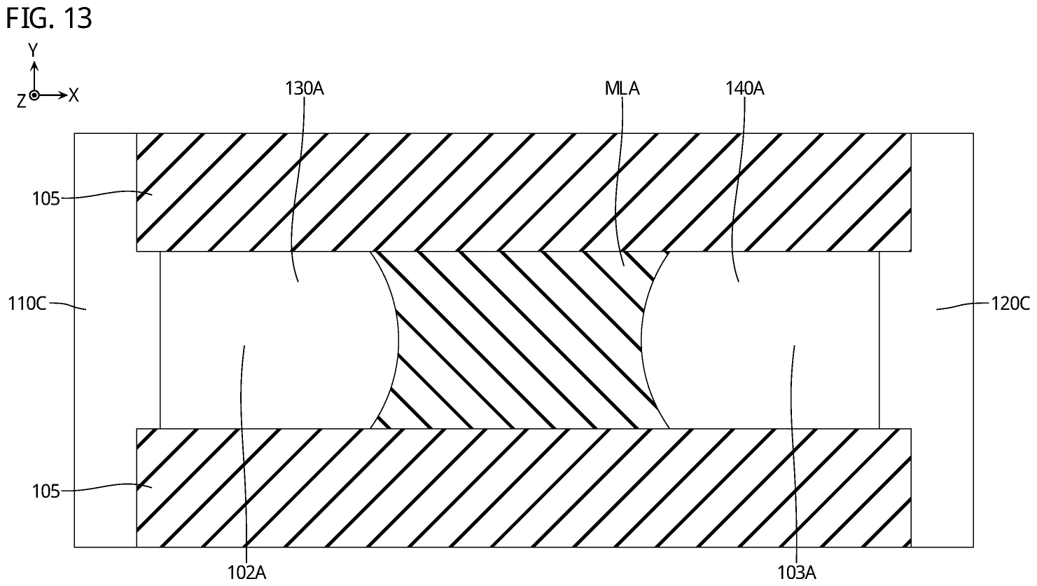

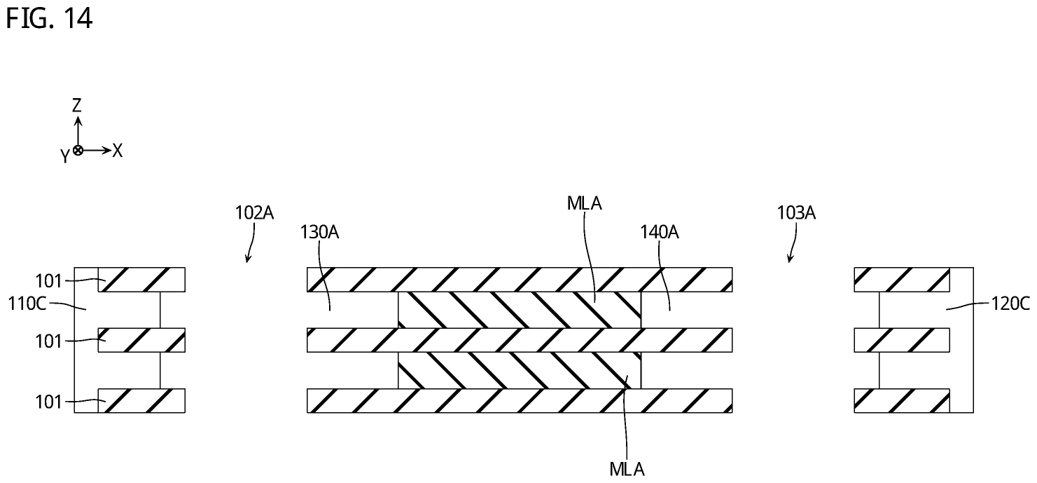

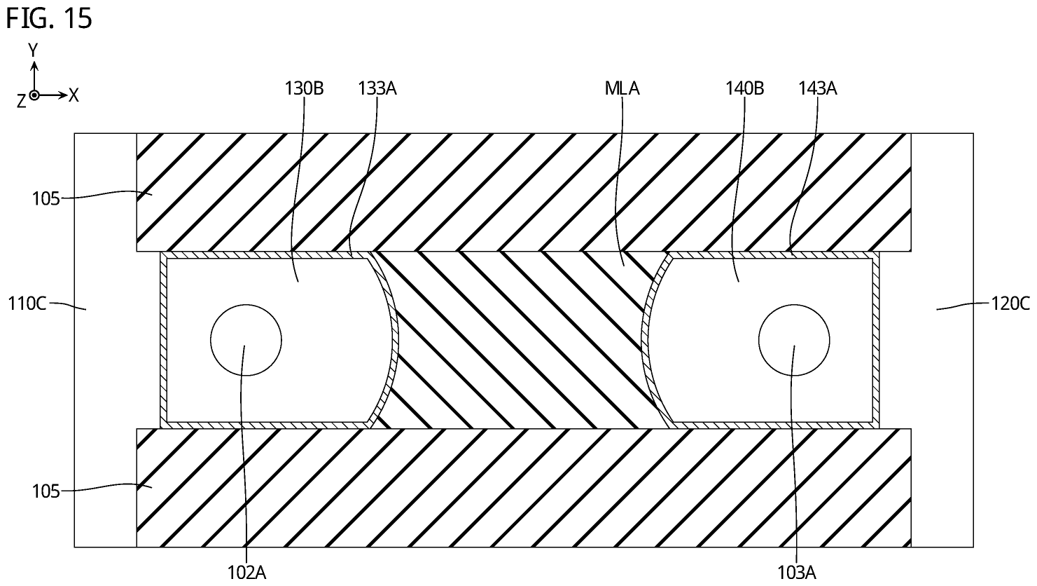

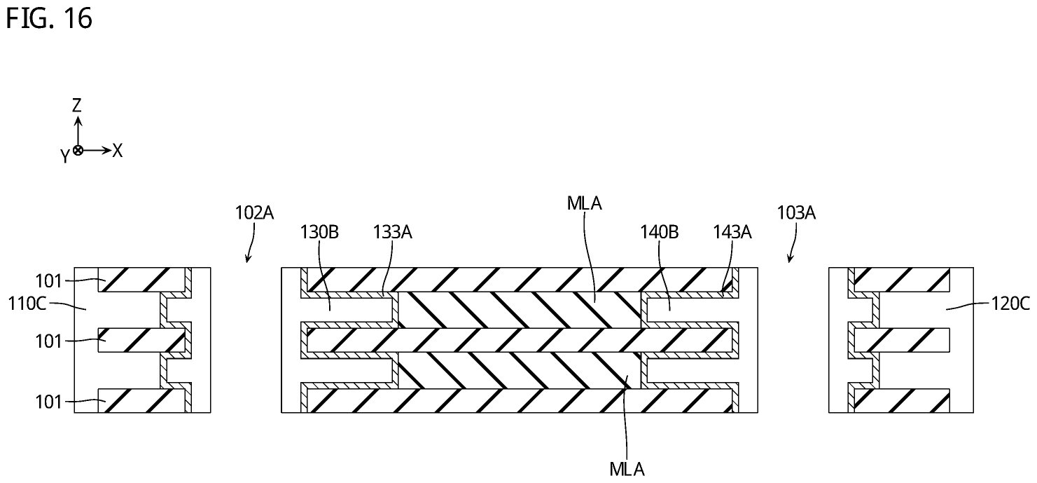

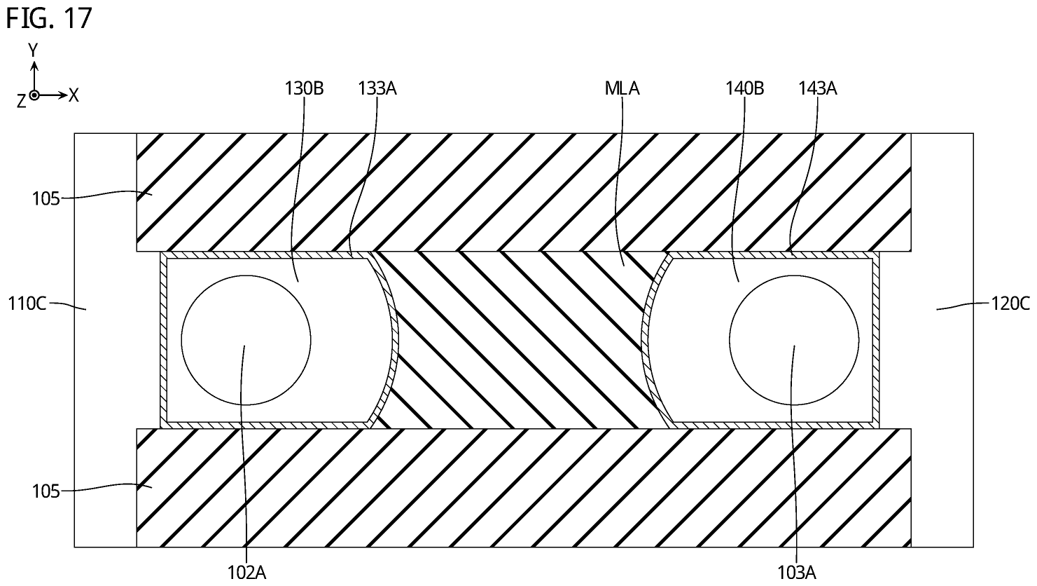

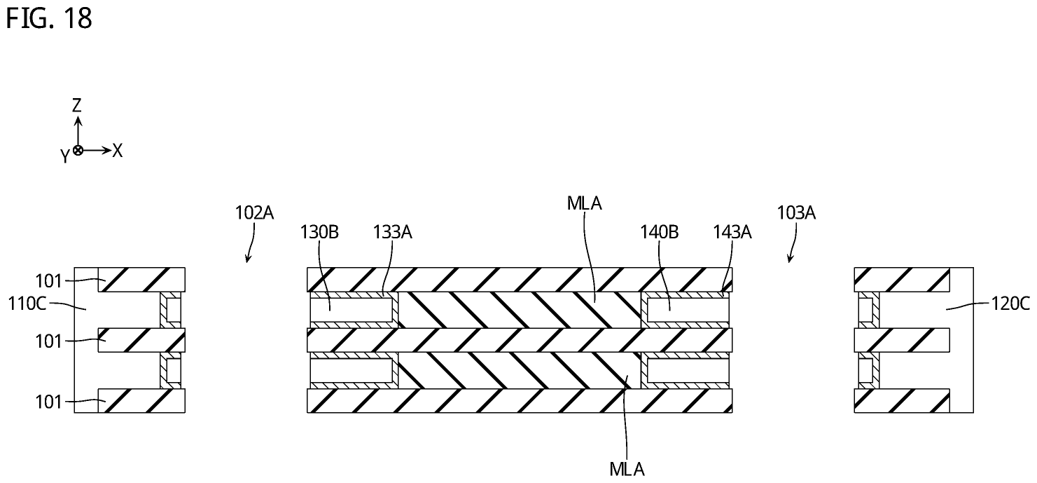

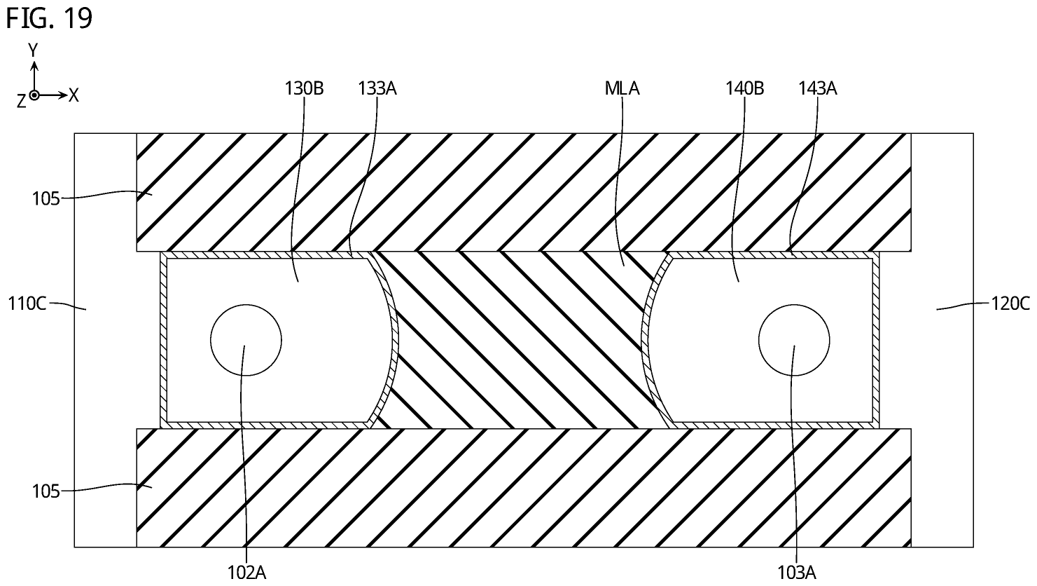

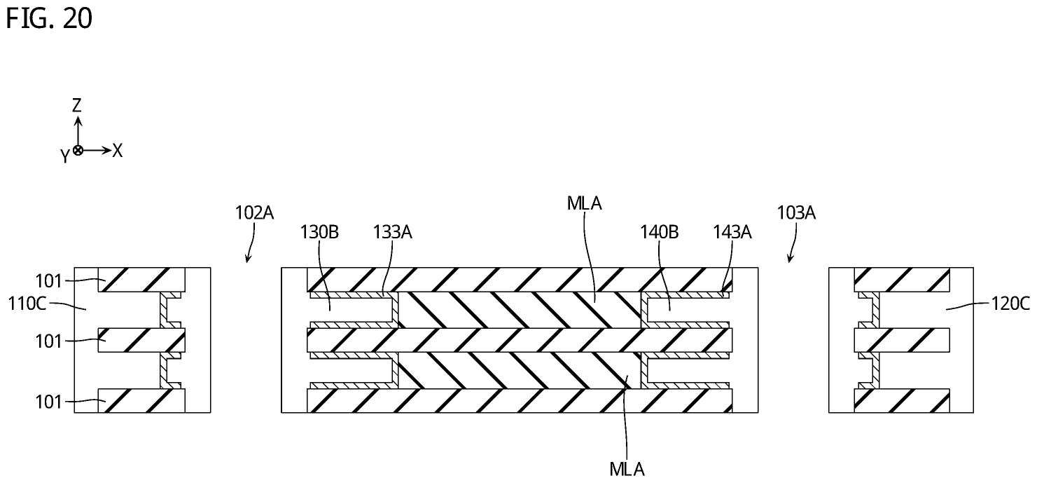

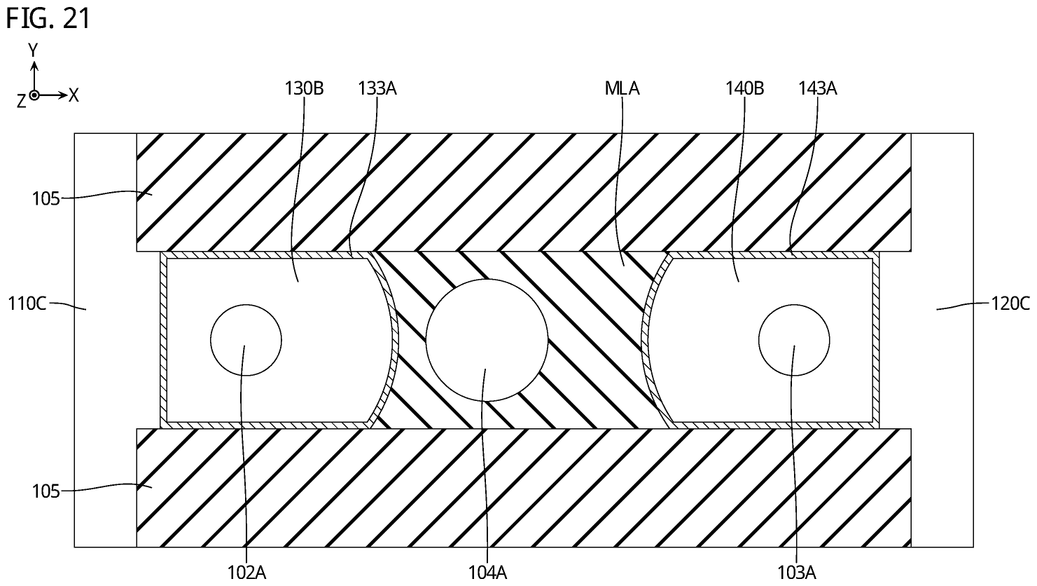

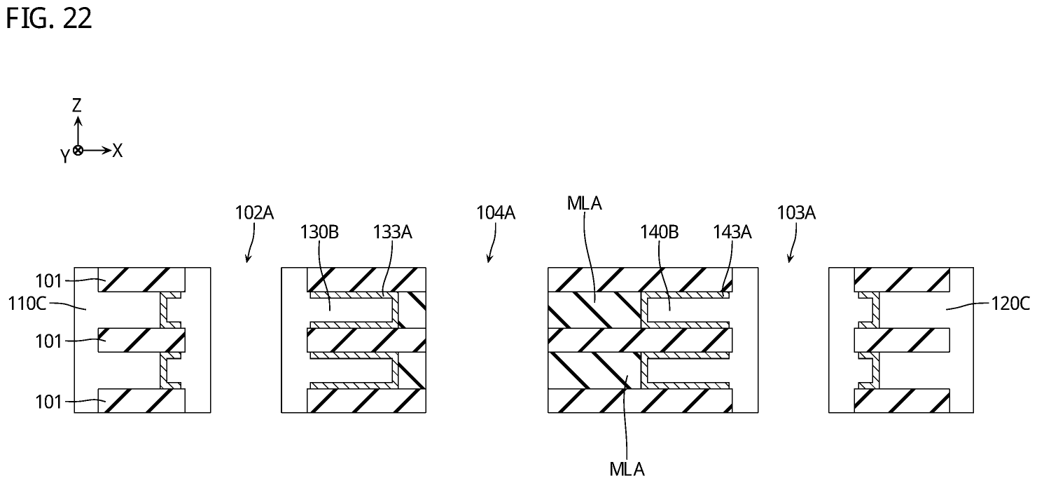

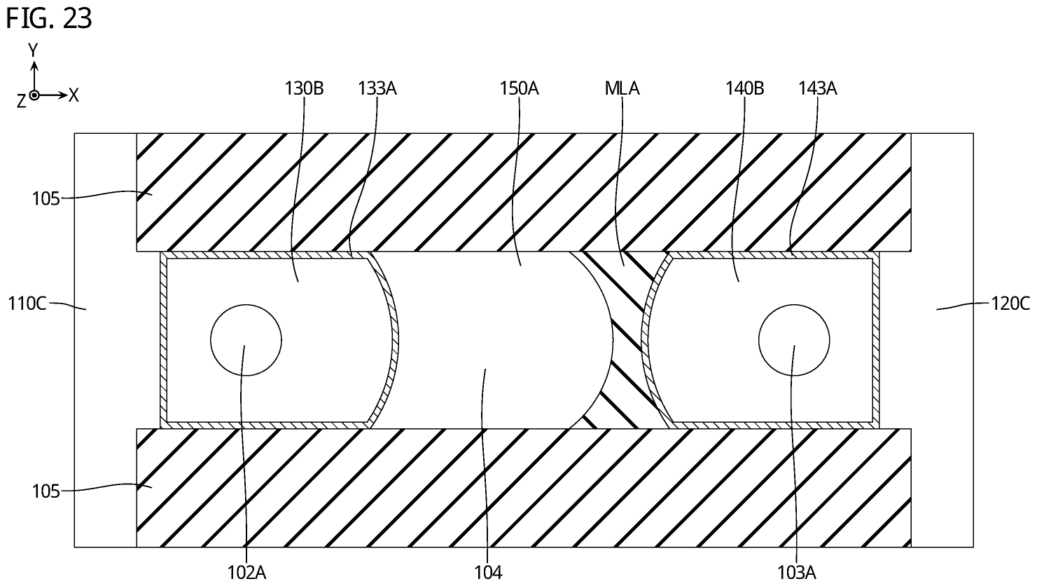

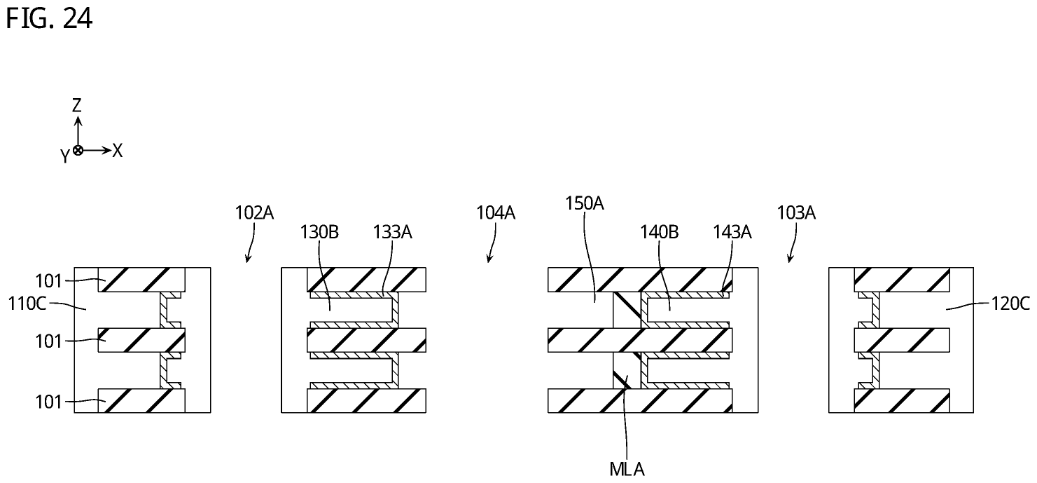

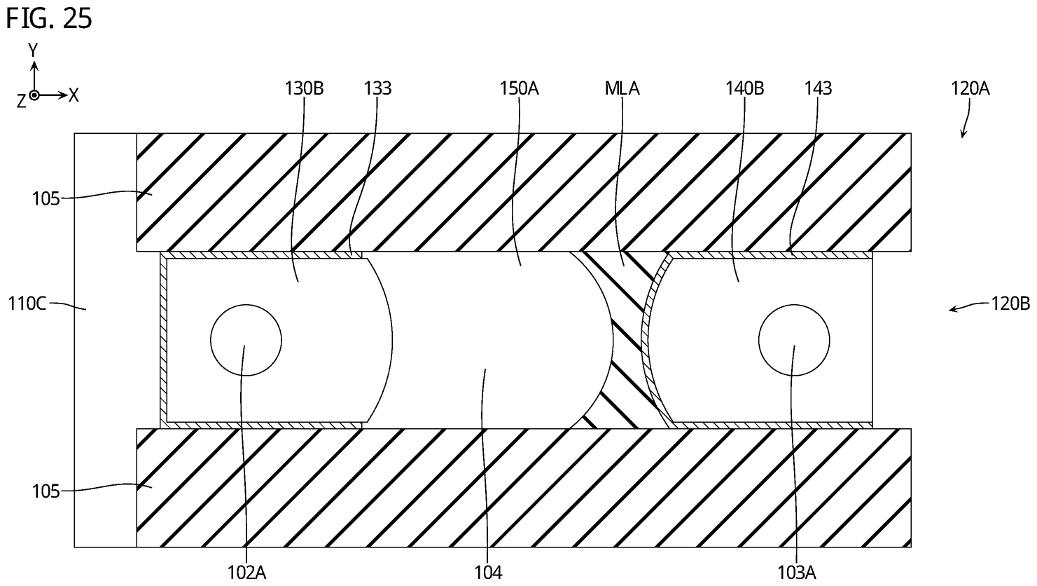

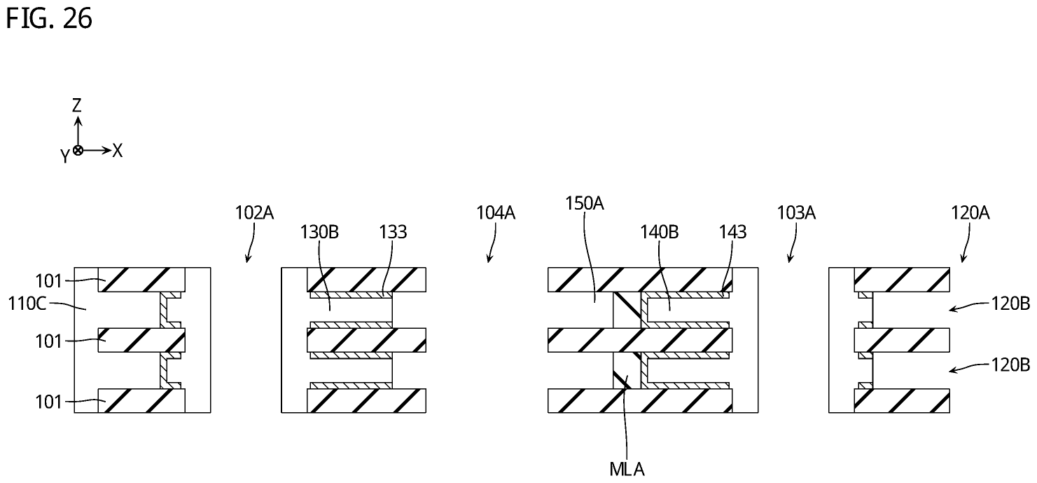

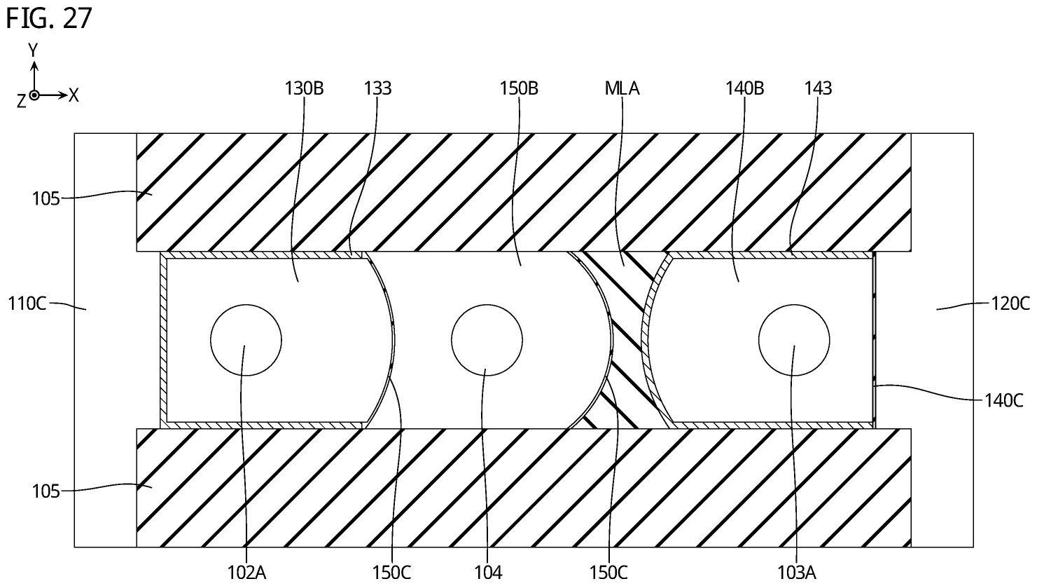

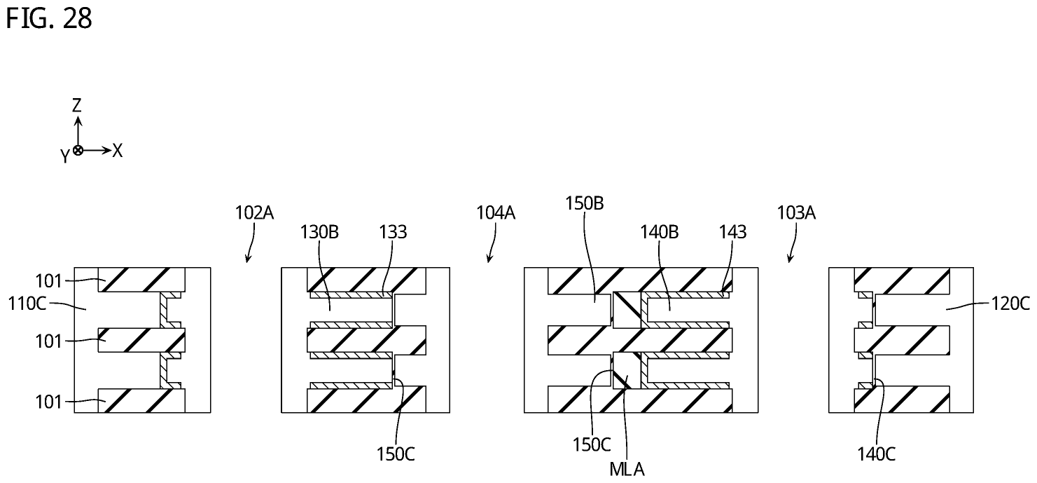

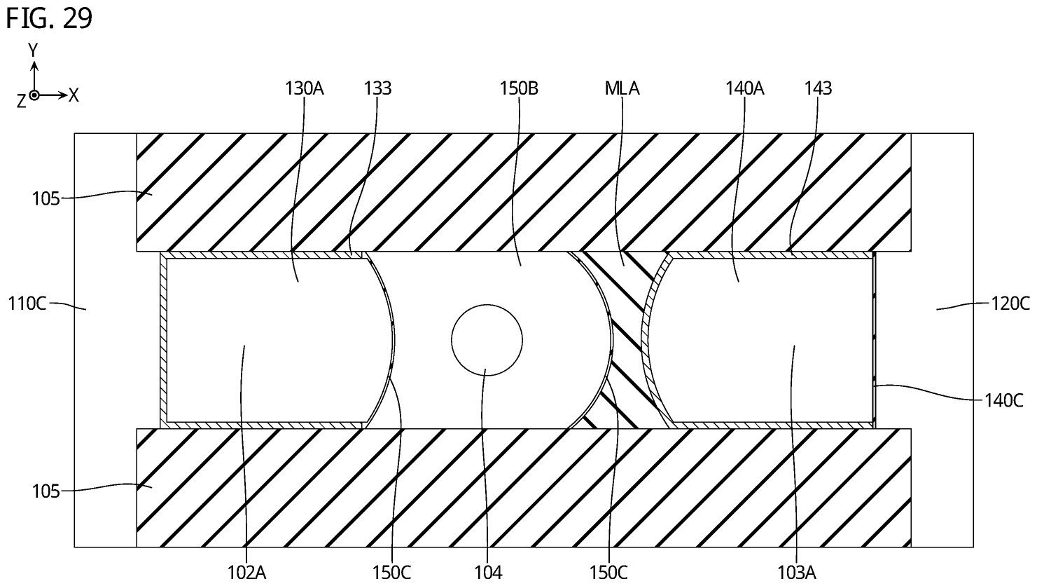

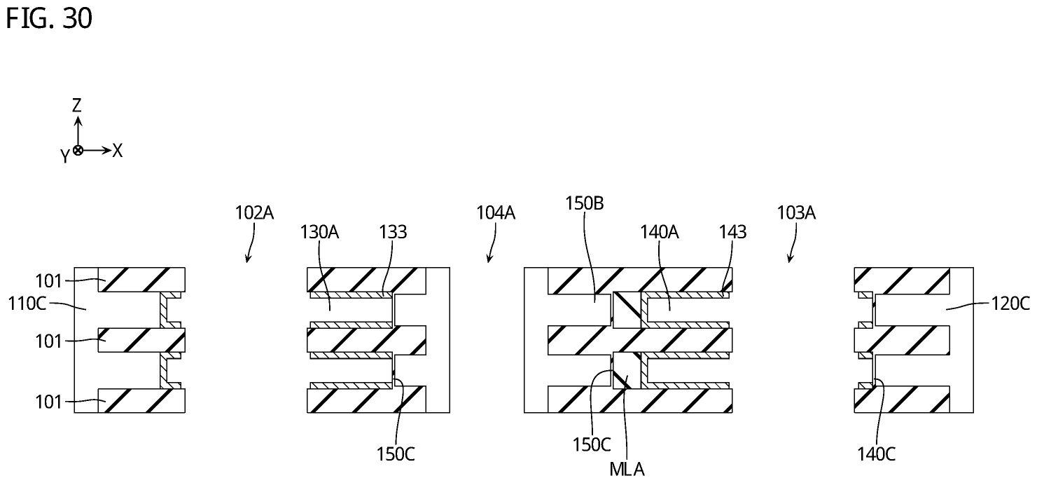

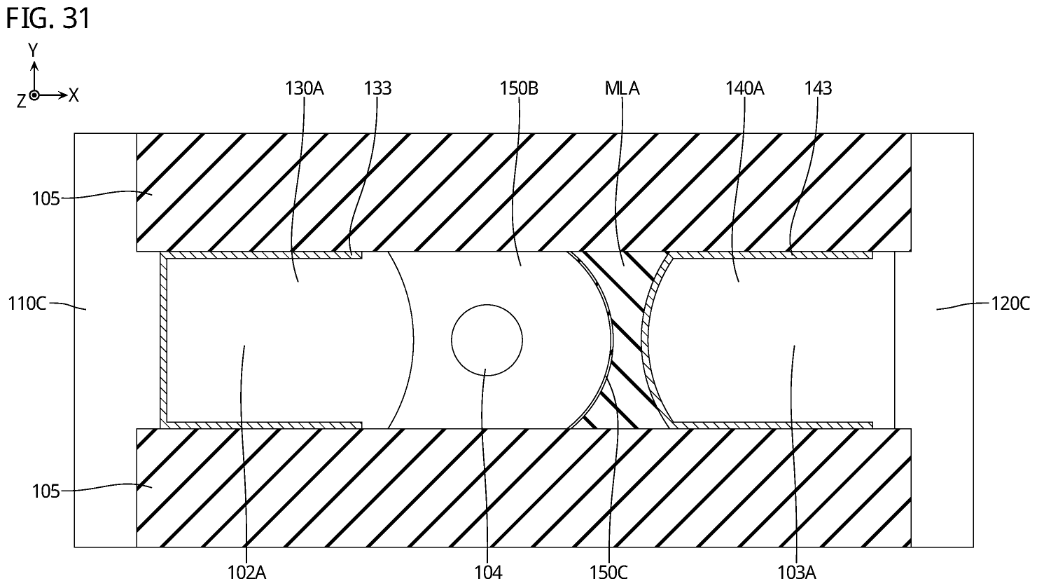

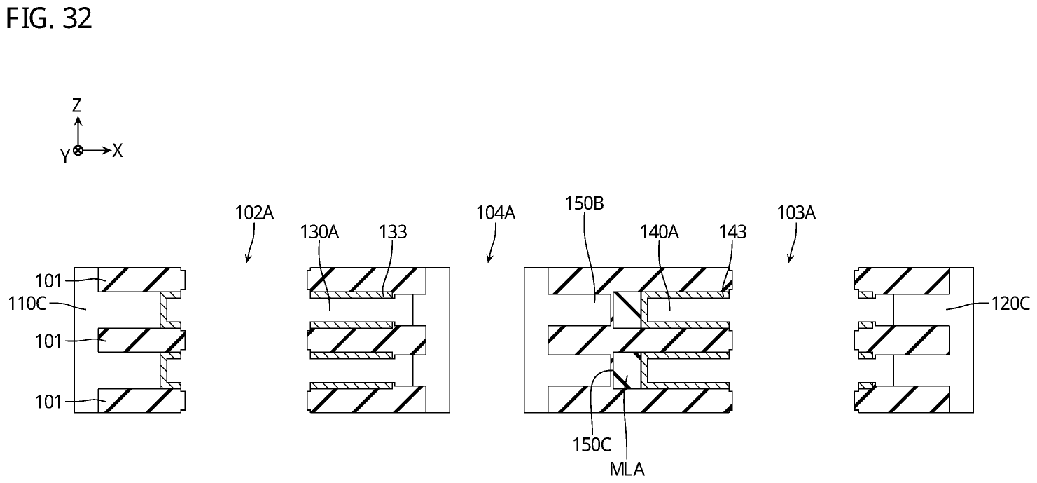

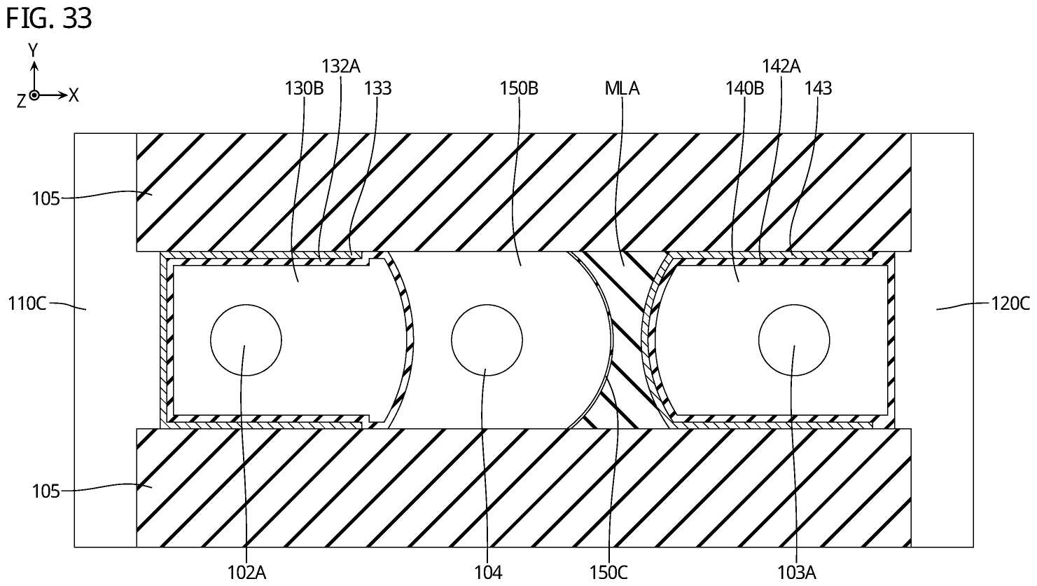

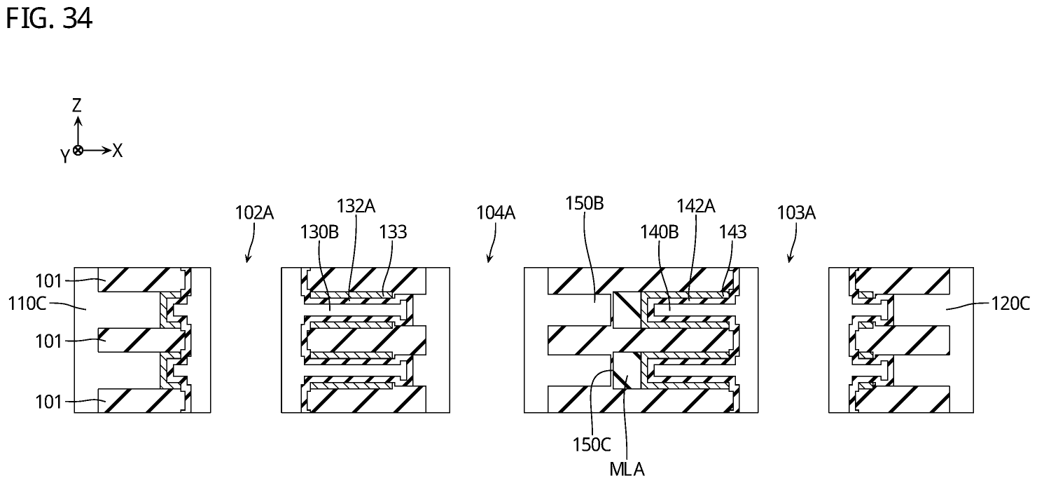

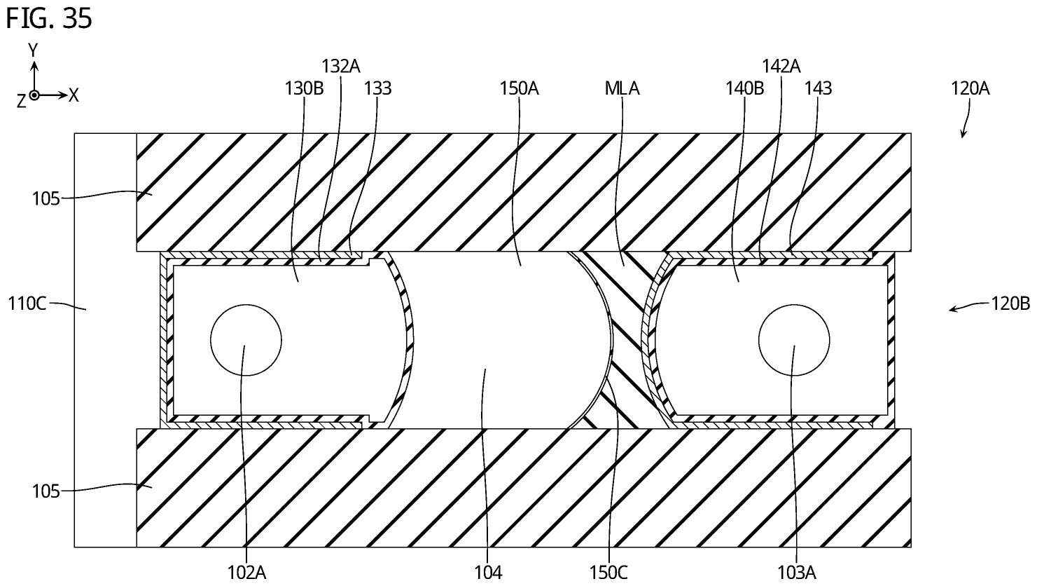

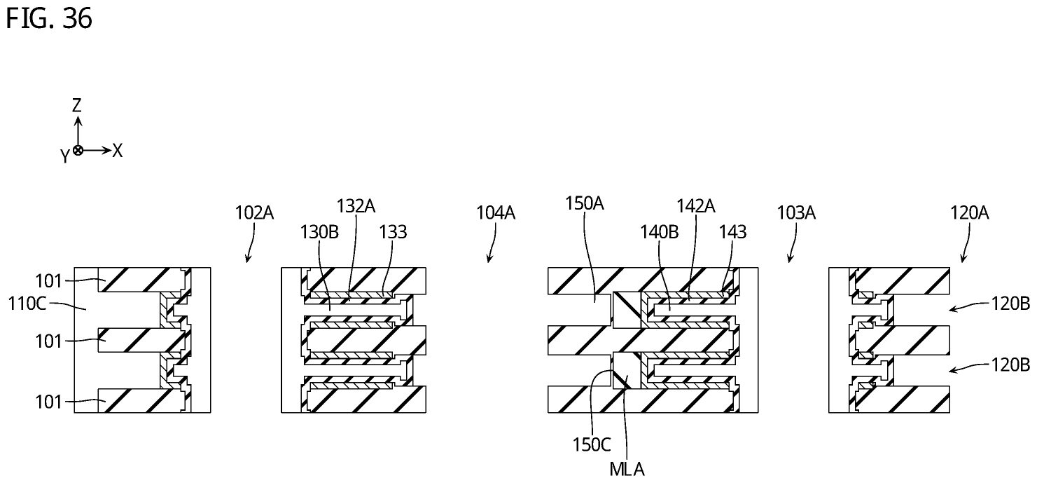

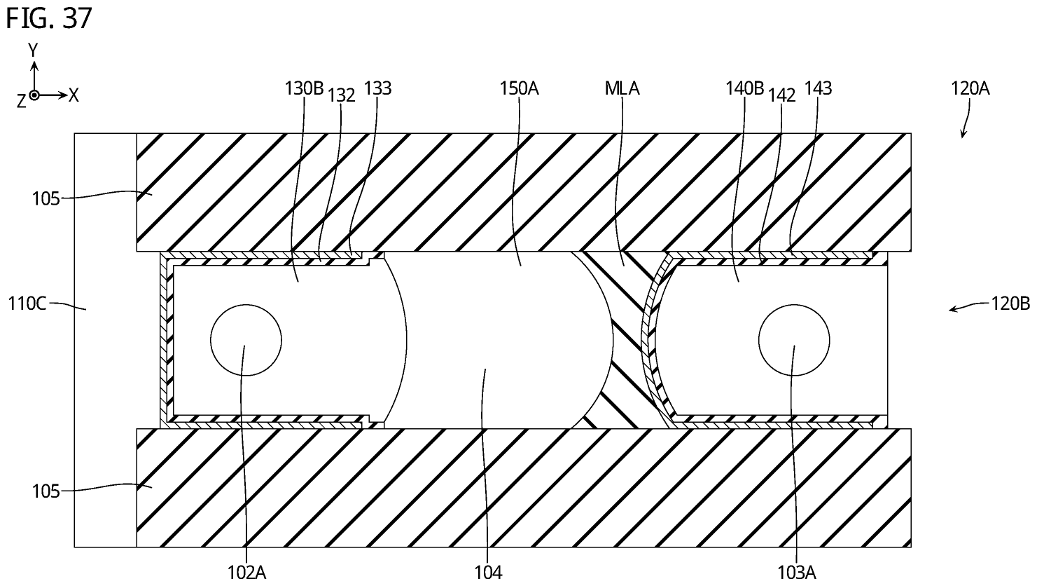

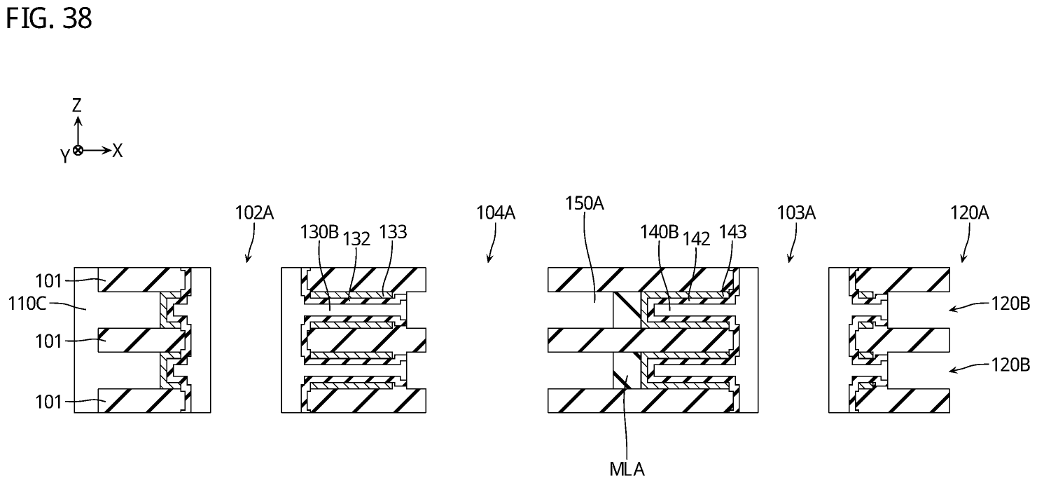

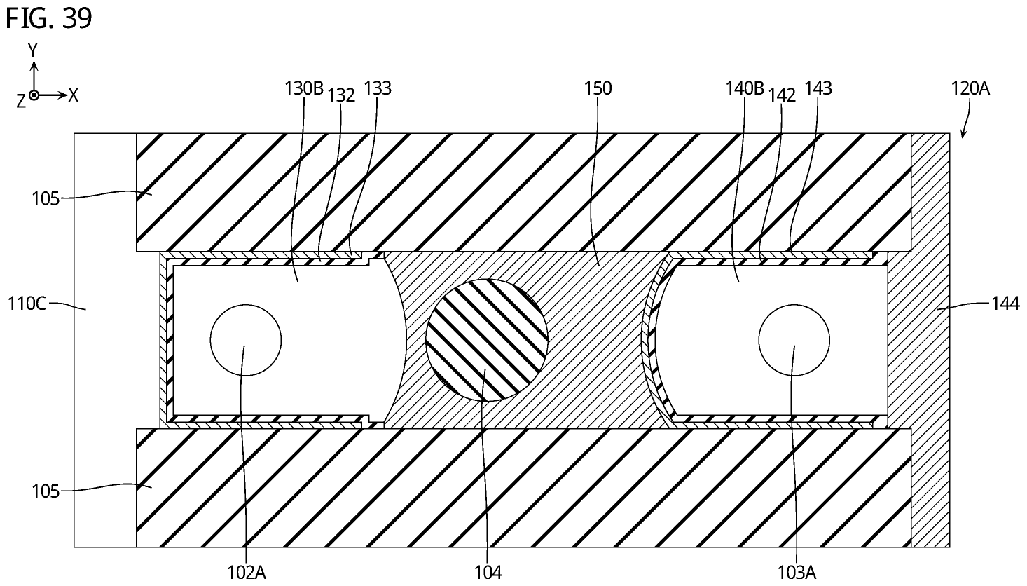

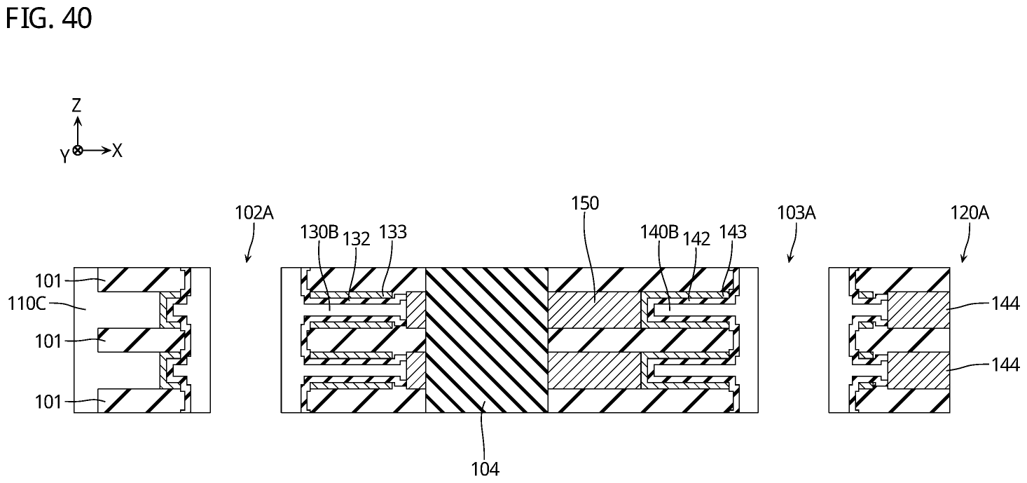

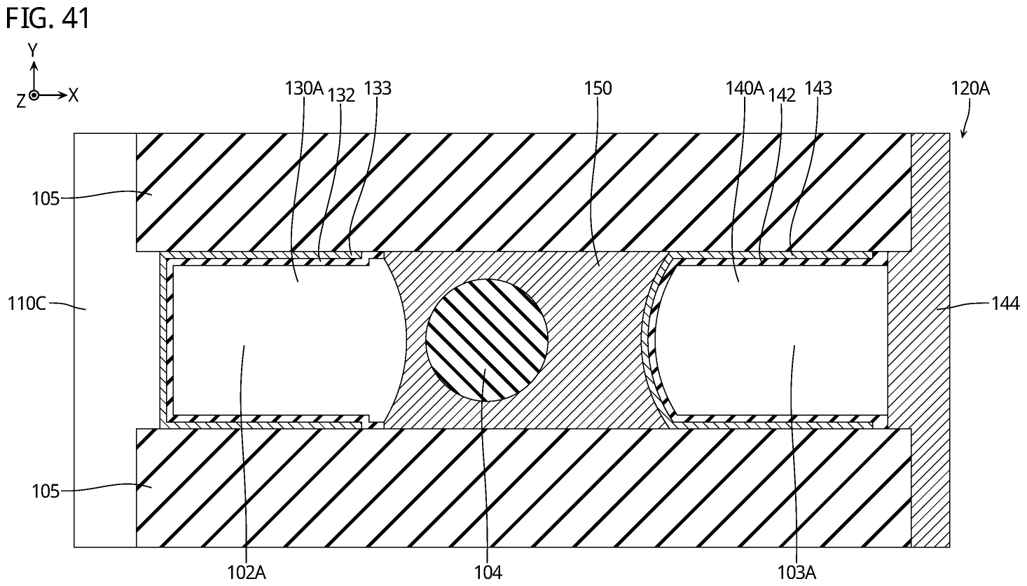

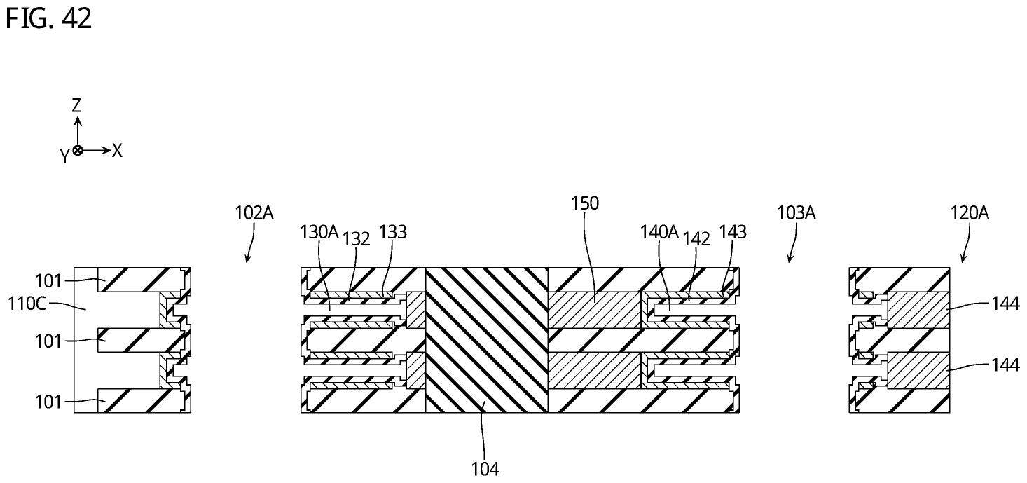

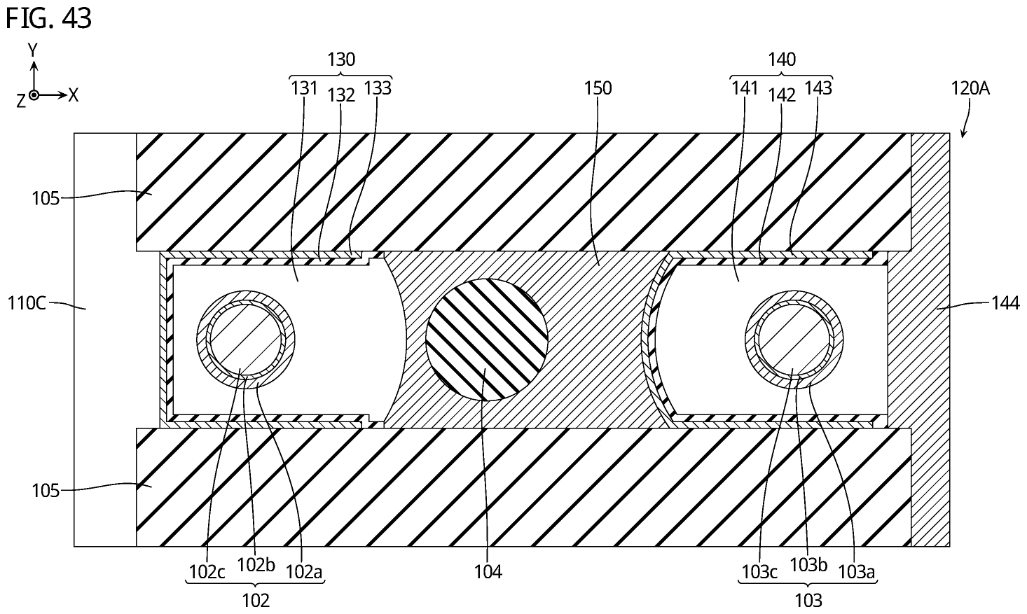

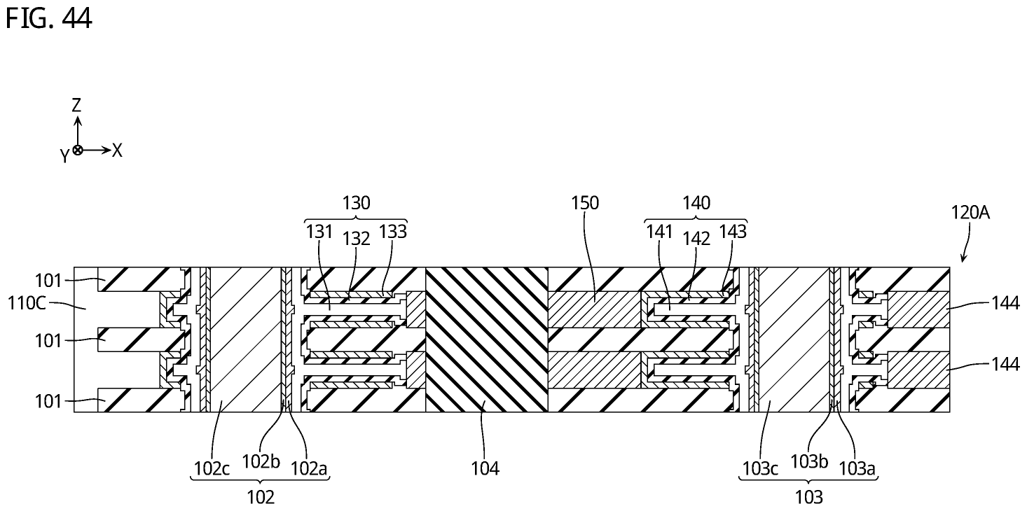

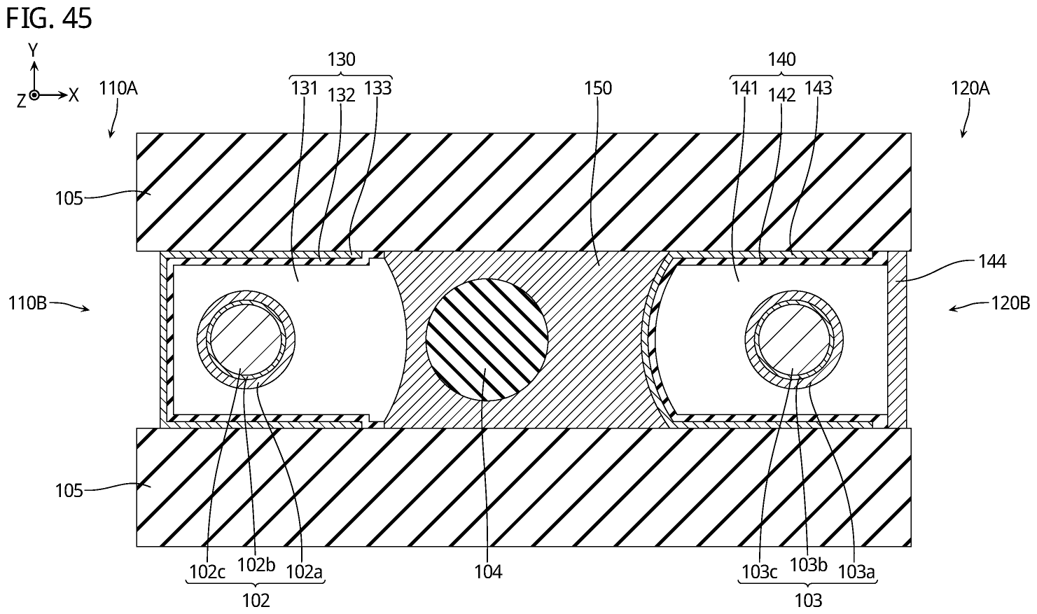

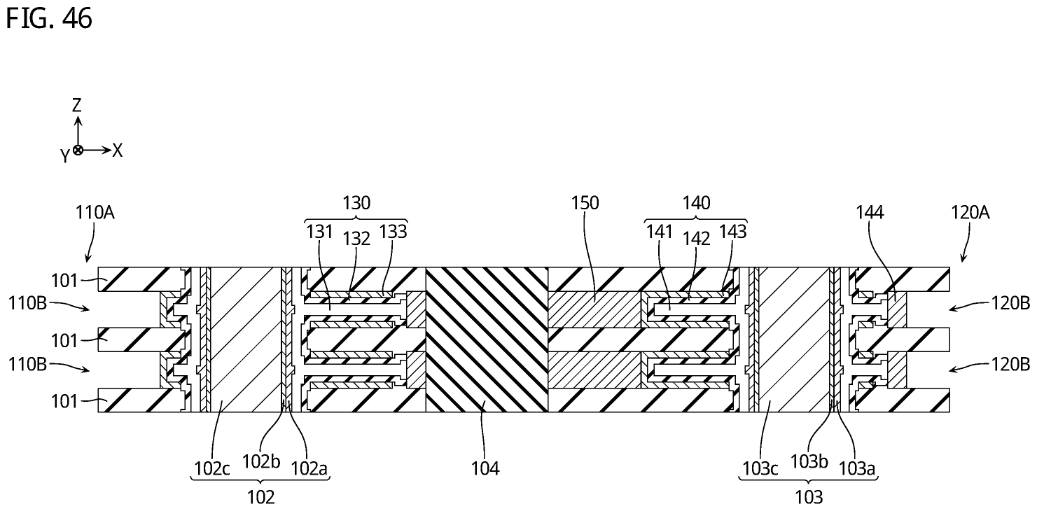

FIG. 5 to FIG. 46 are schematic cross-sectional views for describing a method for manufacturing the semiconductor memory device according to the first embodiment. FIG. 5, FIG. 7, FIG. 9, FIG. 11, FIG. 13, FIG. 15, FIG. 17, FIG. 19, FIG. 21, FIG. 23, FIG. 25, FIG. 27, FIG. 29, FIG. 31, FIG. 33, FIG. 35, FIG. 37, FIG. 39, FIG. 41, FIG. 43, and FIG. 45 illustrate cross-sectional surfaces corresponding to FIG. 3. FIG. 6, FIG. 8, FIG. 10, FIG. 12, FIG. 14, FIG. 16, FIG. 18, FIG. 20, FIG. 22, FIG. 24, FIG. 26, FIG. 28, FIG. 30, FIG. 32, FIG. 34, FIG. 36, FIG. 38, FIG. 40, FIG. 42, FIG. 44, and FIG. 46 illustrate cross-sectional surfaces corresponding to FIG. 4.

In the manufacturing method, for example, as illustrated in FIG. 6, a plurality of the insulating layers 101 and a plurality of sacrifice layers MLA are alternately formed. The sacrifice layer MLA contains, for example, silicon nitride (Si₃N₄). This process is performed by, for example, Chemical Vapor Deposition (CVD).

Next, for example, as illustrated in FIG. 5, insulating layers 105 are formed. Int this process, for example, openings are formed at positions corresponding to the insulating layers 105. The openings extend in the Z-direction, and penetrate the plurality of insulating layers 101 and the plurality of sacrifice layers MLA arranged in the Z-direction. This process is performed by, for example, Reactive Ion Etching (RIE). After the openings are formed, the insulating layers 105 are formed. This process is performed by, for example, CVD.

Next, for example, as illustrated in FIG. 7 and FIG. 8, openings 110A, 120A are formed at the proximity of positions corresponding to the wirings 110, 120. The openings 110A, 120A extend in the Y-direction and the Z-direction, and penetrate the plurality of insulating layers 101 and the plurality of sacrifice layers MLA arranged in the Z-direction to separate these configurations in the X-direction. This process is performed by, for example, RIE.

Openings 110B, 120B are formed at positions corresponding to the wirings 110, 120. A part of an upper surface and a part of a lower surface of the insulating layer 101, a part of a side surface of the insulating layer 105 in the Y-direction, and a part of a side surface of the sacrifice layer MLA in the X-direction are exposed inside of the openings 110B, 120B. In this process, for example, a part of the sacrifice layer MLA is selectively removed via the openings 110A, 120A. This process is performed by, for example, wet etching.

Next, for example, as illustrated in FIG. 9 and FIG. 10, sacrifice layers 110C, 120C of silicon (Si) or the like are filled in the openings 110A, 120A and the openings 110B, 120B. This process is performed by, for example, CVD.

Next, for example, as illustrated in FIG. 11 and FIG. 12, openings 102A, 103A are formed at positions corresponding to the via-wirings 102, 103. The openings 102A, 103A extend in the Z-direction as illustrated in FIG. 12, and penetrate the plurality of insulating layers 101 and the plurality of sacrifice layers MLA arranged in the Z-direction. This process is performed by, for example, RIE.

Next, for example, as illustrated in FIG. 13 and FIG. 14, openings 130A, 140A are formed at positions corresponding to the transistor structures 130, 140. A part of the upper surface and a part of the lower surface of the insulating layer 101, a part of the side surface of the sacrifice layer MLA in the X-direction, and a part of the side surface of the insulating layer 105 in the Y-direction are exposed inside of the openings 130A, 140A. A part of a side surface of the sacrifice layer 110C in the X-direction is exposed inside the opening 130A. A part of a side surface of the sacrifice layer 120C in the X-direction is exposed inside the opening 140A. In this process, for example, a part of the sacrifice layer MLA is selectively removed via the openings 102A, 103A. This process is performed by, for example, wet etching.

Next, for example, as illustrated in FIG. 15 and FIG. 16, a conductive layer 133A and a sacrifice layer 130B of silicon (Si) or the like are formed inside the opening 130A 5 and the opening 102A. Similarly, a conductive layer 143A and a sacrifice layer 140B of silicon (Si) or the like are formed inside the opening 140A and the opening 103A. The conductive layers 133A, 143A are formed on a part of the upper surface, a part of the lower surface, and surfaces exposed to the openings 102A, 103A of the insulating layer 101, a part of the side surface of the sacrifice layer MLA in the X-direction, a part of the side surface of the insulating layer 105 in the Y-direction, and a part of the side surfaces of the sacrifice layers 110C, 120C in the X-direction. The opening 130A is filled with the sacrifice layer 130B, and the opening 102A is not filled with the sacrifice layer 130B. Similarly, the opening 140A is filled with the sacrifice layer 140B, and the opening 103A is not filled with the sacrifice layer 140B. This process is performed by for example, CVD.

Next, for example, as illustrated in FIG. 17 and FIG. 18, the conductive layers 133A, 143A are partially removed. In this process, for example, parts of the sacrifice layers 130B, 140B provided at inner peripheral surfaces of the openings 102A, 103A are removed. Next, parts of the conductive layers 133A, 143A provided at the inner peripheral surfaces of the openings 102A, 103A are removed to separate the conductive layers 133A, 143A in the Z-direction. This process is performed by, for example, wet etching.

Next, for example, as illustrated in FIG. 19 and FIG. 20, sacrifice layers 130B, 140B are formed inside the openings 102A, 103A. This process is performed by, for example, CVD. Although not illustrated, after the end of this process, upper portions of the openings 102A, 103A are closed by an insulating layer or the like.

Next, for example, as illustrated in FIG. 21 and FIG. 22, an opening 104A is formed at a position corresponding to the insulating member 104. The opening 104A extends in the Z-direction as illustrated in FIG. 22, and penetrates the plurality of insulating layers 101 and the plurality of sacrifice layers MLA arranged in the Z-direction. This process is performed by, for example, RIE.

Next, for example, as illustrated in FIG. 23 and FIG. 24, an opening 150A is formed at a part of a position corresponding to the conductive member 150. A part of the upper surface and a part of the lower surface of the insulating layer 101, a part of the side surface of the sacrifice layer MLA in the X-direction, a part of the side surface of the insulating layer 105 in the Y-direction, and a part of a side surface of the conductive layer 133A in the X-direction are exposed inside the opening 150A. In this process, for example, a part of the sacrifice layer MLA is selectively removed via the opening 104A. In this process, a part of the sacrifice layer MLA is left, and the conductive layer 143A is not exposed inside the opening 150A. This process is performed by, for example, wet etching.

Next, for example, as illustrated in FIG. 25 and FIG. 26, the conductive layers 133, 143 are formed. In this process, for example, the sacrifice layer 120C is removed. For example, a part of the conductive layer 133A covering a side surface of the sacrifice layer 130B on one side in the X-direction (side surface on an opening 120A side) is removed. This causes the side surface of the sacrifice layer 130B on one side in the X-direction to be exposed inside the opening 150A. Further, a part of the conductive layer 143A covering a side surface of the sacrifice layer 140B on one side in the X-direction (side surface on the opening 120A side) is removed. This causes the side surface of the sacrifice layer 140B on one side in the X-direction to be exposed inside the opening 120B. This process is performed by, for example, wet etching.

Next, for example, as illustrated in FIG. 27 and FIG. 28, an oxidation process is performed on the sacrifice layer 130B and the sacrifice layer MLA via the openings 104A, 150A to form an insulating layer 150C. Similarly, an oxidation process is performed on the sacrifice layer 140B via the openings 120A, 120B to form an insulating layer 140C. Further, sacrifice layers 150B, 120C of silicon (Si) or the like are formed inside the openings 104A, 120A and the openings 150A, 120B. This process is performed by, for example, CVD. Although not illustrated, after the end of this process, upper portions of the openings 104A, 120A are closed by an insulating layer or the like.

Next, for example, as illustrated in FIG. 29 and FIG. 30, the sacrifice layers 130B, 140B are removed. This process is performed by, for example, wet etching.

Next, for example, as illustrated in FIG. 31 and FIG. 32, the insulating layer 150C exposed inside the opening 130A, the insulating layer 140C exposed inside the opening 140A, and a part of the sacrifice layers 150B and 120C are removed. This process is performed by, for example, wet etching.

Next, for example, as illustrated in FIG. 33 and FIG. 34, an insulating layer 132A and the sacrifice layer 130B are formed inside the openings 102A, 130A. The insulating layer 132A is formed on an upper surface, a lower surface, and the like of the conductive layer 133, which are surfaces exposed to the opening 130A, a part of the upper surface, a part of the lower surface, and a surface exposed to the opening 102A of the insulating layer 101, a part of a side surface of the sacrifice layer 150B in the X-direction, and a part of the side surface of the insulating layer 105 in the Y-direction. The opening 130A is filled with the sacrifice layer 130B, and the opening 102A is not filled with the sacrifice layer 130B.

Similarly, an insulating layer 142A and the sacrifice layer 140B are formed inside the openings 103A, 140A. The insulating layer 142A is formed on an upper surface, a lower surface, and the like of the conductive layer 143, which are surfaces exposed to the opening 140A, a part of the upper surface, a part of the lower surface, and a surface exposed to the opening 103A of the insulating layer 101, a part of the side surface of the sacrifice layer 120C in the X-direction, and a part of the side surface of the insulating layer 105 in the Y-direction. The opening 140A is filled with the sacrifice layer 140B, and the opening 103A is not filled with the sacrifice layer 140B.

This process is performed by, for example, CVD. Although not illustrated, after the formation of the sacrifice layer 130B and the sacrifice layer 140B, upper portions of the openings 102A, 103A are closed by an insulating layer or the like.

Next, for example, as illustrated in FIG. 35 and FIG. 36, the sacrifice layers 150B, 120C are removed. This process is performed by, for example, wet etching.

Next, for example, as illustrated in FIG. 37 and FIG. 38, the insulating layers 132, 142 are formed. In this process, a part of the insulating layer 132A covering the side surface of the sacrifice layer 130B on one side in the X-direction (side surface on an opening 150A side) is removed via the opening 104A and the opening 150A. This causes the side surface of the sacrifice layer 130B in the X-direction to be exposed inside the opening 150A. Similarly, a part of the insulating layer 142A covering the side surface of the sacrifice layer 140B on one side in the X-direction (side surface on the opening 120A side) is removed via the opening 120A and the opening 120B. This causes the side surface of the sacrifice layer 140B in the X-direction to be exposed inside the opening 120B. This process is performed by, for example, wet etching. In this process, the insulating layer 150C is also removed.

Next, for example, as illustrated in FIG. 39 and FIG. 40, after the sacrifice layer MLA is removed via the opening 104A and the opening 150A, the conductive member 150 is formed on the side surface of the sacrifice layer 130B on one side in the X-direction (side surface on the opening 120A side), the side surface of the conductive layer 143 on one side in the X-direction (side surface on an opening 110A side), both side surfaces of the insulating layer 105 in the Y-direction, and the upper surface and the lower surface of the insulating layer 101. Similarly, the conductive oxide layer 144 is formed on the side surface of the sacrifice layer 140B on one side in the X-direction (side surface on the opening 120A side), the side surface on one side in the X-direction (opening 120A side) and both side surfaces in the Y-direction of the insulating layer 105, and the upper surface and the lower surface of the insulating layer 101. This process is performed by, for example, Atomic Layer Deposition (ALD) and wet etching. The conductive member 150 is separated in the Z-direction by the wet etching.

The insulating member 104 is formed inside the opening 104A. This process is performed by, for example, CVD.

Next, for example, as illustrated in FIG. 41 and FIG. 42, the sacrifice layers 130B, 140B are removed. This process is performed by, for example, wet etching.

Next, for example, as illustrated in FIG. 43 and FIG. 44, the semiconductor layers 131, 141 are formed inside the openings 130A, 140A. The via-wirings 102, 103 are formed inside the openings 102A, 103A. This process is performed by, for example, ALD and CVD.

Next, for example, as illustrated in FIG. 45 and FIG. 46, the sacrifice layer 110C and a part of the conductive oxide layer 144 are removed. This process is performed by, for example, wet etching.

Then, for example, as illustrated in FIG. 3 to FIG. 5, the wirings 110, 120 are formed inside the openings 110B, 120B. This process is performed by, for example, CVD.

### [Effects]

According to the method as described with reference to FIG. 5 to FIG. 46, only by increasing the number of sacrifice layers MLA and insulating layers 101 stacked in the process described with reference to FIG. 6, the number of memory layers ML included in the memory cell array MCA can be increased. Accordingly, the high integration of the memory cell array MCA can be relatively easily achieved almost without the increase in manufacturing cost.

The semiconductor memory device manufactured by such a method includes the plurality of memory layers ML arranged in the Z-direction and the via-wirings 102, 103 extending in the Z-direction. The configurations (the wirings 110, 120, the transistor structures 130, 140, and the like) in the plurality of memory layers ML are all different in position when viewed in the Z-direction. The configurations in the memory layer ML have symmetrical structures in an up-down direction.

As described with reference to FIG. 2 to FIG. 4, in the transistor structure 130 according to the embodiment, the conductive layer 133 is opposed to the upper surface, the lower surface, and both side surfaces in the Y-direction of the semiconductor layer 131.

In this configuration, an interference of electric field that occurs between the plurality of semiconductor layers 131 arranged in the Z-direction can be reduced. Therefore, even in an attempt of the high integration of the memory cell array MCA in the Z-direction, the semiconductor layer 131 can be appropriately controlled to the ON state or the OFF state, and thus a semiconductor memory device that appropriately operates can be provided.

When the write transistor WTr is turned ON, the channel is formed at the upper surface, the lower surface, and both side surfaces in the Y-direction of the semiconductor layer 131. Therefore, a relatively large ON current of the write transistor WTr can be provided. This allows an attempt of increasing the operation speed and stabilizing the operation. The same applies to the transistor structure 140.

Here, for example, it can be also considered that the wiring 110 that functions as the write word line WWL is disposed between the via-wiring 102 and the conductive member 150, and a part of this wiring that functions as the write word line WWL is used as the gate electrode of the write transistor WTr. However, in such a structure, the semiconductor layer that functions as the channel region of the write transistor WTr intersects with the wiring that functions as the write word line WWL when viewed in the Z-direction. Therefore, for example, it is necessary to process the wiring extending in the Y-direction without separating the semiconductor layer in the X-direction, and this increases the degree of difficulty in manufacture. Further, the width of the memory layer in the Z-direction increases.

In this respect, according to the embodiment, the wiring 110 that functions as the write word line WWL is disposed at the opposite side of the transistor structure 140 with respect to the transistor structure 130, and disposed at a position not overlapping with the transistor structure 130 when viewed in the Z-direction. Therefore, the wiring 110 and the transistor structure 130 can be independently formed, and the manufacture is relatively easy. A value of wiring resistance of the wiring 110 can be reduced to a relatively small value while reducing the width of the memory layer ML in the Z-direction. The same applies to the relation between the wiring 120 and the transistor structure 140.

### Second Embodiment

### [Structure]

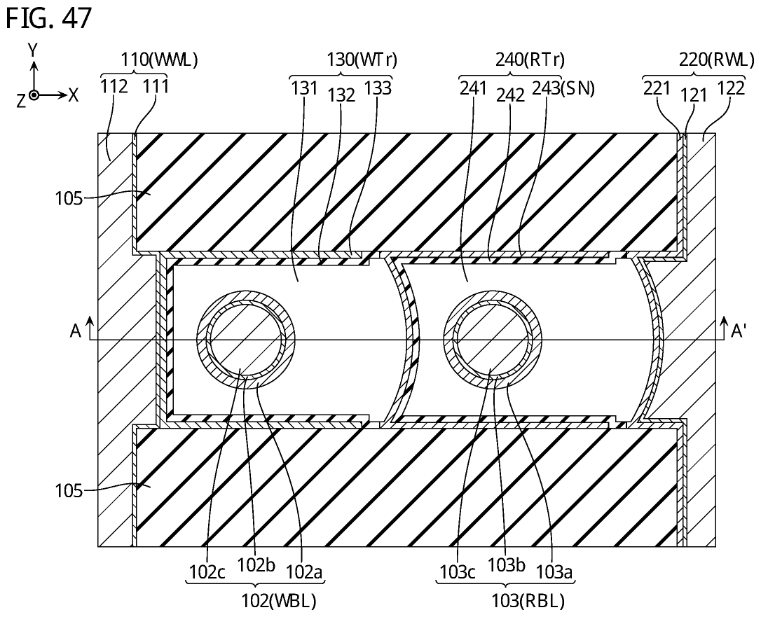

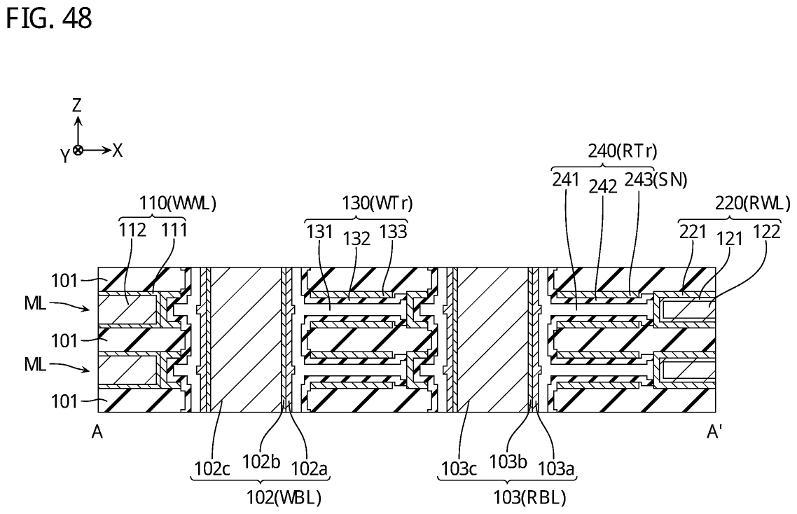

Next, with reference to FIG. 47 and FIG. 48, a semiconductor memory device according to the second embodiment is described. FIG. 47 is a schematic XY cross-sectional view illustrating a configuration of a part of the semiconductor memory device. FIG. 48 is a schematic cross-sectional view illustrating a configuration of a part of the semiconductor memory device, and illustrates a configuration of the structure illustrated in FIG. 47 taken along the line A-A′ when viewed in the arrow direction. In the following description, the same reference numerals are attached to configurations similar to those in the first embodiment, and the explanation is omitted.

The semiconductor memory device according to the second embodiment is basically configured similarly to the semiconductor memory device according to the first embodiment.

However, the semiconductor memory device according to the second embodiment includes a wiring 220 and a transistor structure 240 instead of the wiring 120 and the transistor structure 140. The semiconductor memory device according to the second embodiment does not include the conductive member 150 or the insulating member 104, and the semiconductor layer 131 in the transistor structure 130 is directly connected to a conductive layer 243 described later in the transistor structure 240.

The wiring 220 is basically configured similarly to the wiring 120. However, the wiring 220 includes a conductive oxide film 221 containing a conductive oxide in addition to the barrier conductive film 121 and the conductive film 122. The conductive oxide film 221 covers an upper surface, a lower surface, both side surfaces in the Y-direction, a side surface on one side in the X-direction (side surface on a wiring 110 side), and a side surface on one side in the X-direction (side surface on a transistor structure 240 side) of the barrier conductive film 121, and is in contact with the transistor structure 240.

The transistor structure 240 is basically configured similarly to the transistor structure 140. However, the transistor structure 240 includes a semiconductor layer 241, an insulating layer 242, and a conductive layer 243 instead of the semiconductor layer 141, the insulating layer 142, and the conductive layer 143.

The semiconductor layer 241, the insulating layer 242, and the conductive layer 243 are basically configured similarly to the semiconductor layer 141, the insulating layer 142, and the conductive layer 143.

However, in an XY cross-sectional surface as illustrated in FIG. 47, side surfaces of the semiconductor layer 241, the insulating layer 242, and the conductive layer 243 on one side in the X-direction (the transistor structure 130 side) may be formed along a circle having a center position of the via-wiring 102 as the center. Additionally, side surfaces of the semiconductor layer 241, the insulating layer 242, and the conductive layer 243 on the other side in the X-direction (wiring 120 side) may be formed along a circle having a center position of the via-wiring 103 as the center.

The conductive layer 243 functions as, for example, a sense node SN in addition to functioning as a gate electrode of the read transistor RTr (FIG. 1). The conductive layer 243 contains, for example, a conductive oxide, such as indium tin oxide (ITO).

### [Manufacturing Method]

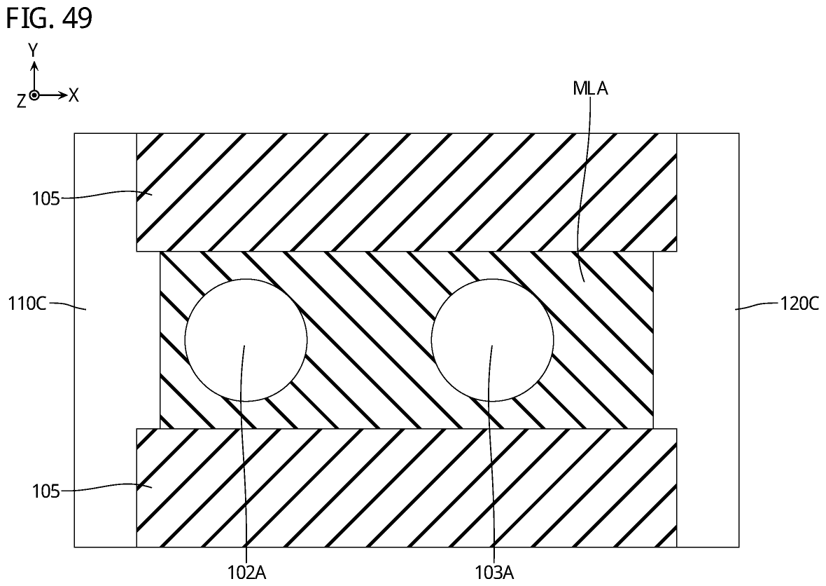

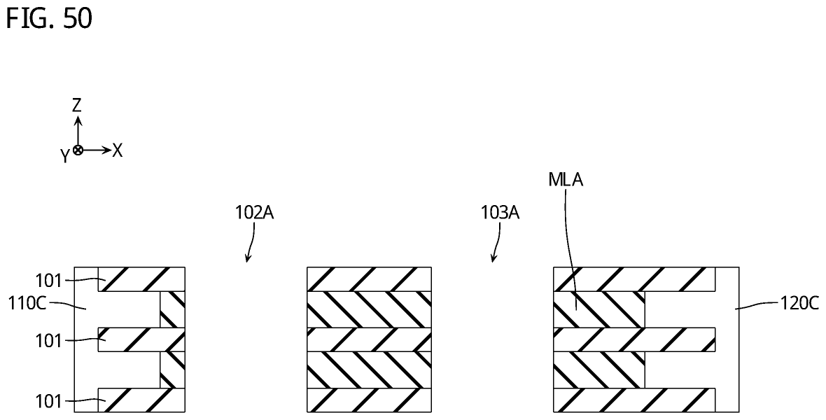

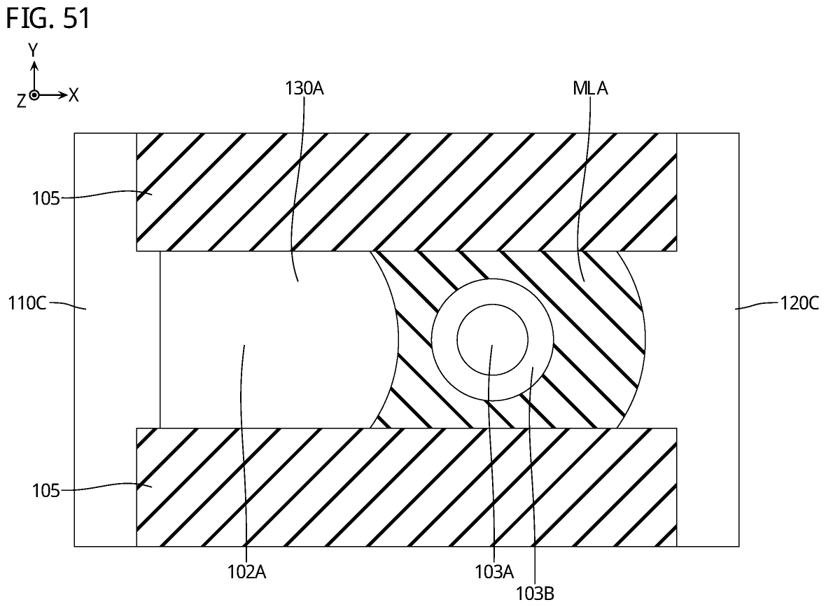

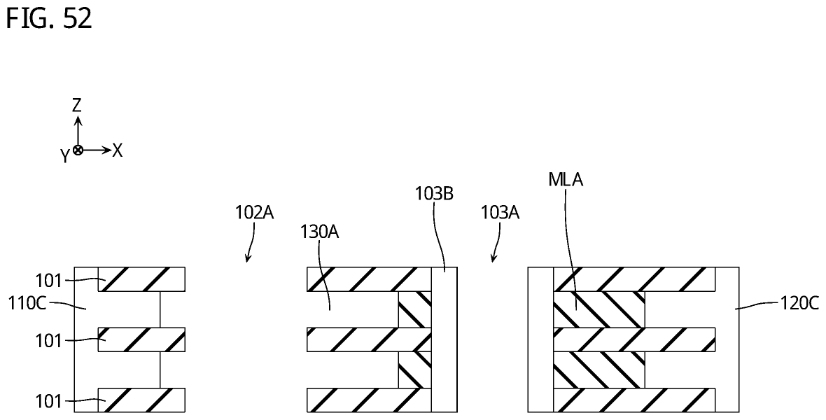

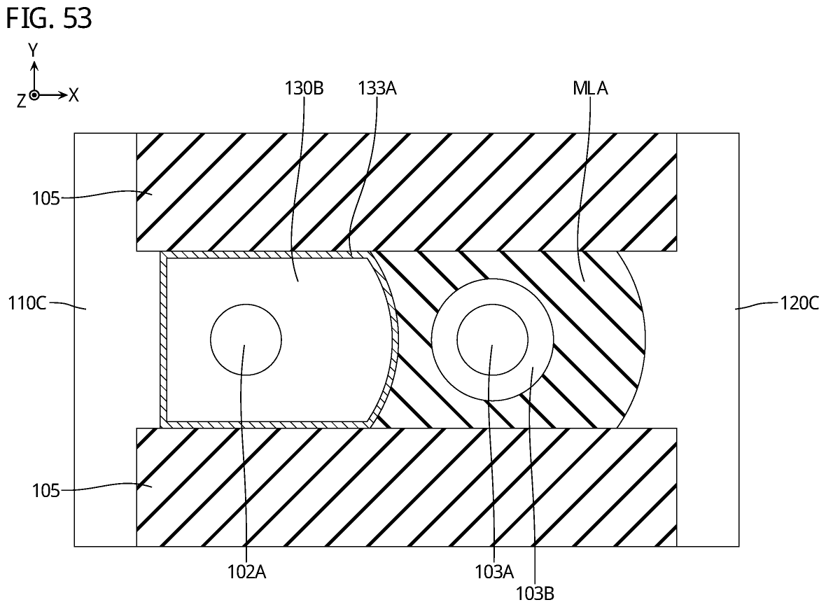

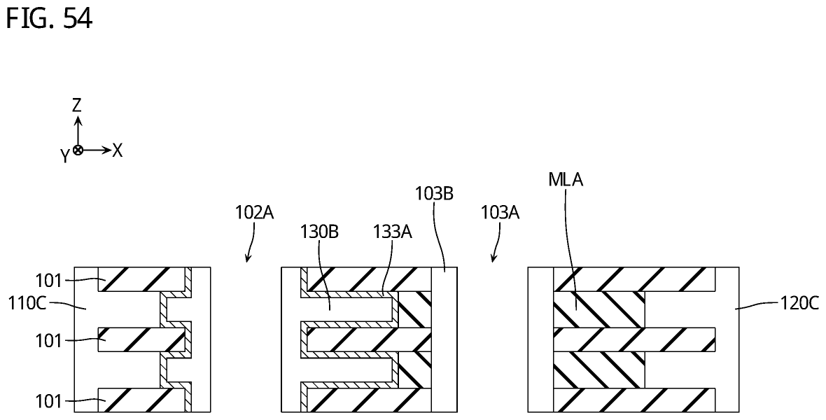

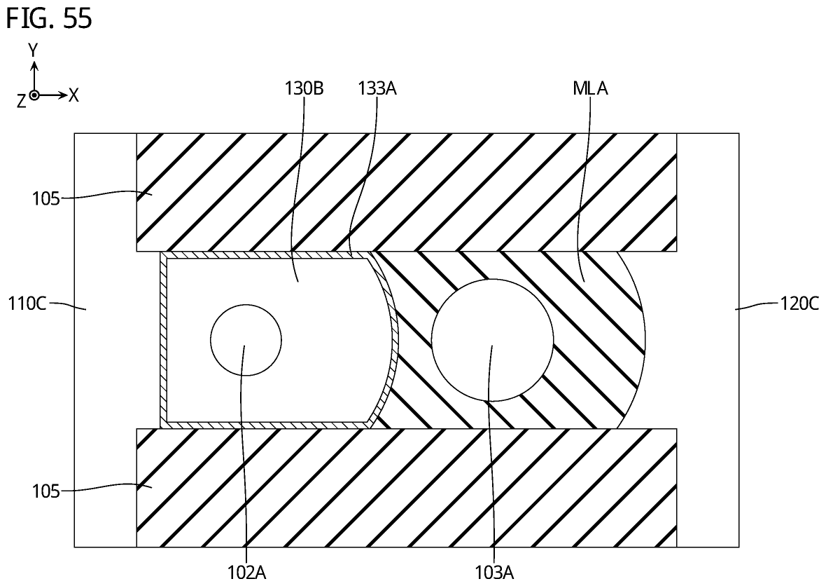

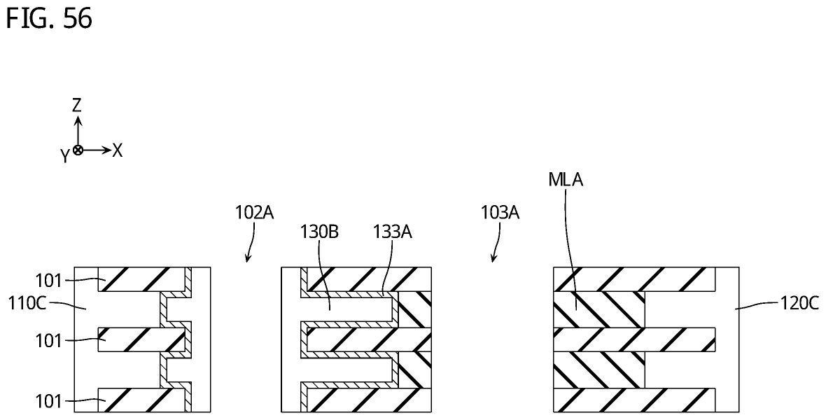

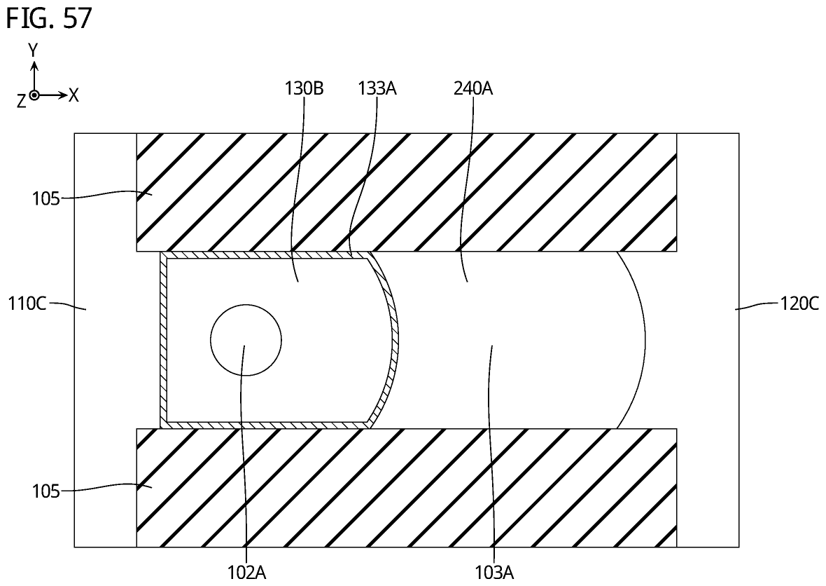

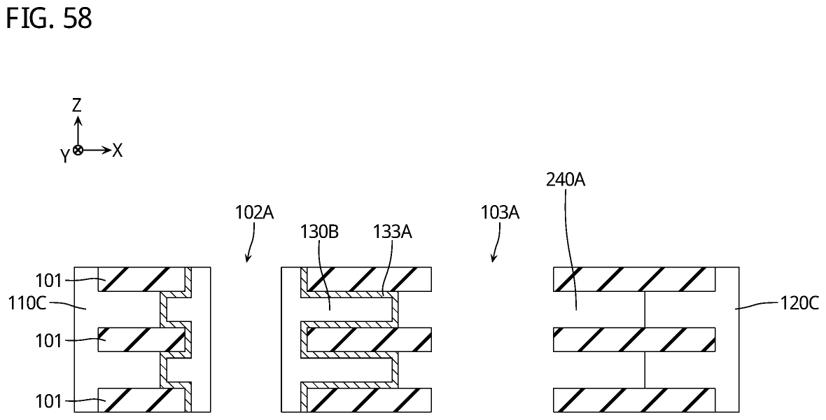

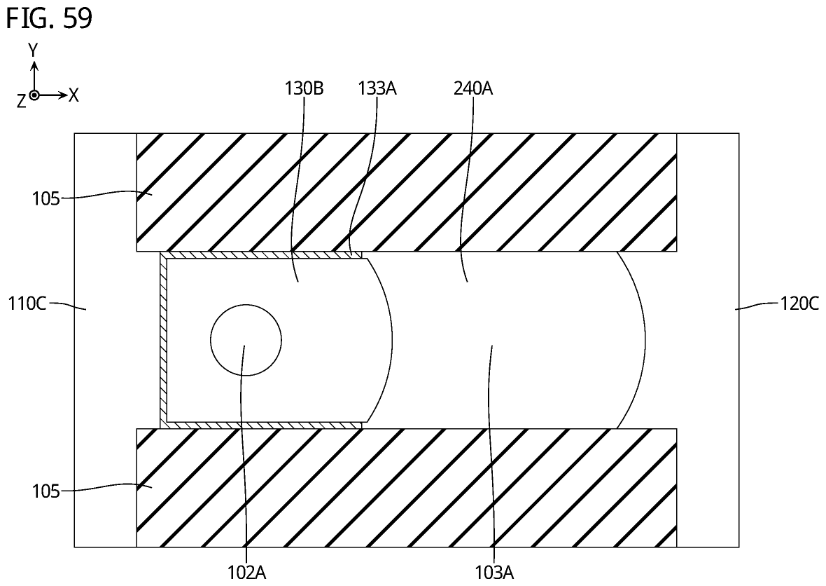

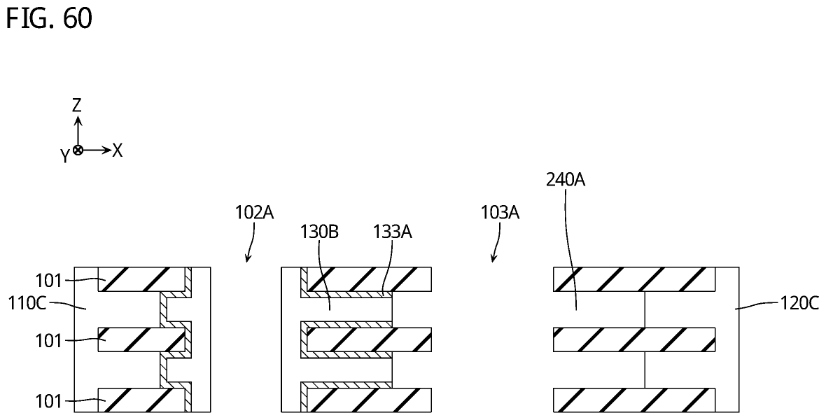

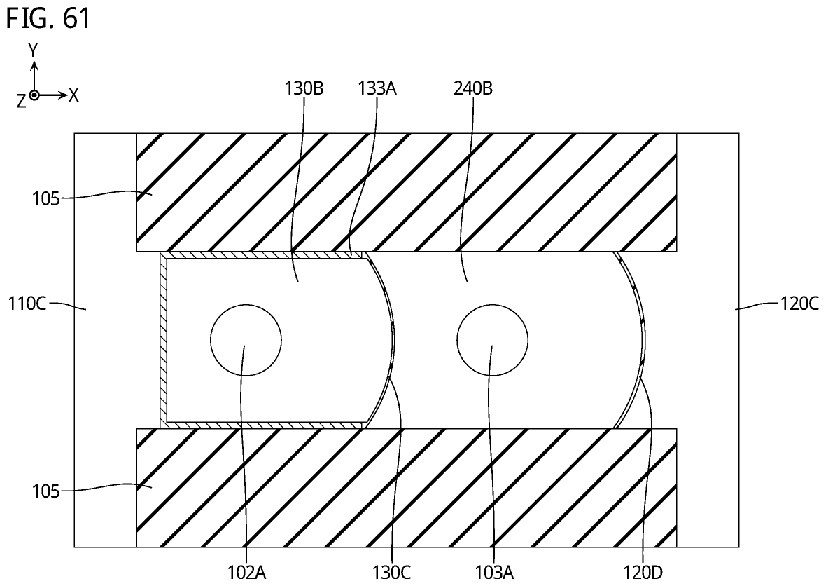

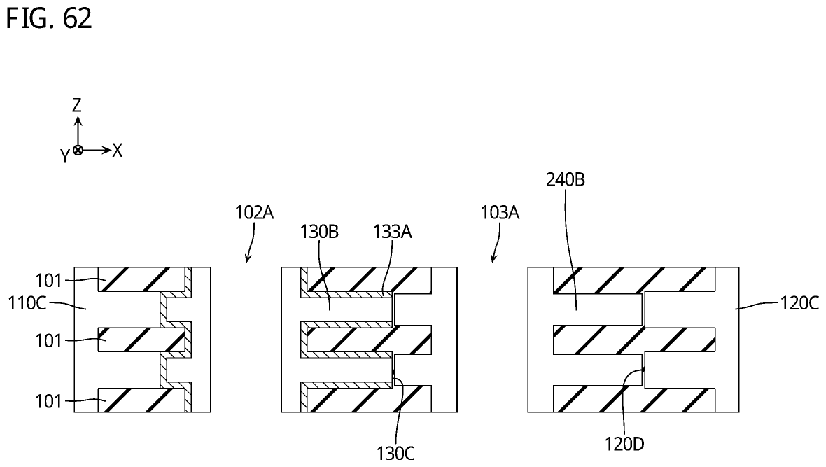

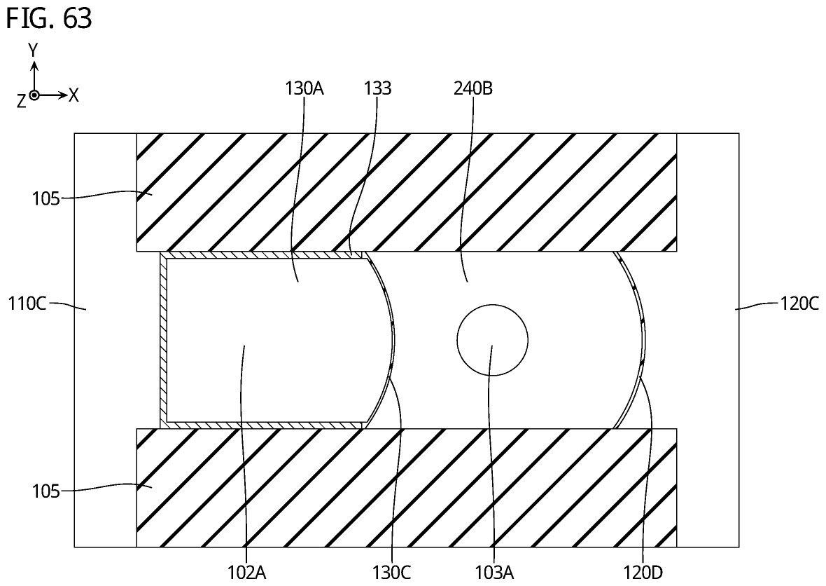

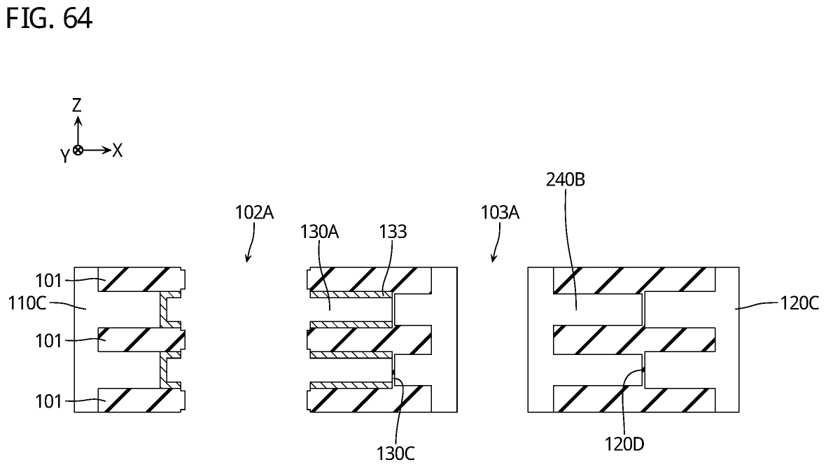

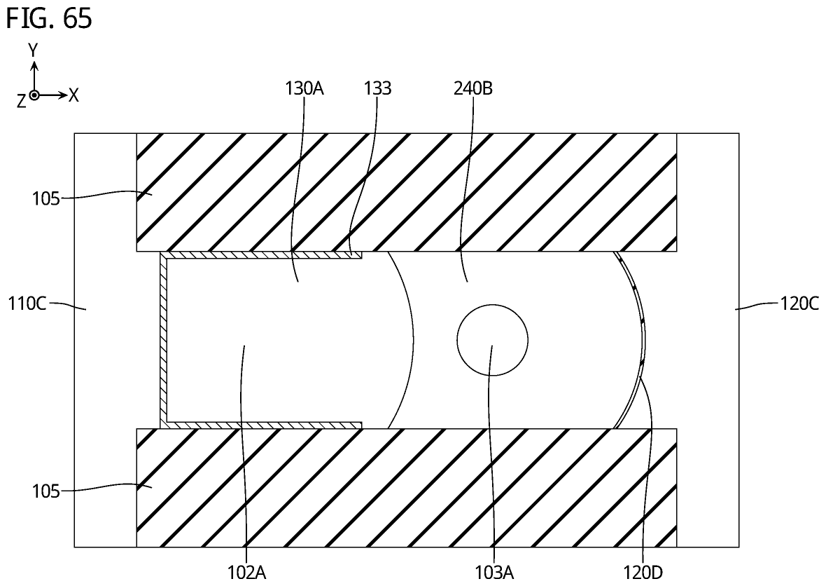

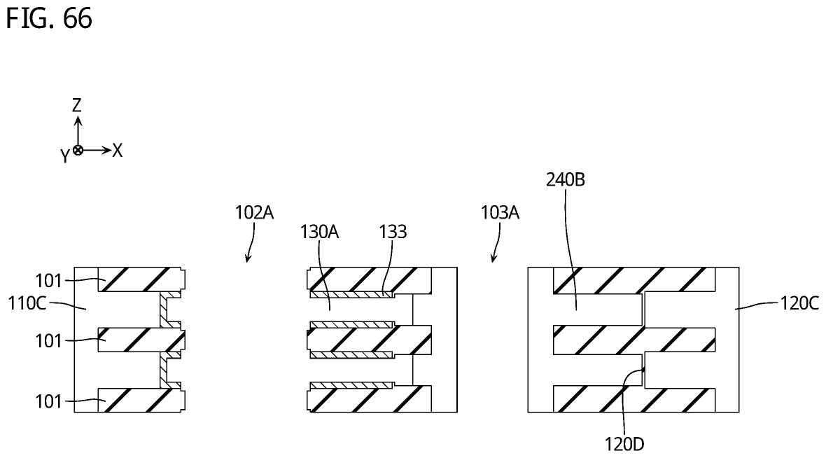

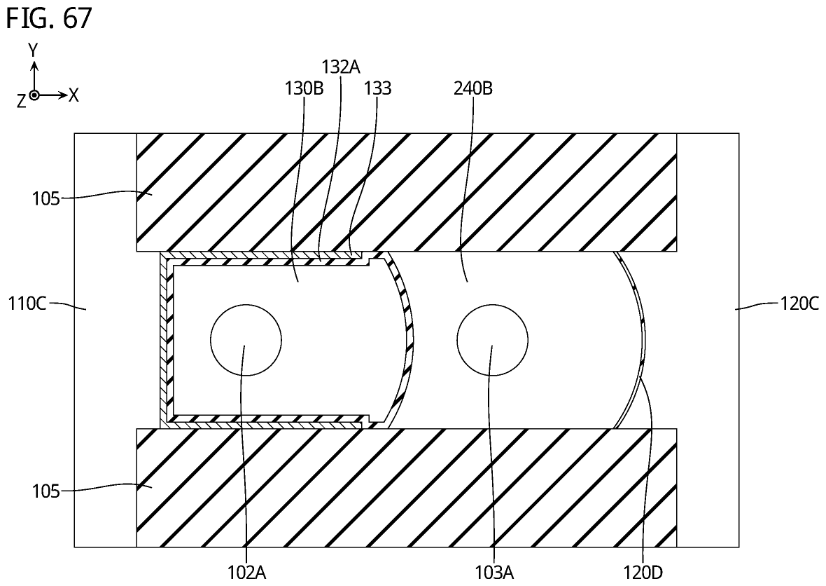

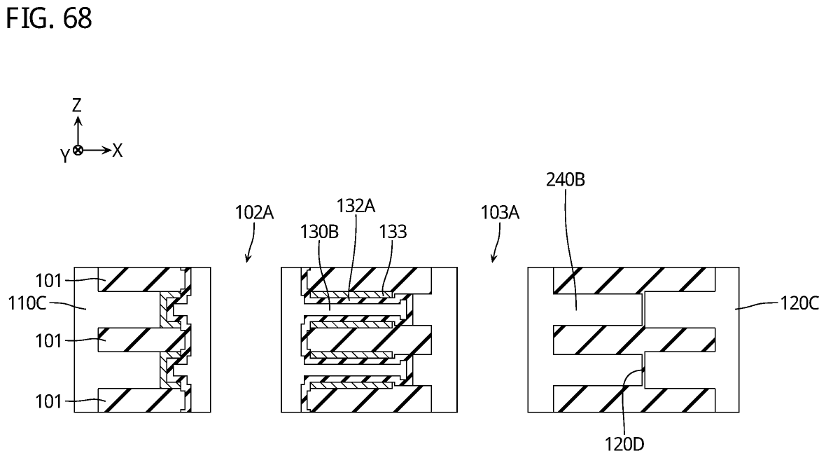

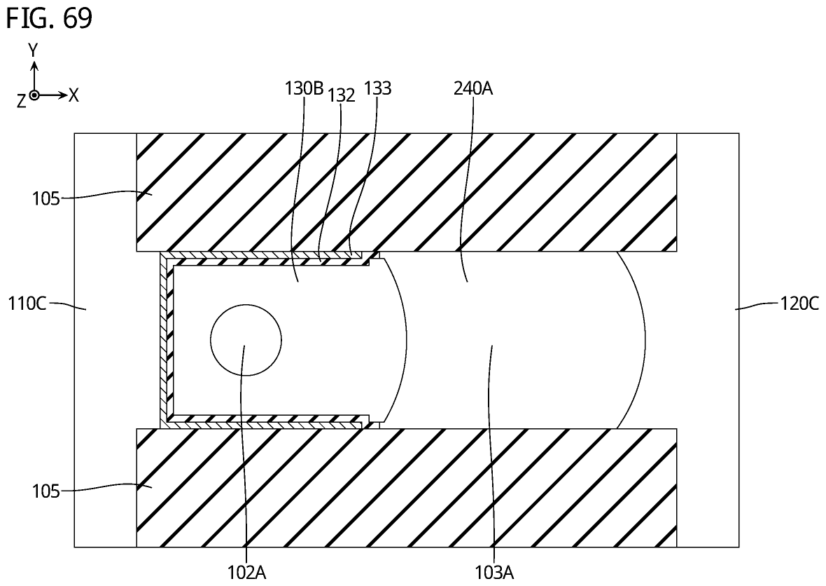

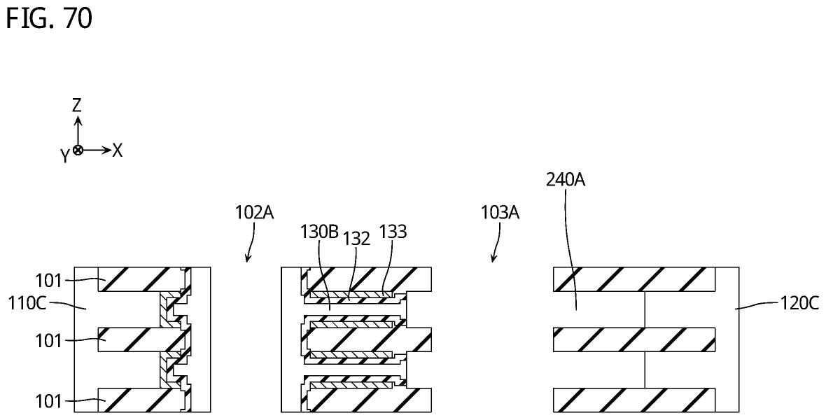

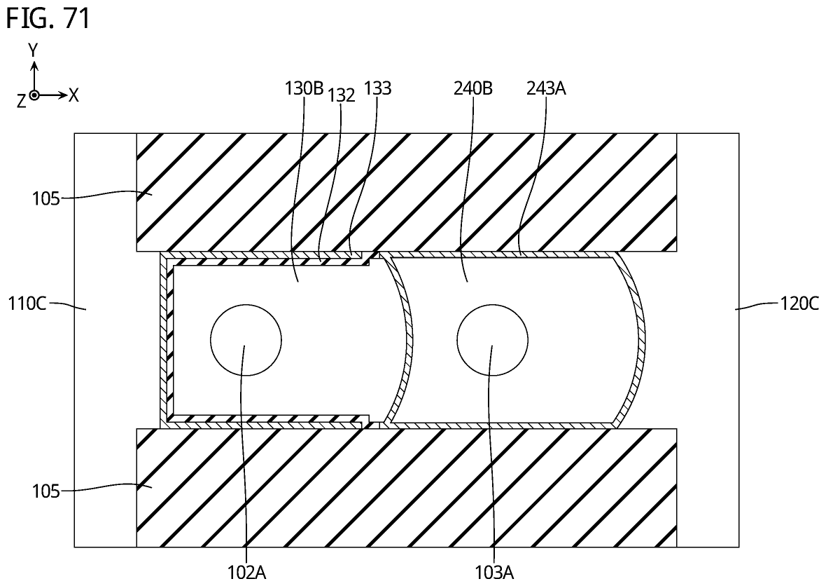

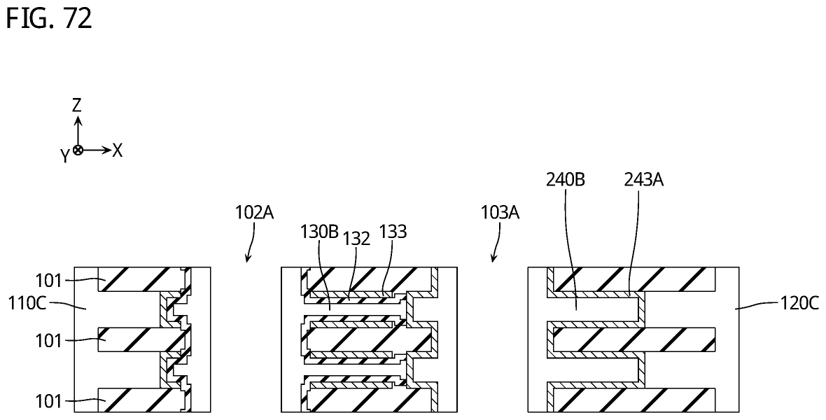

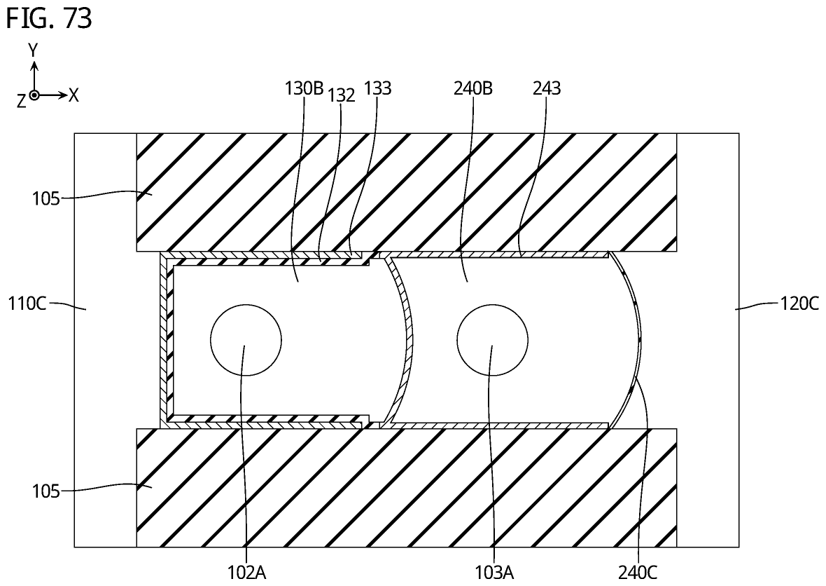

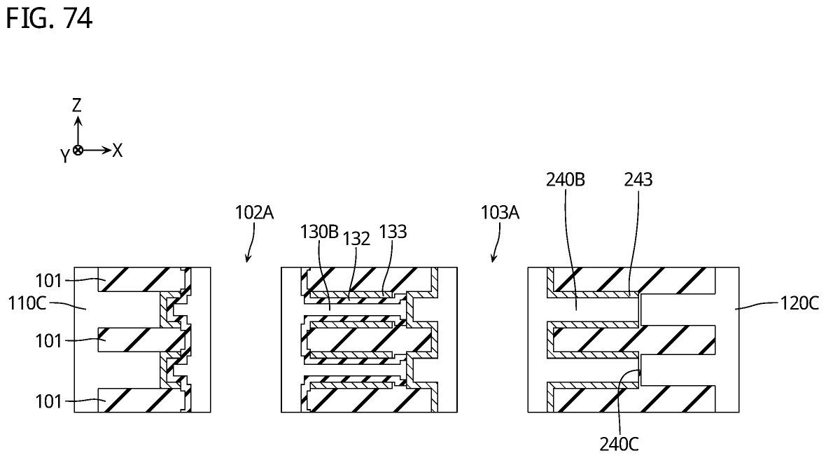

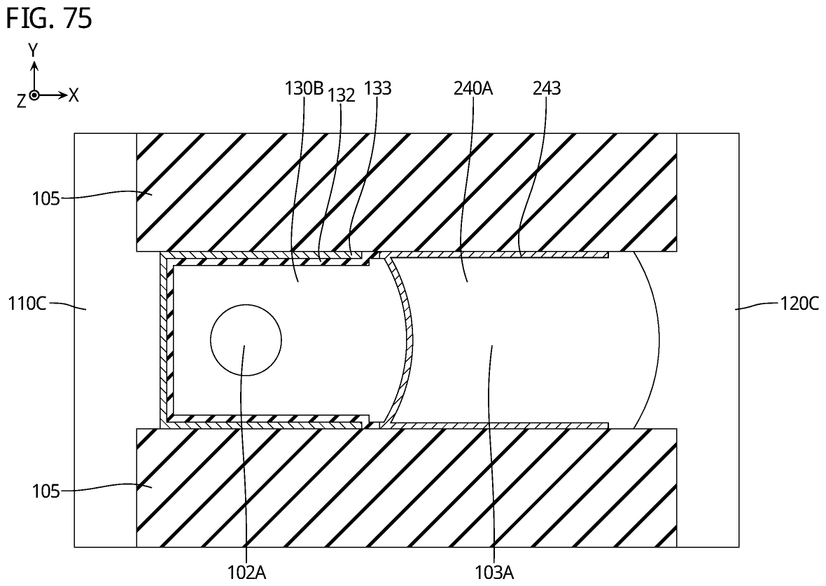

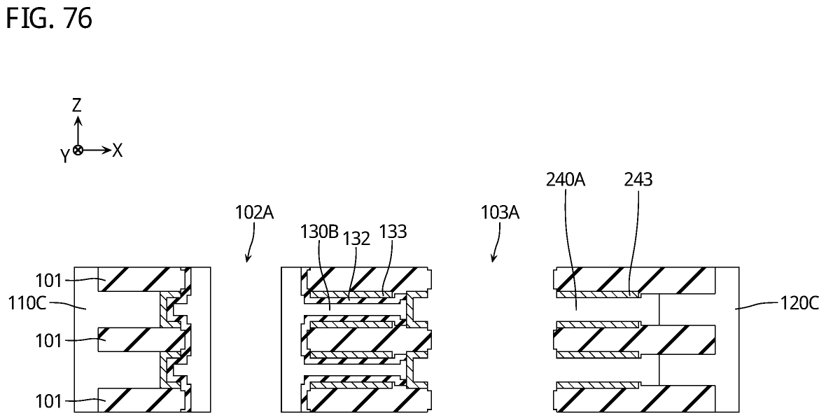

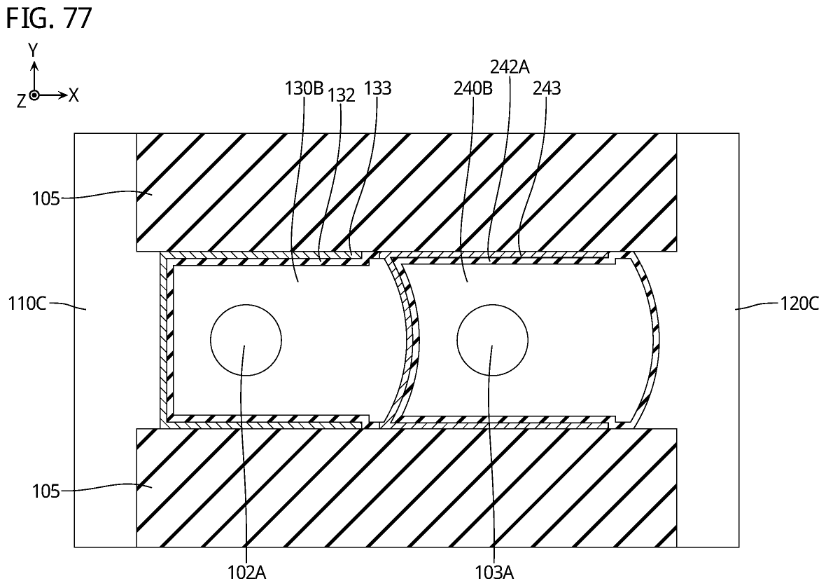

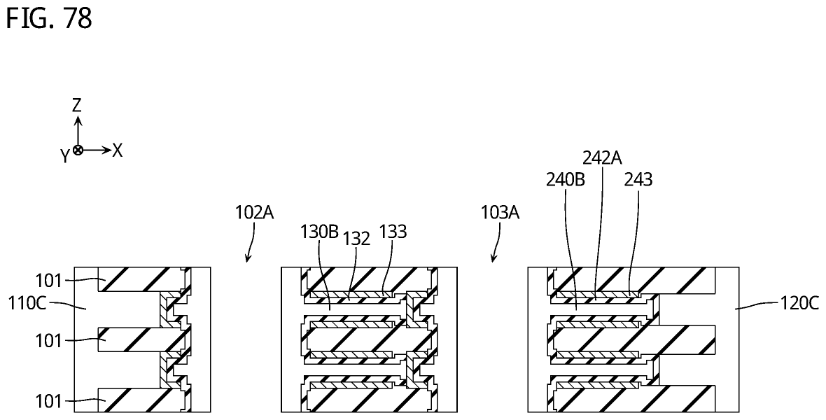

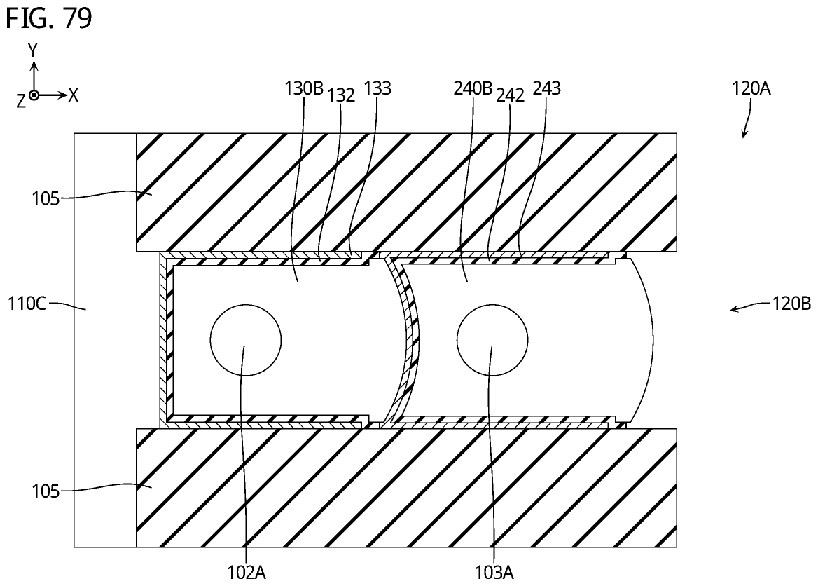

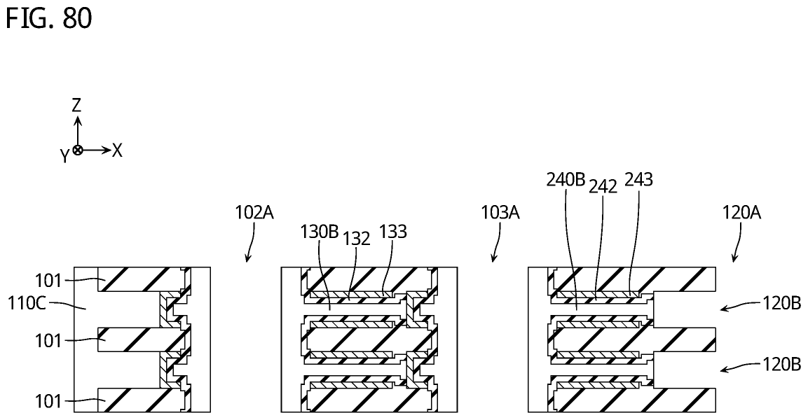

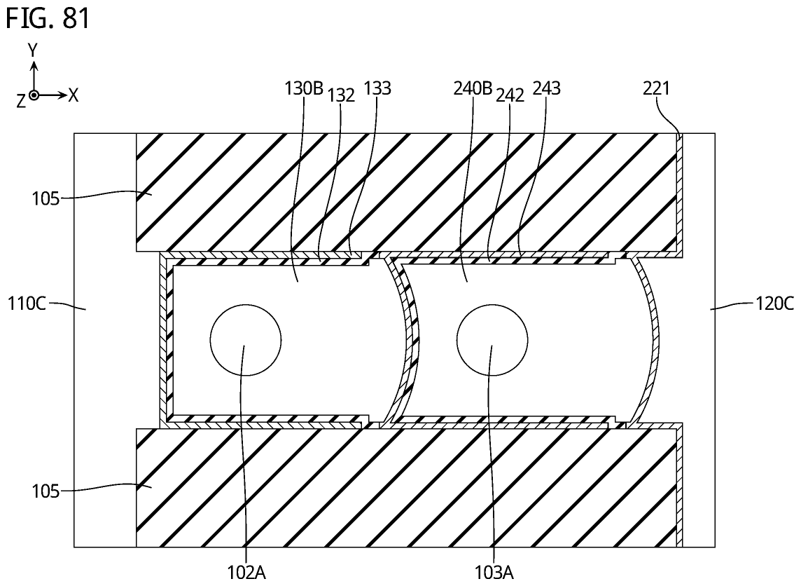

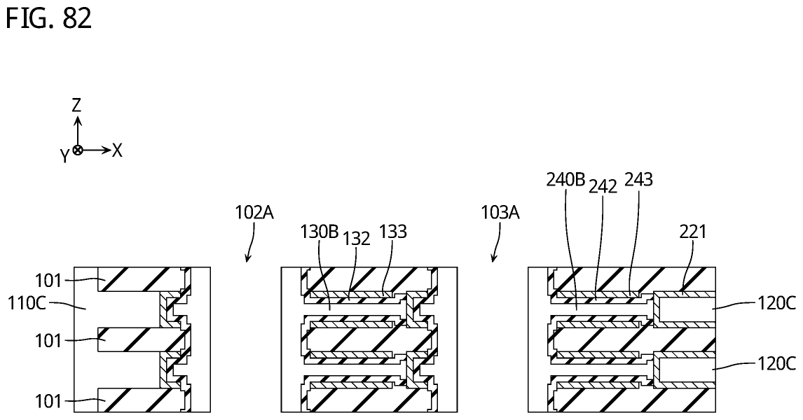

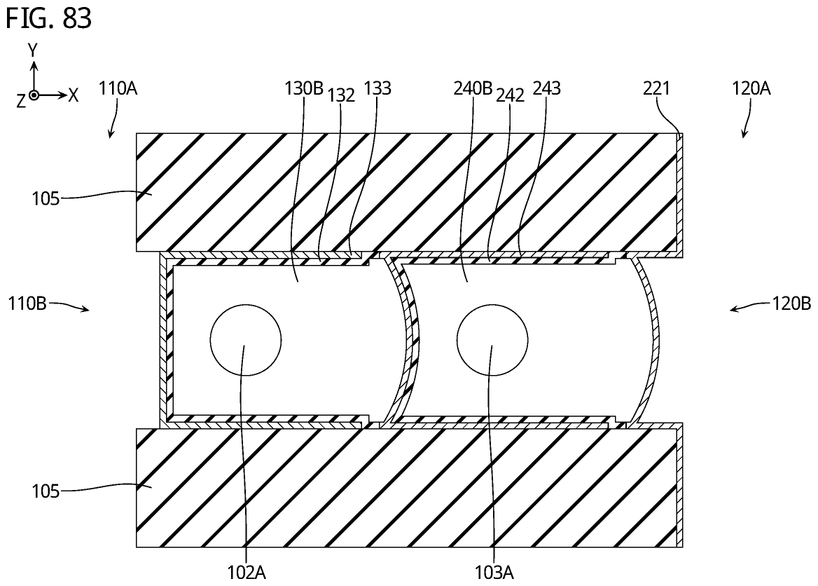

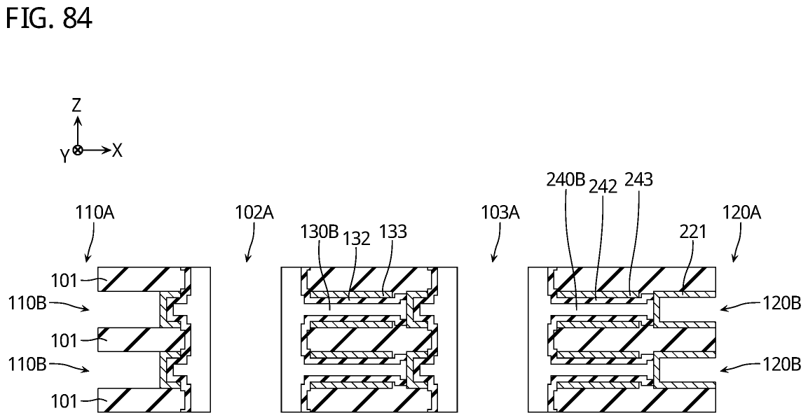

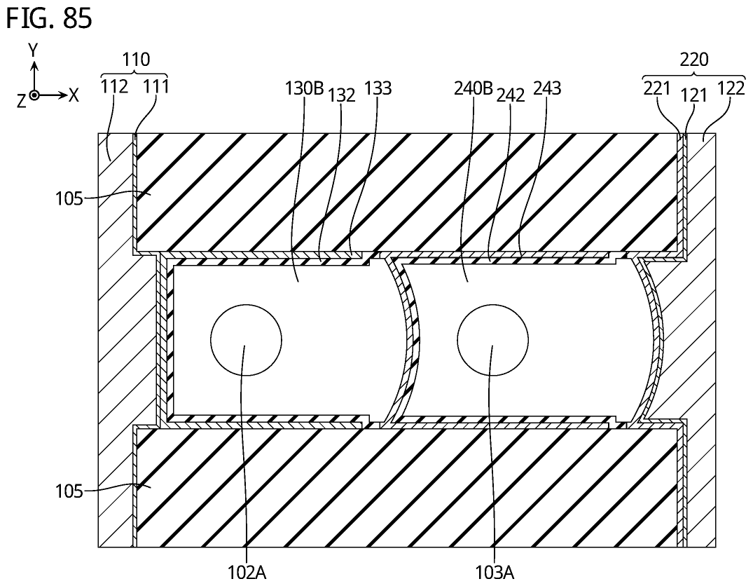

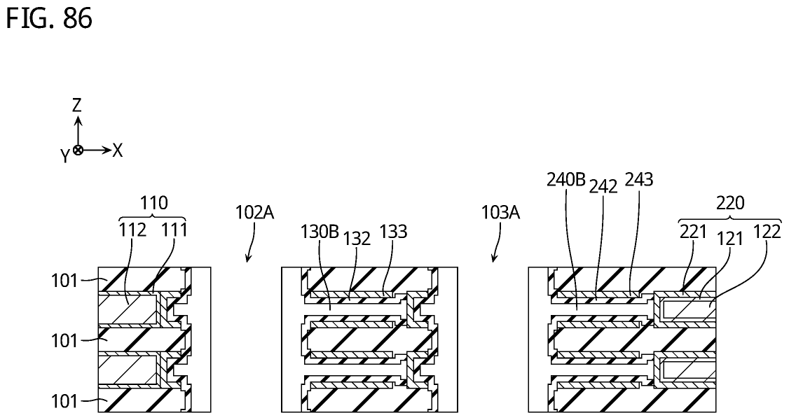

FIG. 49 to FIG. 86 are schematic cross-sectional views for describing a method for manufacturing the semiconductor memory device according to the second embodiment. FIG. 49, FIG. 51, FIG. 53, FIG. 55, FIG. 57, FIG. 59, FIG. 61, FIG. 63, FIG. 65, FIG. 67, FIG. 69, FIG. 71, FIG. 73, FIG. 75, FIG. 77, FIG. 79, FIG. 81, FIG. 83, and FIG. 85 illustrate cross-sectional surfaces corresponding to FIG. 47. FIG. 50, FIG. 52, FIG. 54, FIG. 56, FIG. 58, FIG. 60, FIG. 62, FIG. 64, FIG. 66, FIG. 68, FIG. 70, FIG. 72, FIG. 74, FIG. 76, FIG. 78, FIG. 80, FIG. 82, FIG. 84, and FIG. 86 illustrate cross-sectional surfaces corresponding to FIG. 48.

In the manufacturing method, for example, as illustrated in FIG. 49 and FIG. 50, the processes up to the process described with reference to FIG. 11 and FIG. 12 in the manufacturing process of the semiconductor memory device according to the first embodiment are performed.

Next, for example, as illustrated in FIG. 51 and FIG. 52, a sacrifice layer 103B of silicon (Si) or the like is formed inside an opening 103A. This process is performed by, for example, CVD. Although not illustrated, after the end of this process, an upper portion of the opening 103A is closed by an insulating layer or the like.

At a position corresponding to the transistor structure 130, an opening 130A is formed. A part of the upper surface and a part of the lower surface of the insulating layer 101, a part of the side surface of the sacrifice layer MLA in the X-direction, a part of the side surface of the insulating layer 105 in the Y-direction, and a part of a side surface of the sacrifice layer 110C in the X-direction are exposed inside the opening 130A. In this process, for example, a part of the sacrifice layer MLA is selectively removed via the opening 102A. This process is performed by, for example, wet etching.

Next, for example, as illustrated in FIG. 53 and FIG. 54, a conductive layer 133A and a sacrifice layer 130B are formed inside the opening 130A and the opening 102A. This process is performed, for example, similarly to the process described with reference to FIG. 15 and FIG. 16.

Next, for example, as illustrated in FIG. 55 and FIG. 56, the sacrifice layer 103B is removed. This process is performed by, for example, wet etching.

Next, for example, as illustrated in FIG. 57 and FIG. 58, an opening 240A is formed at a position corresponding to the transistor structure 240. A part of the upper surface and a part of the lower surface of the insulating layer 101, a part of the side surface of the conductive layer 133A in the X-direction, a part of the side surface of the insulating layer 105 in the Y-direction, and a part of a side surface of the sacrifice layer 120C in the X-direction are exposed inside the opening 240A. In this process, for example, the sacrifice layer MLA is removed via the opening 103A. This process is performed by, for example, wet etching.

Next, for example, as illustrated in FIG. 59 and FIG. 60, a part of the conductive layer 133A is removed to expose the side surface of the sacrifice layer 130B on one side in the X-direction. This process is performed, for example, similarly to the process described with reference to FIG. 25 and FIG. 26.

Next, for example, as illustrated in FIG. 61 and FIG. 62, an oxidation process is performed on the sacrifice layers 130B, 120C via the openings 103A, 240A to form insulating layers 130C, 120D. Further, a sacrifice layer 240B of silicon (Si) or the like is formed inside the openings 103A, 240A. This process is performed by, for example, CVD. Although not illustrated, after the end of this process, an upper portion of the opening 103A is closed by an insulating layer or the like.

Next, for example, as illustrated in FIG. 63 and FIG. 64, the sacrifice layer 130B is removed. This process is performed by, for example, wet etching. In this process, a surface exposed to the opening 102A of the conductive layer 133A is removed, and the conductive layer 133A is separated in the Z-direction.

Next, for example, as illustrated in FIG. 65 and FIG. 66, the insulating layer 130C and a part of the sacrifice layer 240B are removed. This process is performed by, for example, wet etching.

Next, for example, as illustrated in FIG. 67 and FIG. 68, an insulating layer 132A and the sacrifice layer 130B are formed inside the openings 102A, 130A. This process is performed, for example, similarly to the process described with reference to FIG. 33 and FIG. 34.

Next, for example, as illustrated in FIG. 69 and FIG. 70, the sacrifice layer 240B is removed. This process is performed by, for example, wet etching.

Further, a part of the insulating layer 132A is formed. This process is performed, for example, similarly to the process described with reference to FIG. 37 and FIG. 38. In this process, the insulating layer 120D is also removed.

Next, for example, as illustrated in FIG. 71 and FIG. 72, a conductive layer 243A and the sacrifice layer 240B are formed inside the opening 240A and the opening 103A. This process is performed, for example, similarly to the process described with reference to FIG. 15 and FIG. 16.

Next, for example, as illustrated in FIG. 73 and FIG. 74, a part of the conductive layer 243A is removed to expose the side surface of the sacrifice layer 240B on one side in the X-direction. In this process, for example, the sacrifice layer 120C is removed by wet etching or the like, and further, a process similar to the process described with reference to FIG. 25 and FIG. 26 is performed.

An oxidation process is performed on the sacrifice layer 240B via the openings 120A, 120B to form an insulating layer 240C. Further, the sacrifice layer 120C of silicon (Si) or the like is formed inside the openings 120A, 120B. This process is performed by, for example, CVD.

Next, for example, as illustrated in FIG. 75 and FIG. 76, the sacrifice layer 240B is removed. This process is performed by, for example, wet etching. In this process, a surface exposed to the opening 103A of the conductive layer 243A is removed, and the conductive layer 243A is separated in the Z-direction.

The insulating layer 240C and a part of the sacrifice layer 120C are removed. This process is performed by, for example, wet etching.

Next, for example, as illustrated in FIG. 77 and FIG. 78, an insulating layer 242A and the sacrifice layer 240B are formed inside the openings 103A, 240A. This process is performed, for example, similarly to the process described with reference to FIG. 33 and FIG. 34. Although not illustrated, after the end of this process, the upper portion of the opening 103A is closed by an insulating layer or the like.

Next, for example, as illustrated in FIG. 79 and FIG. 80, the sacrifice layer 120C is removed. This process is performed by, for example, wet etching.

A part of the insulating layer 242A is formed to expose a side surface of the sacrifice layer 240B on one side in the X-direction. This process is performed, for example, similarly to the process described with reference to FIG. 37 and FIG. 38.

Next, for example, as illustrated in FIG. 81 and FIG. 82, the conductive oxide film 221 and the sacrifice layer 120C are formed at the opening 120B. This process is performed by, for example, ALD, CVD, and wet etching.

Next, for example, as illustrated in FIG. 83 and FIG. 84, the sacrifice layers 110C, 120C are removed. This process is performed by, for example, wet etching. In this process, a surface exposed to the opening 102A of the conductive oxide film 221 is removed, and the conductive oxide film 221 is separated in the Z-direction.

Next, for example, as illustrated in FIG. 85 and FIG. 86, the wirings 110, 220 are formed inside the openings 110B, 120B. This process is performed by, for example, CVD.

Then, the sacrifice layer 130B and the sacrifice layer 240B are removed, and for example, as illustrated in FIG. 47 and FIG. 48, the semiconductor layers 131, 241 are formed inside the openings 130A, 240A. The via-wirings 102, 103 are formed inside the openings 102A, 103A. This process is performed by, for example, ALD and CVD.

### [Effects]

As described above, the semiconductor memory device according to the second embodiment does not include the conductive member 150 or the insulating member 104, and the semiconductor layer 131 in the transistor structure 130 is directly connected to the conductive layer 243. With this configuration, the area per memory cell MC can be reduced compared with the semiconductor memory device according to the first embodiment. Therefore, according to the second embodiment, the high integration of the semiconductor memory device can be achieved.

### Third Embodiment

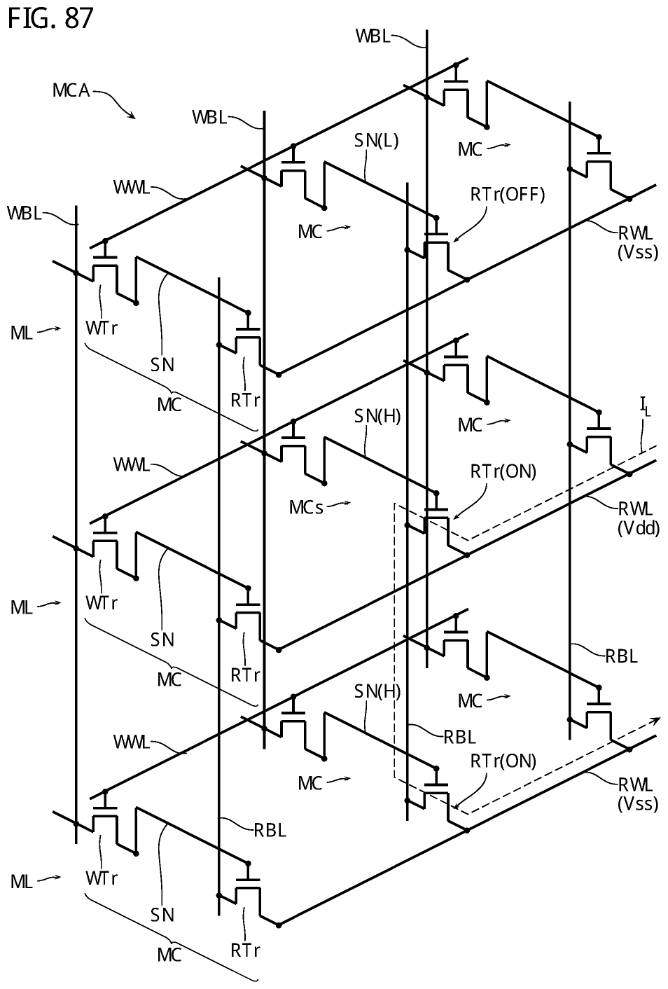

FIG. 87 is a schematic circuit diagram illustrating a configuration of a part of the semiconductor memory device according to the first embodiment. FIG. 87 illustrates a state of the read operation of the semiconductor memory device.

As described with reference to FIG. 1, in the read operation of the semiconductor memory device according to the first embodiment, for example, the power supply voltage Vdd is applied to a read word line RWL that is a target of the read operation and the ground voltage Vss is applied to the other read word lines RWL among the plurality of read word lines RWL. Here, when the sense node SN of a selected memory cell MCs is charged with the power supply voltage Vdd, since the read transistor RTr turns ON, the voltage of the read bit line RBL increases.

Here, the read bit line RBL is connected to the plurality of read word lines RWL via the plurality of read transistors RTr. Therefore, when the voltage of the read bit line RBL increases, a leakage current IL from the read bit line RBL to the read word line RWL is generated via the memory cell MC in the ON state among the memory cells MC that are not the target of the read operation in some cases. In association with this, the current flowing through the read bit line RBL decreases, and an electric charge of the read bit line RBL is discharged. This possibly increases the time taken for the read operation, or possibly causes a failure in appropriate execution of the read operation.

Therefore, in a semiconductor memory device according to the third embodiment, a transistor is added to the memory cell MC, thereby reducing the generation of such a leakage current IL.

The semiconductor memory device according to the third embodiment is described below with reference to the drawings. In the following description, the same reference numerals are attached to configurations similar to those in the first embodiment, and the explanation is omitted.

### [Circuit Configuration]

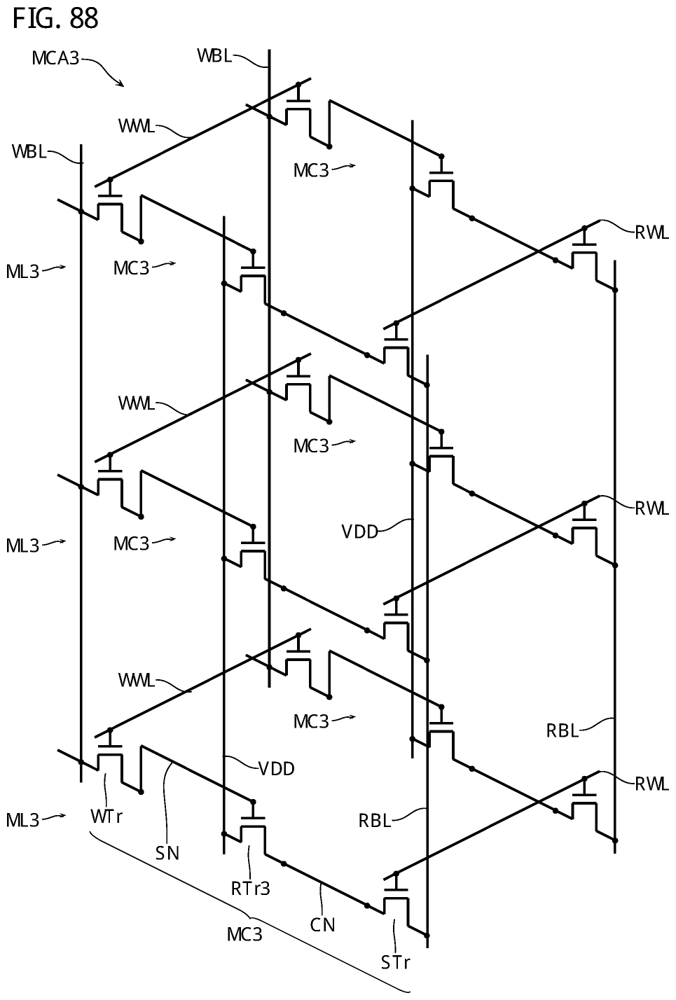

FIG. 88 is a schematic circuit diagram illustrating a configuration of a part of the semiconductor memory device according to the third embodiment.

As illustrated in FIG. 88, the semiconductor memory device according to the embodiment includes a memory cell array MCA3. The memory cell array MCA3 includes a plurality of memory layers ML3, a plurality of write bit lines WBL connected to these plurality of memory layers ML3, a plurality of voltage supply lines VDD connected to the plurality of memory layers ML3, and a plurality of read bit lines RBL connected to the plurality of memory layers ML3. The voltage supply lines VDD supply the power supply voltage Vdd.

Each of the memory layers ML3 includes a write word line WWL, a read word line RWL, and a plurality of memory cells MC3 connected to these write word line WWL and read word line RWL. Each of the memory cells MC3 includes a write transistor WTr, a sense node SN, a read transistor RTr3, a connection node CN, and a switch transistor STr.

The read transistor RTr3 is, for example, a field-effect type NMOS transistor. The read transistor RTr3 has one electrode connected to the voltage supply line VDD. The read transistor RTr3 has the other electrode connected to the connection node CN. The one and the other electrodes of the read transistor RTr3 function as a source electrode or a drain electrode corresponding to a voltage applied to the read transistor RTr3. The read transistor RTr3 has a gate electrode connected to the sense node SN.

The switch transistor STr is, for example, a field-effect type NMOS transistor. The switch transistor STr has one electrode connected to the read bit line RBL. The switch transistor STr has the other electrode connected to the connection node CN. The one and the other electrodes of the switch transistor STr function as a source electrode or a drain electrode corresponding to a voltage applied to the switch transistor STr. The switch transistor STr has a gate electrode connected to the read word line RWL.

The write operation of the semiconductor memory device according to the third embodiment can be executed similarly to the write operation of the semiconductor memory device according to the first embodiment.

The read operation of the semiconductor memory device according to the third embodiment can be basically executed similarly to the read operation of the semiconductor memory device according to the first embodiment. However, in the read operation of the semiconductor memory device according to the third embodiment, the power supply voltage Vdd is applied to the voltage supply line VDD.

Here, also in the third embodiment, in the read operation, a power supply voltage Vdd is applied to a read word lines RWL that is a target of the read operation and a ground voltage Vss is applied to the other read word lines RWL among the plurality of read word lines RWL. This causes the switch transistors STr in the memory layer ML3 that is the target of the read operation to turn ON, and causes the switch transistors STr in the other memory layers ML3 to turn OFF. Therefore, the read bit line RBL is electrically conducted with the read transistors RTr3 in the memory layer ML3 that is the target of the read operation, and electrically separated from the read transistors RTr3 in the other memory layers ML3. This enables reducing the generation of the leakage current IL as described above.

### [Structure]

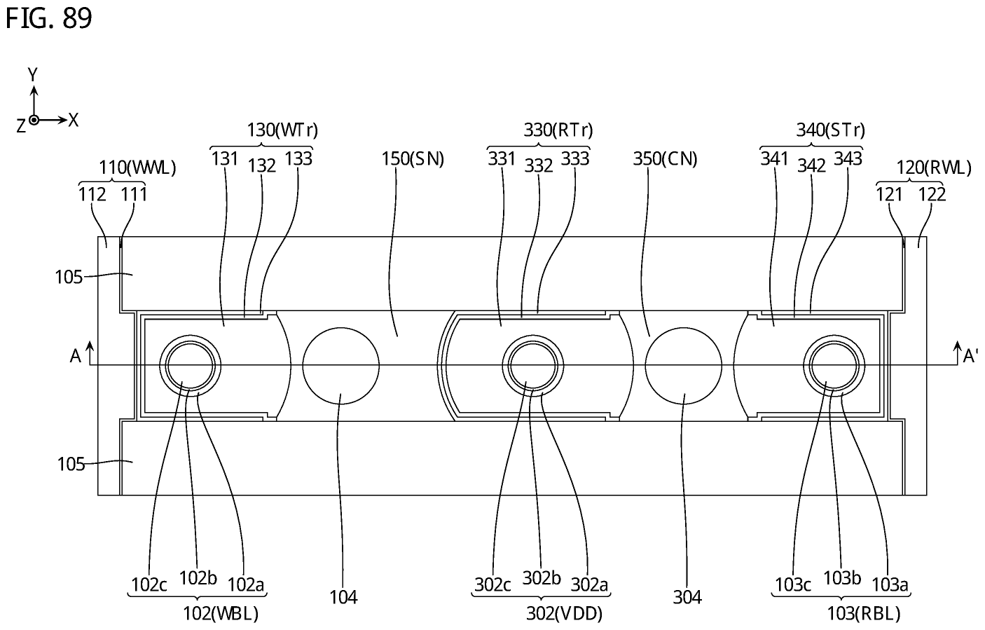

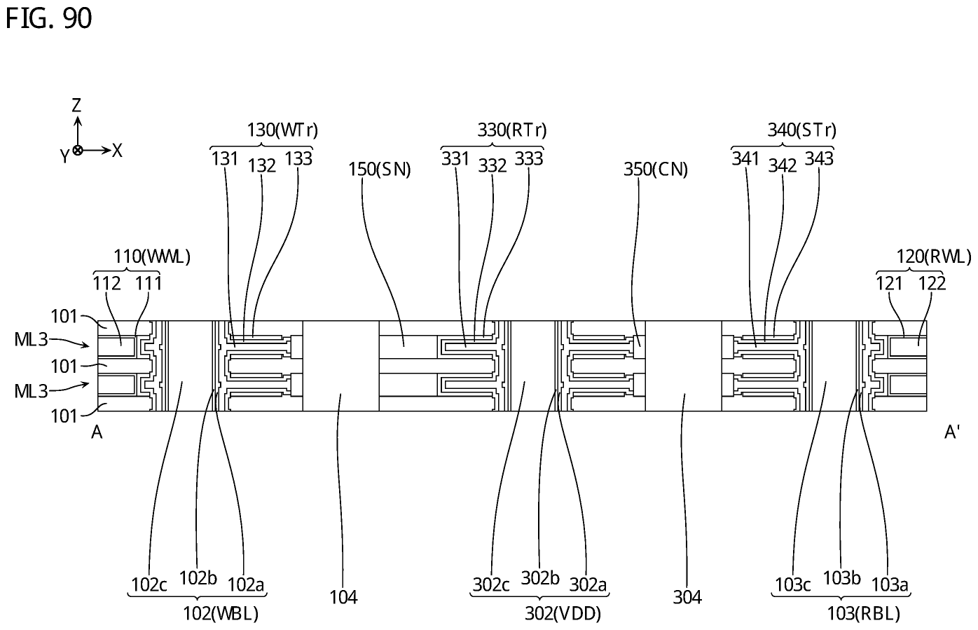

FIG. 89 is a schematic XY cross-sectional view illustrating a configuration of a part of the semiconductor memory device according to the third embodiment. FIG. 90 is a schematic cross-sectional view illustrating a configuration of a part of the semiconductor memory device, and illustrates a configuration of the structure illustrated in FIG. 89 taken along the line A-A′ when viewed in the arrow direction.

The memory cell array MCA3 includes a plurality of memory layers ML3 arranged in the Z-direction. Insulating layers 101 of silicon oxide (SiO₂) or the like are each disposed between the plurality of memory layers ML3.

The memory cell array MCA3 includes via-wirings 102, 302, 103. The via-wiring 302 functions as the voltage supply line VDD. The via-wirings 102, 302, 103 are sequentially arranged in the X-direction, and penetrate the plurality of memory layers ML3 to extend in the Z-direction.

The via-wiring 302 includes, for example, a conductive oxide film 302a containing a conductive oxide, a barrier conductive film 302b of titanium nitride (TiN) or the like, and a conductive member 302c of tungsten (W) or the like. The via-wiring 302 may contain any metal including ruthenium (Ru), iridium (Ir), or another metal instead of the conductive oxide film 302a. The via-wiring 302 may contain only the conductive oxide, or may contain only ruthenium (Ru), iridium (Ir), or another metal.

The conductive member 302c has an approximately columnar shape extending in the Z-direction. The barrier conductive film 302b has an approximately cylindrical shape extending in the Z-direction along an outer peripheral surface of the conductive member 302c. The conductive oxide film 302a has an approximately cylindrical shape extending in the Z-direction along an outer peripheral surface of the barrier conductive film 302b.

The memory cell array MCA3 includes insulating members 104, 304 of silicon oxide (SiO₂) or the like. The insulating member 104 is disposed between the via-wirings 102, 302, and penetrates the plurality of memory layers ML3 to extend in the Z-direction. The insulating member 304 is disposed between the via-wirings 302, 103, and penetrates the plurality of memory layers ML3 to extend in the Z-direction.

The memory layer ML3 includes wirings 110, 120 arranged in the X-direction and extending in the Y-direction, transistor structures 130, 340 disposed between these wirings 110, 120, a transistor structure 330 disposed between these transistor structures 130, 340, a conductive member 150 disposed between the transistor structures 130, 330, and a conductive member 350 disposed between the transistor structures 330, 340. The transistor structures 130, 330, 340 are provided at positions corresponding to the via-wirings 102, 302, 103, respectively. The conductive member 150 is provided at a position corresponding to the insulating member 104. The conductive member 350 is provided at a position corresponding to the insulating member 304. In the example of the drawing, the transistor structures 130, 330, 340 and the conductive members 150, 350 are arranged in the X-direction.

The transistor structure 330 is basically configured similarly to the transistor structure 140. However, the transistor structure 330 includes a semiconductor layer (semiconductor portion) 331, an insulating layer (insulating portion) 332, and a conductive layer 333 instead of the semiconductor layer 141, the insulating layer 142, and the conductive layer 143.

The semiconductor layer 331, the insulating layer 332, and the conductive layer 333 are basically configured similarly to the semiconductor layer 141, the insulating layer 142, and the conductive layer 143.

However, in an XY cross-sectional surface as exemplified in FIG. 89, a side surface of the semiconductor layer 331 on one side (wiring 120 side) in the X-direction may be formed along a circle with a center position of the via-wiring 302 as its center. Additionally, side surfaces of the semiconductor layer 331, the insulating layer 332, and the conductive layer 333 on the other side (wiring 110 side) in the X-direction may be formed along a circle with a center position of the via-wiring 302 as its center.

The conductive layer 333 is disposed at a position overlapping with the semiconductor layer 331 and not overlapping with a semiconductor layer 341 when viewed in the Z-direction.

For example, as illustrated in FIG. 89, the transistor structure 340 includes the semiconductor layer (semiconductor portion) 341 connected to an outer peripheral surface of the via-wiring 103 and extending in the X-direction, an insulating layer (insulating portion) 342 disposed on an upper surface, a lower surface, both side surfaces in the Y-direction, and a side surface on one side (wiring 120 side) in the X-direction of the semiconductor layer 341, and a conductive layer 343 disposed on an upper surface, a lower surface, both side surfaces in the Y-direction, and a side surface on one side (wiring 120 side) in the X-direction of the insulating layer 342.

In an XY cross-sectional surface as exemplified in FIG. 89, a side surface of the semiconductor layer 341 on one side (wiring 110 side) in the X-direction may be formed along a circle with a center position of the via-wiring 103 as its center. Additionally, side surfaces of the semiconductor layer 341, the insulating layer 342, and the conductive layer 343 on the other side (wiring 120 side) in the X-direction may be formed in a straight line along a side surface of the wiring 120. Both side surfaces of the semiconductor layer 341, the insulating layer 342, and the conductive layer 343 in the Y-direction may be formed in a straight line along a side surface of the insulating layer 105.

The semiconductor layer 341 functions as, for example, a channel region of the switch transistor STr (FIG. 88). The semiconductor layer 341, for example, may be a semiconductor containing at least one element of gallium (Ga) or aluminum (Al), and containing indium (In), zinc (Zn), and oxygen (O) or may be other oxide semiconductors. The plurality of semiconductor layers 341 arranged in the Z-direction are connected to the via-wiring 103 extending in the Z-direction in common.

The insulating layer 342 functions as, for example, a gate insulating film of the switch transistor STr (FIG. 88). The insulating layer 342 contains, for example, silicon oxide (SiO₂).

The conductive layer 343 functions as, for example, a gate electrode of the switch transistor STr (FIG. 88). The conductive layer 343 contains, for example, a conductive material, such as titanium nitride (TiN), or a conductive oxide, such as indium tin oxide (ITO). The conductive layer 343 is opposed to the upper surface, the lower surface, both side surfaces in the Y-direction, and the side surface on one side (wiring 120 side) in the X-direction of the semiconductor layer 341 via the insulating layer 342. The conductive layer 343 is disposed at a position overlapping with the semiconductor layer 341 and not overlapping with the semiconductor layer 331 when viewed in the Z-direction.

### [Manufacturing Method]

The semiconductor memory device according to the third embodiment can be basically manufactured similarly to the semiconductor memory device according to the first embodiment.

However, in the manufacture of the semiconductor memory device according to the third embodiment, in the process described with reference to FIG. 11 and FIG. 12, an opening is formed also at a position corresponding to the via-wiring 302.

In the process described with reference to FIG. 21 and FIG. 22, an opening is formed also at a position corresponding to the insulating member 304.

In the process described with reference to FIG. 35 and FIG. 36, the sacrifice layer 120C is not removed, and alternatively, a sacrifice layer inside the opening provided at the position corresponding to the insulating member 304 is removed.

### Fourth Embodiment

In the second embodiment, the conductive member 150 and the insulating member 104 are omitted from the semiconductor memory device according to the first embodiment, thereby attempting the high integration of the semiconductor memory device according to the first embodiment. Here, the high integration of the semiconductor memory device according to the third embodiment also can be attempted by omitting the conductive members 150, 350 and the insulating members 104, 304 from the semiconductor memory device according to the third embodiment.

A semiconductor memory device according to the fourth embodiment is described below with reference to the drawings. In the following description, the same reference numerals are attached to configurations similar to those in the first embodiment to the third embodiment, and the explanation is omitted.

### [Structure]

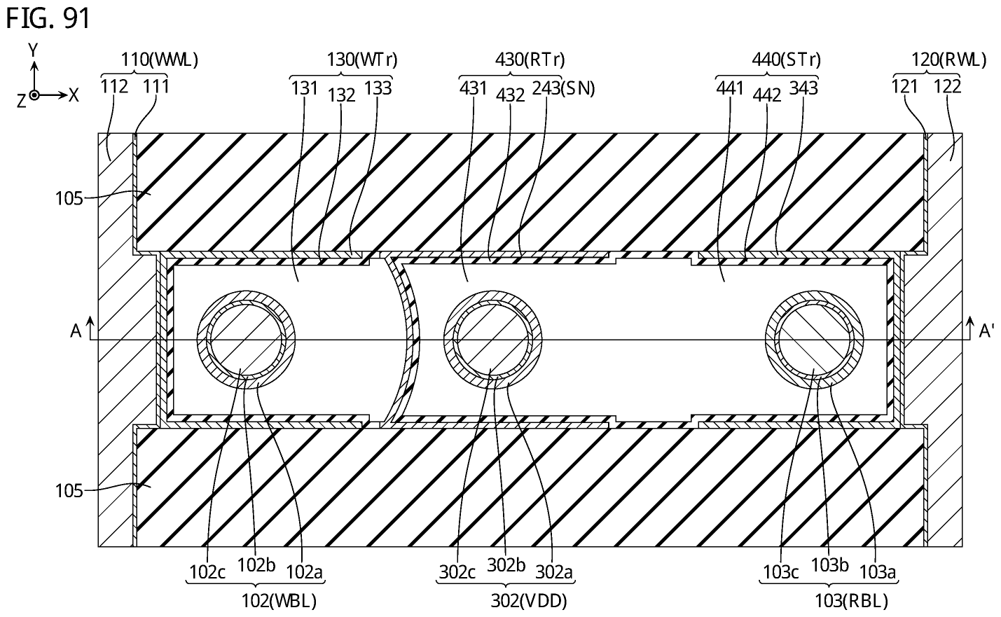

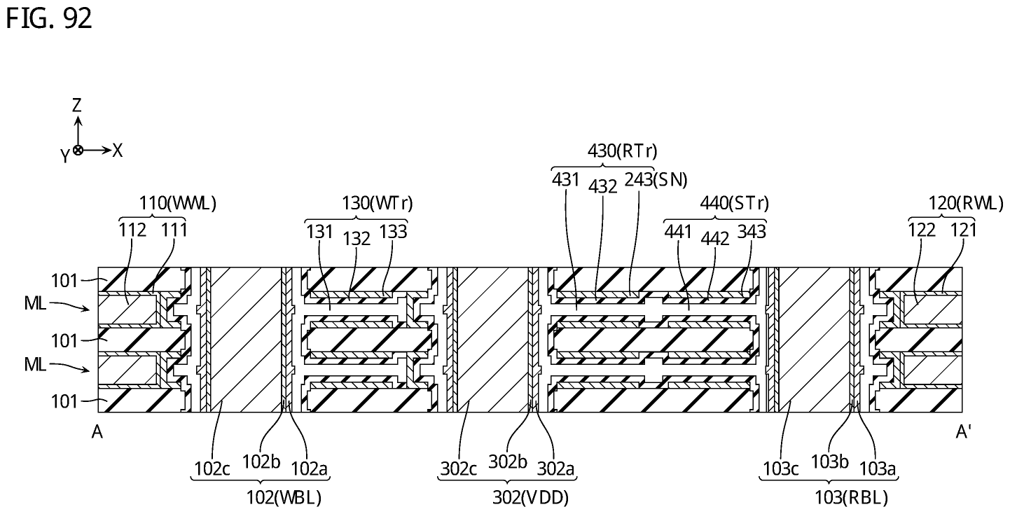

FIG. 91 is a schematic XY cross-sectional view illustrating a configuration of a part of the semiconductor memory device. FIG. 92 is a schematic cross-sectional view illustrating a configuration of a part of the semiconductor memory device, and illustrates a configuration of the structure illustrated in FIG. 91 taken along the line A-A′ when viewed in the arrow direction.

The semiconductor memory device according to the fourth embodiment is basically configured similarly to the semiconductor memory device according to the third embodiment.

However, the semiconductor memory device according to the fourth embodiment does not include the conductive member 150 or the insulating member 104, and the semiconductor layer 131 in the transistor structure 130 is directly connected to a conductive layer 243 in a transistor structure 430 described later.

The semiconductor memory device according to the fourth embodiment does not include the transistor structures 330, 340, the conductive member 350, or the insulating member 304, but includes transistor structures 430, 440 instead thereof.

The transistor structure 430 is basically configured similarly to the transistor structure 240 (FIG. 47, FIG. 48). However, the transistor structure 430 includes a semiconductor portion 431 and an insulating portion 432 instead of the semiconductor layer 241 and the insulating layer 242.

The transistor structure 440 is basically configured similarly to the transistor structure 340 (FIG. 89, FIG. 90). However, the transistor structure 440 includes a semiconductor portion 441 and an insulating portion 442 instead of the semiconductor layer 341 and the insulating layer 342.

The semiconductor portion 431 and the insulating portion 432 are basically configured similarly to the semiconductor layer 241 and the insulating layer 242. The semiconductor portion 441 and the insulating portion 442 are basically configured similarly to the semiconductor layer 341 and the insulating layer 342.

However, the semiconductor portion 431 is continuous with the semiconductor portion 441, and the semiconductor portion 431 and the semiconductor portion 441 are directly connected to one another. Each of the semiconductor portion 431 and the semiconductor portion 441 is a part of one semiconductor layer extending in the X-direction. Similarly, the insulating portion 432 is continuous with the insulating portion 442, and the insulating portion 432 and the insulating portion 442 are directly connected to one another. Each of the insulating portion 432 and the insulating portion 442 is a part of one insulating layer.

In this embodiment, the conductive layer 243 is disposed at a position overlapping with the semiconductor portion 431 and not overlapping with the semiconductor portion 441 when viewed in the Z-direction. The conductive layer 343 is disposed at a position overlapping with the semiconductor portion 441 and not overlapping with the semiconductor portion 431 when viewed in the Z-direction.

### [Manufacturing Method]

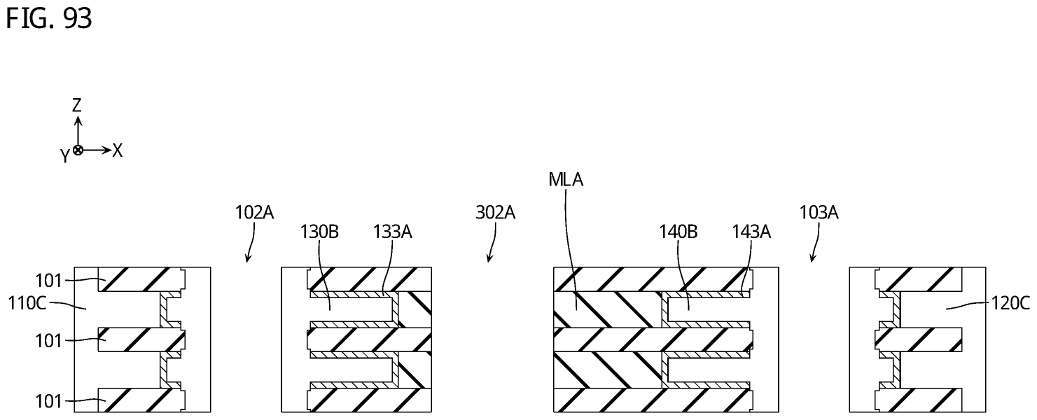

FIG. 93 to FIG. 103 are schematic cross-sectional views for describing a method for manufacturing the semiconductor memory device according to the fourth embodiment. FIG. 93 to FIG. 103 illustrate cross-sectional surfaces corresponding to FIG. 92.

In the manufacturing method, for example, as illustrated in FIG. 93, the processes up to the process described with reference to FIG. 19 and FIG. 20 in the manufacturing process of the semiconductor memory device according to the first embodiment are performed.

Further, at a position corresponding to the via-wiring 302, an opening 302A is formed. The opening 302A extends in the Z-direction and penetrates a plurality of insulating layers 101 and a plurality of sacrifice layers MLA arranged in the Z-direction. This process is performed by, for example, RIE.

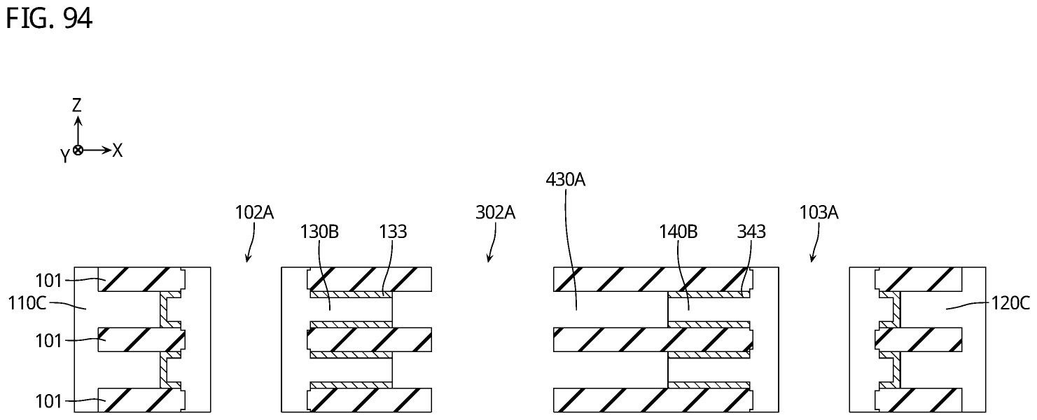

Next, for example, as illustrated in FIG. 94, an opening 430A is formed at a position corresponding to the transistor structure 430. A part of an upper surface and a part of a lower surface of the insulating layer 101, a part of a side surface of the conductive layer 143A in the X-direction, a part of a side surface of the insulating layer 105 in the Y-direction, and a part of a side surface of the conductive layer 133A in the X-direction are exposed inside the opening 430A. In this process, for example, the sacrifice layer MLA is selectively removed via the opening 302A. This process is performed by, for example, wet etching.

Further, the conductive layers 133, 343 are formed. The conductive layer 133 is formed, for example, similarly to the process described with reference to FIG. 25 and FIG. 26. A part of the conductive layer 143A covering a side surface of the sacrifice layer 140B on one side in the X-direction (side surface on the opening 110A side) is removed. This causes the side surface of the sacrifice layer 140B on one side in the X-direction to be exposed inside the opening 430A. This process is performed by, for example, wet etching.

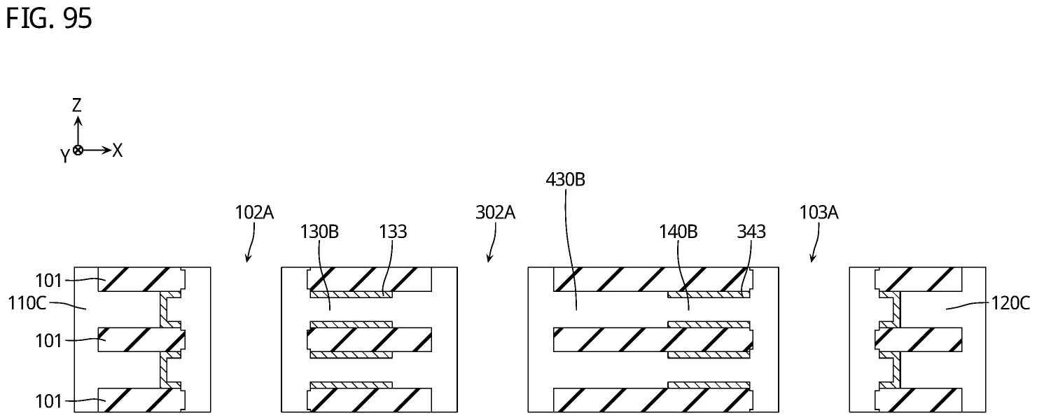

Next, for example, as illustrated in FIG. 95, a sacrifice layer 430B of silicon (Si) or the like is formed inside the opening 302A and the opening 430A. This process is performed by, for example, CVD. Although not illustrated, after the end of this process, an upper portion of the opening 302A is closed by an insulating layer or the like.

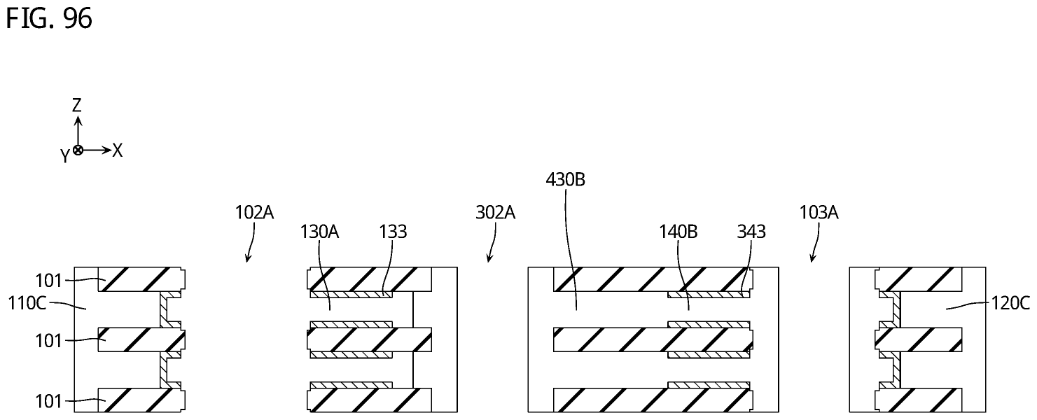

Next, for example, as illustrated in FIG. 96, the sacrifice layer 130B is removed. This process is performed by, for example, wet etching.

Further, a part of the sacrifice layer 430B is removed. This process is performed by, for example, wet etching.

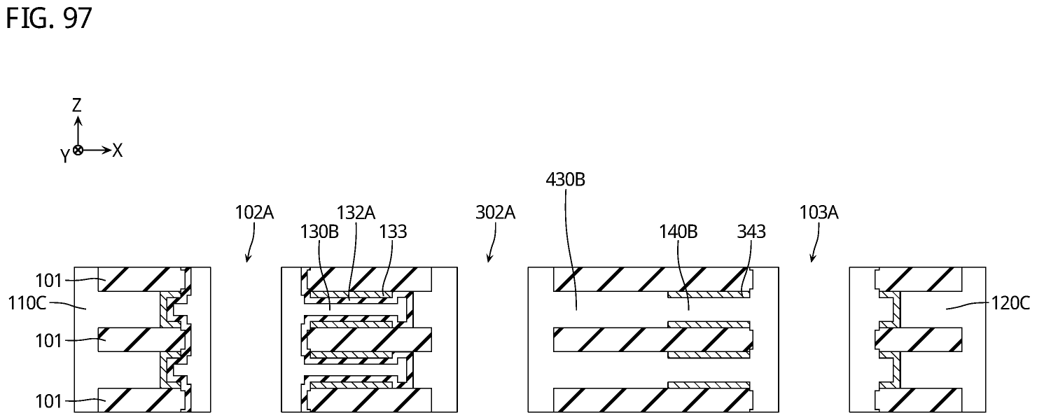

Next, for example, as illustrated in FIG. 97, an insulating layer 132A and the sacrifice layer 130B are formed inside the openings 130A, 102A. This process is performed, for example, similarly to the process described with reference to FIG. 33 and FIG. 34.

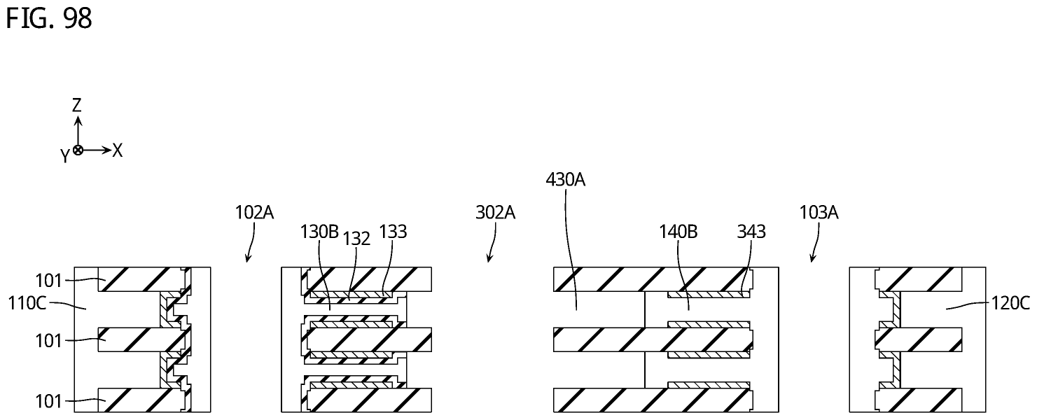

Next, for example, as illustrated in FIG. 98, the sacrifice layer 430B is removed. This process is performed by, for example, wet etching.

Further, the insulating layer 132 is formed. This process is performed, for example, similarly to the process described with reference to FIG. 37 and FIG. 38.

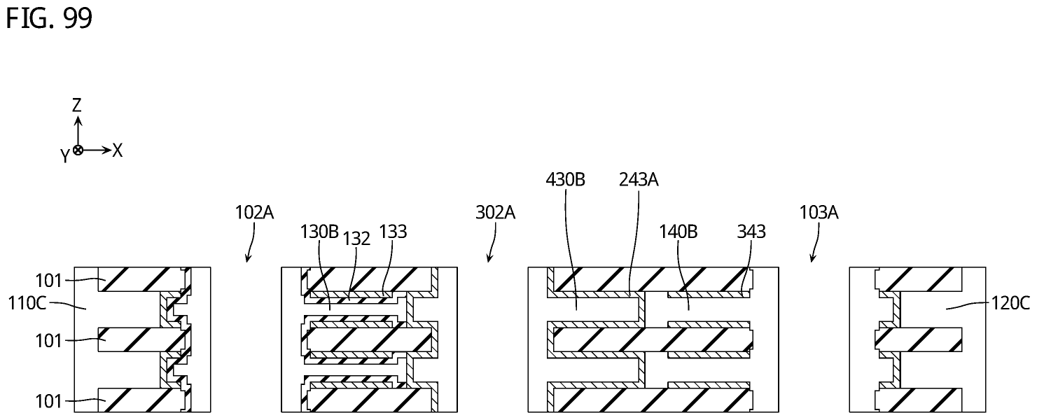

Next, for example, as illustrated in FIG. 99, via the opening 302A, a conductive layer 243A is formed on a side surface of the sacrifice layer 130B on one side in the X-direction (side surface on the opening 120A side), the side surface of the sacrifice layer 140B on one side in the X-direction (side surface on the opening 110A side), both side surfaces of the insulating layer 105 in the Y-direction, and the upper surface and the lower surface of the insulating layer 101. This process is performed by, for example, CVD.

Further, a sacrifice layer 430B is formed inside the openings 430A, 302A. This process is performed by, for example, CVD. Although not illustrated, after the end of this process, an upper portion of the opening 302A is closed by an insulating layer or the like.

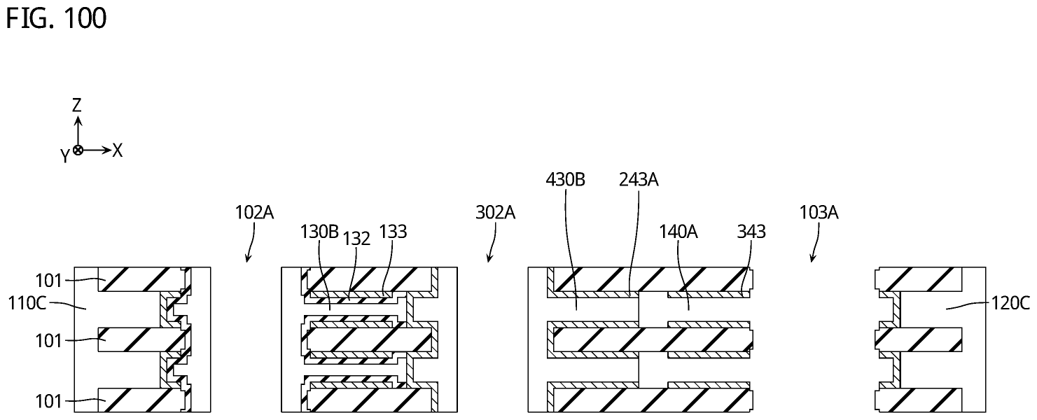

Next, for example, as illustrated in FIG. 100, the sacrifice layer 140B is removed. For example, a part of the conductive layer 243A covering a side surface of the sacrifice layer 430B on one side in the X-direction (side surface on the opening 120A side) is removed. This causes the side surface of the sacrifice layer 430B on one side in the X-direction to be exposed inside the opening 103A. This process is performed by, for example, wet etching.

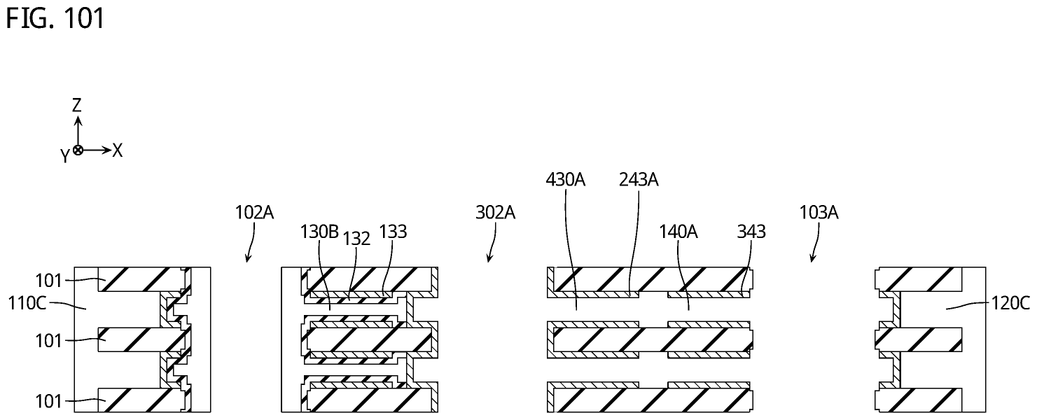

Next, for example, as illustrated in FIG. 101, the sacrifice layer 430B is removed. This process is performed by, for example, wet etching.

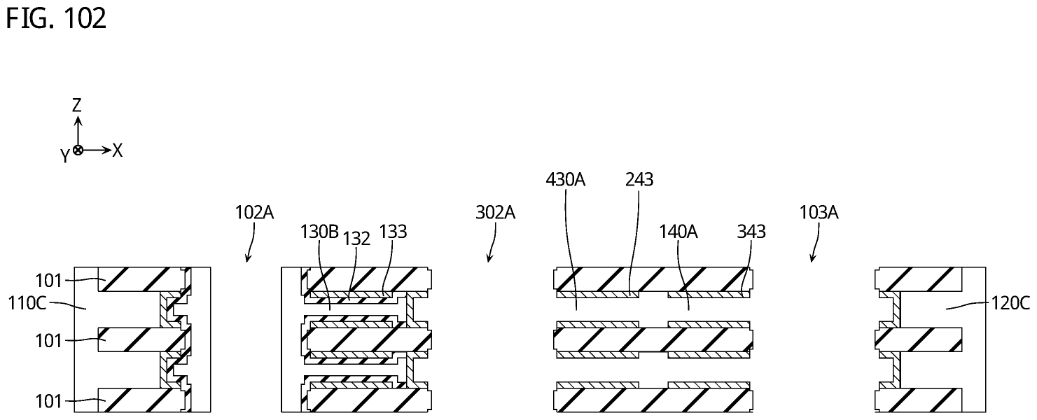

Next, for example, as illustrated in FIG. 102, the conductive layer 243 is formed. In this process, for example, a sacrifice layer 430B of silicon or the like is formed inside the openings 430A, 302A. Subsequently, a part of the sacrifice layer 430B disposed at an inner peripheral surface of the opening 302A is removed. Subsequently, a part of the conductive layer 243A disposed at the inner peripheral surface of the opening 302A is removed to separate the conductive layer 243A in the Z-direction. Further, the sacrifice layer 430B is removed. This process is performed by, for example, CVD and wet etching.

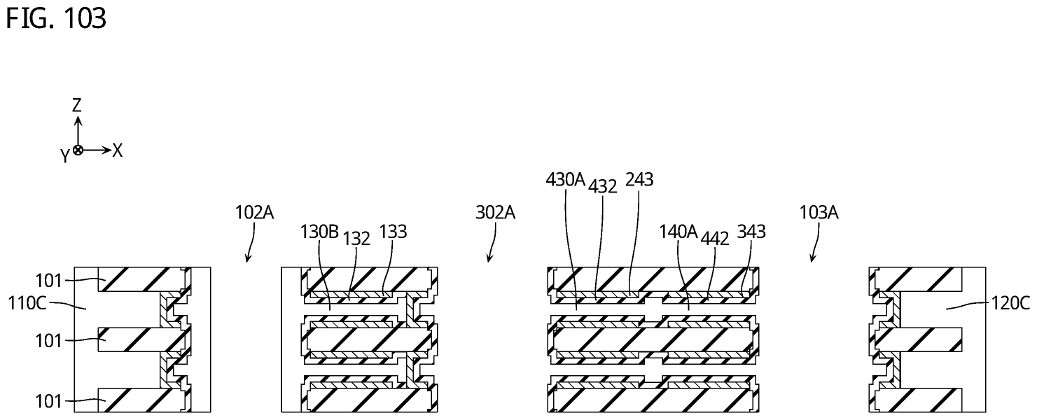

Next, for example, as illustrated in FIG. 103, the insulating portions 432, 442 are formed inside the openings 430A, 302A, 140A, 103A. The insulating portions 432, 442 are formed on upper surfaces and lower surfaces of the conductive layers 243, 343, a part of the upper surface, a part of the lower surface, and surfaces exposed to the openings 302A, 103A of the insulating layer 101, and a part of the side surface of the insulating layer 105 in the Y-direction.

Then, for example, as illustrated in FIG. 91 and FIG. 92, the semiconductor portions 431, 441 are formed inside the openings 430A, 140A. The via-wirings 302, 103 are formed inside the openings 302A, 103A. The semiconductor layer 131 is formed inside the opening 130A, and the via-wiring 102 is formed inside the opening 102A. Furthermore, the wirings 110, 120 are formed. This process is performed by, for example, ALD, CVD, and wet etching.

### [Effects]

As described with reference to FIG. 91 and FIG. 92, the semiconductor memory device according to the fourth embodiment does not include the conductive member 150 or the insulating member 104, and the semiconductor layer 131 in the transistor structure 130 is directly connected to the conductive layer 243 in the transistor structure 430. Additionally, the semiconductor memory device according to the fourth embodiment does not include the conductive member 350 or the insulating member 304, and the semiconductor portion 431 in the transistor structure 430 is directly connected to the semiconductor portion 441 in the transistor structure 440. With this configuration, the area per memory cell MC3 can be reduced compared with the semiconductor memory device according to the third embodiment. Therefore, according to the fourth embodiment, the high integration of the semiconductor memory device can be achieved.

### Fifth Embodiment

As described above, with the semiconductor memory device according to the third embodiment, the generation of the leakage current IL can be reduced in the read operation. However, as described with reference to FIG. 88, the memory cell MC3 according to the third embodiment includes the switch transistor STr in addition to the write transistor WTr and the read transistor RTr. Therefore, as described with reference to FIG. 89 and FIG. 90, the memory cell MC3 of the semiconductor memory device according to the third embodiment includes the three via-wirings 102, 302, 103 and the two insulating members 104, 304, and this makes the high integration difficult compared with the semiconductor memory device according to the first embodiment.

Therefore, in a semiconductor memory device according to the fifth embodiment, one including a floating gate is used as the read transistor RTr, thereby reducing the generation of the leakage current IL described above. With such a configuration, since the generation of the leakage current IL can be reduced by two transistors, the high integration is facilitated compared with the semiconductor memory device according to the third embodiment.

The semiconductor memory device according to the fifth embodiment is described below with reference to the drawings. In the following description, the same reference numerals are attached to configurations similar to those in the first embodiment to the fourth embodiment, and the explanation is omitted.

### [Circuit Configuration]

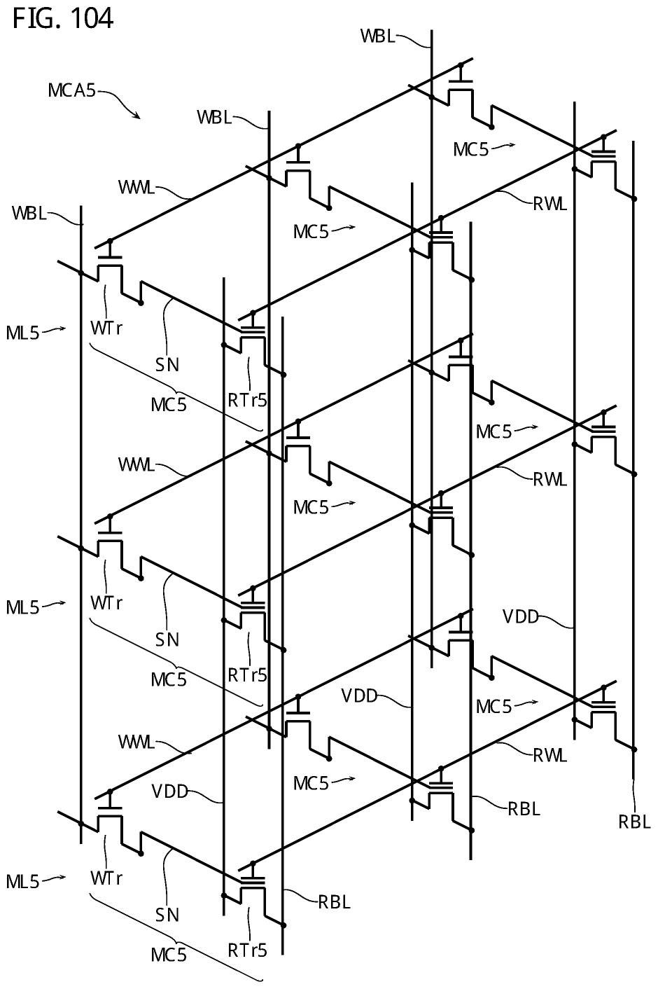

FIG. 104 is a schematic circuit diagram illustrating a configuration of a part of the semiconductor memory device according to the fifth embodiment.

As illustrated in FIG. 104, the semiconductor memory device according to the embodiment includes a memory cell array MCA5. The memory cell array MCA5 includes a plurality of memory layers ML5, a plurality of write bit lines WBL connected to these plurality of memory layers ML5, voltage supply lines VDD that supply the power supply voltage Vdd, and a plurality of read bit lines RBL connected to the plurality of memory layers ML5.

Each of the memory layers ML5 includes a write word line WWL, a read word line RWL, and a plurality of memory cells MC5 connected to these write word line WWL and read word line RWL. Each of the memory cells MC5 includes a write transistor WTr, a sense node SN, and a read transistor RTr5.

The read transistor RTr5 is, for example, a field-effect type NMOS transistor, and includes a floating gate. The read transistor RTr5 has one electrode connected to the voltage supply line VDD. The read transistor RTr5 has the other electrode connected to the read bit line RBL. The one and the other electrodes of the read transistor RTr5 function as a source electrode or a drain electrode corresponding to a voltage applied to the read transistor RTr5. The read transistor RTr5 has a gate electrode connected to the read word line RWL. The floating gate of the read transistor RTr5 is connected to the sense node SN.

The write operation of the semiconductor memory device according to the fifth embodiment can be executed similarly to the write operation of the semiconductor memory device according to the first embodiment.

The read operation of the semiconductor memory device according to the fifth embodiment can be executed similarly to the read operation of the semiconductor memory device according to the third embodiment.

Here, also in the fifth embodiment, in the read operation, a power supply voltage Vdd is applied to a read word line RWL that is a target of the read operation and a ground voltage Vss is applied to the other read word lines RWL among the plurality of read word lines RWL. Thus, among the read transistors RTr5 in the memory layer ML5 that is the target of the read operation, the read transistors RTr5 in which the sense node SN is charged with the power supply voltage Vdd turn ON, and the read transistors RTr5 in which the sense node SN is not charged with the power supply voltage Vdd turn OFF. The read transistors RTr5 in the memory layers ML5 other than the target of the read operation turn OFF. This enables reducing the generation of the leakage current IL as described above.

### [Structure]

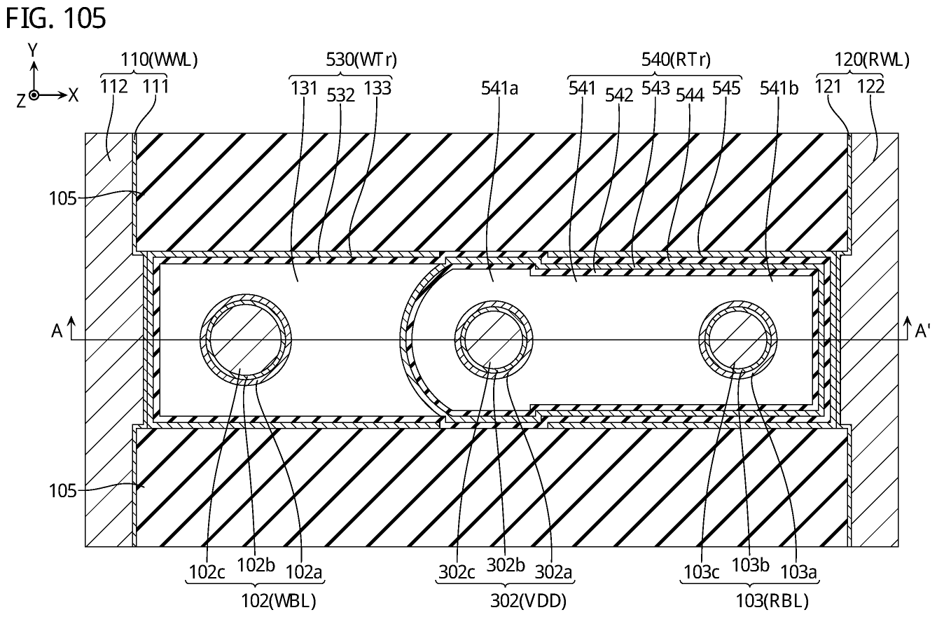

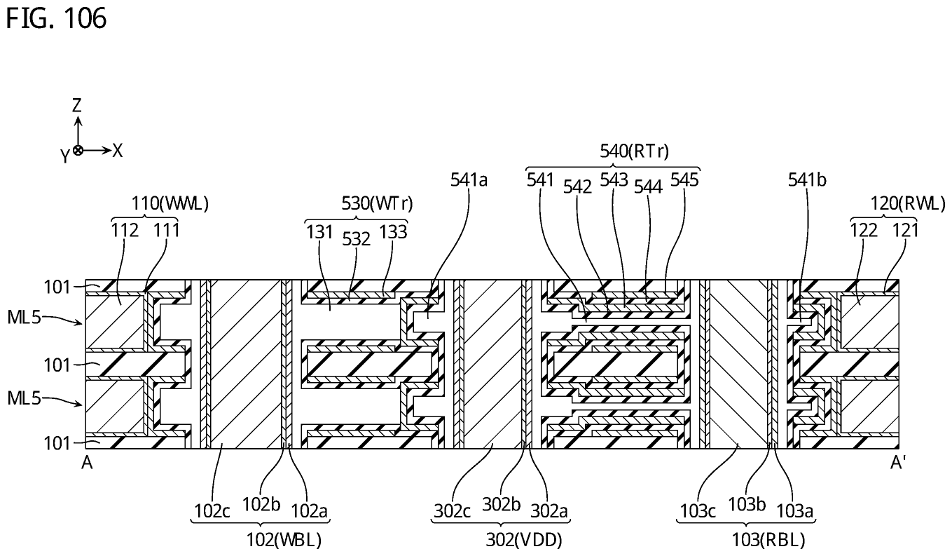

FIG. 105 is a schematic XY cross-sectional view illustrating a configuration of a part of the semiconductor memory device according to the fifth embodiment. FIG. 106 is a schematic cross-sectional view illustrating a configuration of a part of the semiconductor memory device, and illustrates a configuration of the structure illustrated in FIG. 105 taken along the line A-A′ when viewed in the arrow direction.

The memory cell array MCA5 includes a plurality of memory layers ML5 arranged in the Z-direction. Insulating layers 101 of silicon oxide (SiO₂) or the like are each disposed between the plurality of memory layers ML5.

The memory cell array MCA5 includes via-wirings 102, 302, 103. The via-wirings 102, 302, 103 are sequentially arranged in the X-direction, and penetrate the plurality of memory layers ML5 to extend in the Z-direction.

The memory layer ML5 includes wirings 110, 120 arranged in the X-direction and extending in the Y-direction, and transistor structures 530, 540 disposed between these wirings 110, 120. The transistor structure 530 is disposed at a position corresponding to the via-wiring 102. The transistor structure 540 is disposed at a position corresponding to the via-wirings 302, 103.

The transistor structure 530 is basically configured similarly to the transistor structure 130. However, the transistor structure 530 includes an insulating portion 532 instead of the insulating layer 132. The insulating portion 532 is basically configured similarly to the insulating layer 132. However, the insulating portion 532 is continuous with an insulating portion 544 described later in the transistor structure 540, and the insulating portion 532 and the insulating portion 544 are directly connected to one another. Each of the insulating portion 532 and the insulating portion 544 is a part of one insulating layer.

For example, as illustrated in FIG. 106, the transistor structure 540 includes a semiconductor layer 541 connected to outer peripheral surfaces of the via-wirings 302, 103 and extending in the X-direction, an insulating layer 542 disposed on an upper surface, a lower surface, both side surfaces in the Y-direction, and both side surfaces in the X-direction of the semiconductor layer 541, a conductive layer 543 disposed on an upper surface, a lower surface, both side surfaces in the Y-direction, and both side surfaces in the X-direction of the insulating layer 542, an insulating portion 544 disposed on an upper surface, a lower surface, both side surfaces in the Y-direction, and a side surface on one side (wiring 120 side) in the X-direction of the conductive layer 543, and a conductive layer 545 disposed on an upper surface, a lower surface, both side surfaces in the Y-direction, and a side surface on one side (wiring 120 side) in the X-direction of the insulating portion 544.

In an XY cross-sectional surface as exemplified in FIG. 105, side surfaces of the semiconductor layer 541, the insulating layer 542, and the conductive layer 543 on one side (wiring 110 side) in the X-direction may be formed along a circle with a center position of the via-wiring 302 as its center. Additionally, side surfaces of the semiconductor layer 541, the insulating layer 542, the conductive layer 543, the insulating portion 544, and the conductive layer 545 on the other side (wiring 120 side) in the X-direction may be formed in a straight line along a side surface of the wiring 120. Both side surfaces of the semiconductor layer 541, the insulating layer 542, the conductive layer 543, the insulating portion 544, and the conductive layer 545 in the Y-direction may be formed in a straight line along a side surface of the insulating layer 105.

The semiconductor layer 541 functions as, for example, a channel region of the read transistor RTr5 (FIG. 104). The semiconductor layer 541, for example, may be a semiconductor containing at least one element of gallium (Ga) or aluminum (Al), and containing indium (In), zinc (Zn), and oxygen (O) or may be other oxide semiconductors. The semiconductor layer 541 includes a semiconductor portion 541a connected to the outer peripheral surface of the via-wiring 302, and a semiconductor portion 541b connected to the outer peripheral surface of the via-wiring 103. A plurality of the semiconductor portions 541a arranged in the Z-direction are connected to the via-wiring 302 extending in the Z-direction in common. A plurality of the semiconductor portions 541b arranged in the Z-direction are connected to the via-wiring 103 extending in the Z-direction in common. In the example of FIG. 106, the semiconductor portion 541a has a length in the Z-direction larger than a length of the semiconductor portion 541b in the Z-direction.

The insulating layer 542 functions as, for example, a gate insulating film of the read transistor RTr5 (FIG. 104). The insulating layer 542 contains, for example, silicon oxide (SiO₂).

The conductive layer 543 functions as, for example, a floating gate of the read transistor RTr5 (FIG. 104) and the sense node SN (FIG. 104). The conductive layer 543 contains, for example, a conductive oxide, such as indium tin oxide (ITO). The conductive layer 543 is opposed to the upper surface, the lower surface, both side surfaces in the Y-direction, and both side surfaces in the X-direction of the semiconductor layer 541 via the insulating layer 542. The conductive layer 543 is connected to the side surface of the semiconductor layer 131 on one side (wiring 120 side) in the X-direction. The conductive layer 543 is disposed at a position overlapping with the semiconductor portion 541b and overlapping with the semiconductor portion 541a when viewed in the Z-direction.

The insulating portion 544 functions as, for example, a gate insulating film of the read transistor RTr5 (FIG. 104). The insulating portion 544 contains, for example, silicon oxide (SiO₂).

The conductive layer 545 functions as, for example, a gate electrode of the read transistor RTr5 (FIG. 104). The conductive layer 545 contains, for example, a conductive material, such as titanium nitride (TiN), or a conductive oxide, such as indium tin oxide (ITO). The conductive layer 545 is opposed to the upper surface, the lower surface, both side surfaces in the Y-direction, and the side surface on one side (wiring 120 side) in the X-direction of the semiconductor layer 541 via the insulating portion 544, the conductive layer 543, and the insulating layer 542. The conductive layer 545 is disposed at a position overlapping with the semiconductor portion 541b and not overlapping with the semiconductor portion 541a when viewed in the Z-direction.

### [Manufacturing Method]

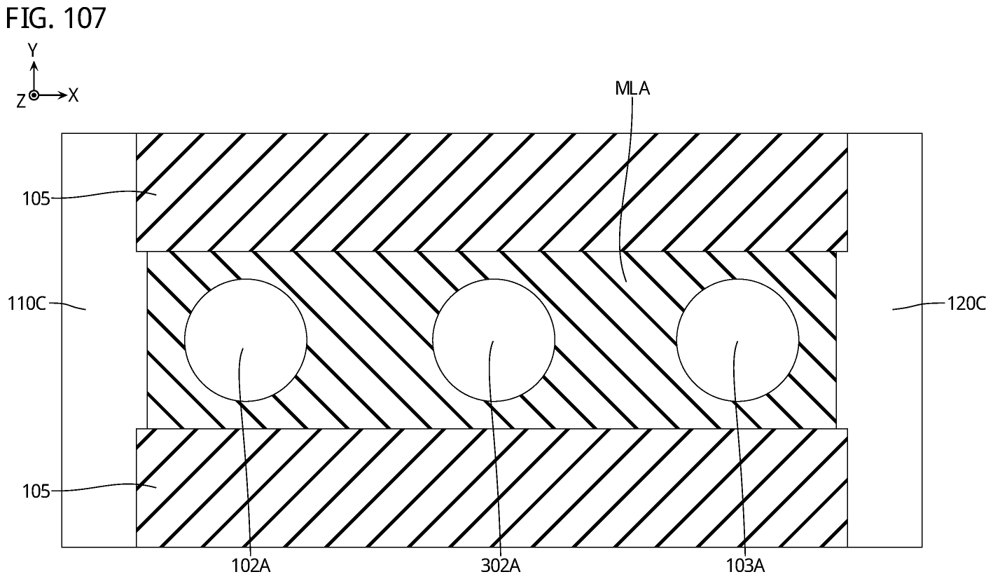

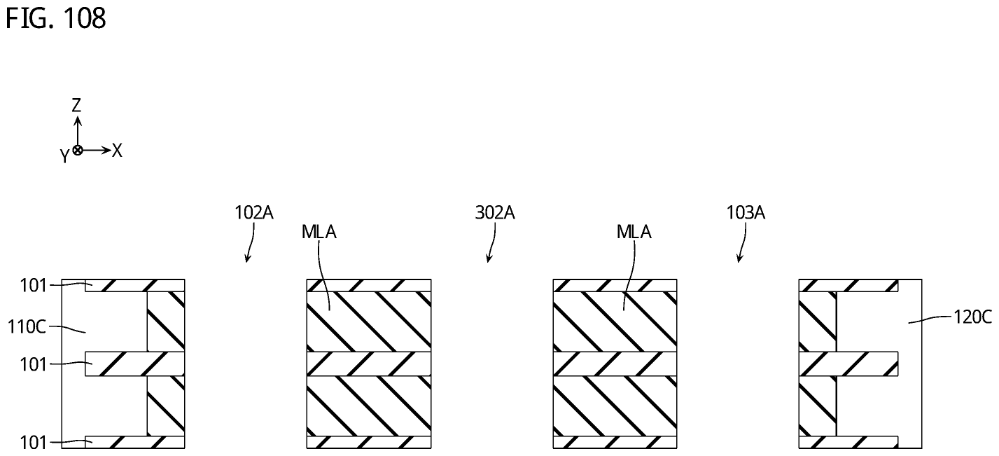

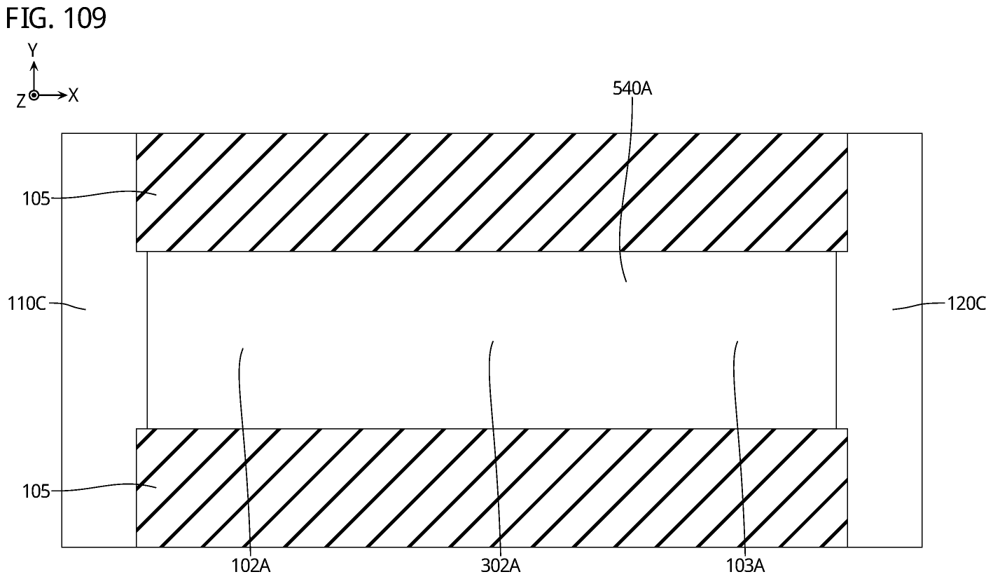

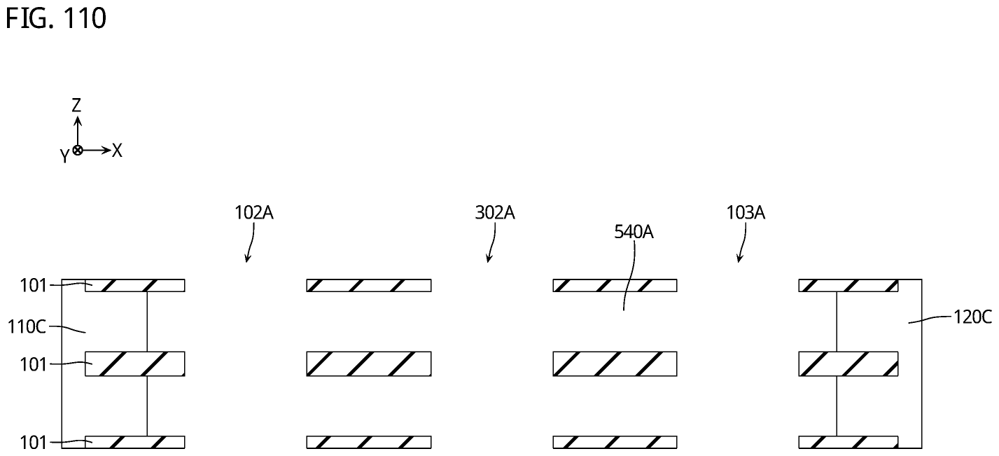

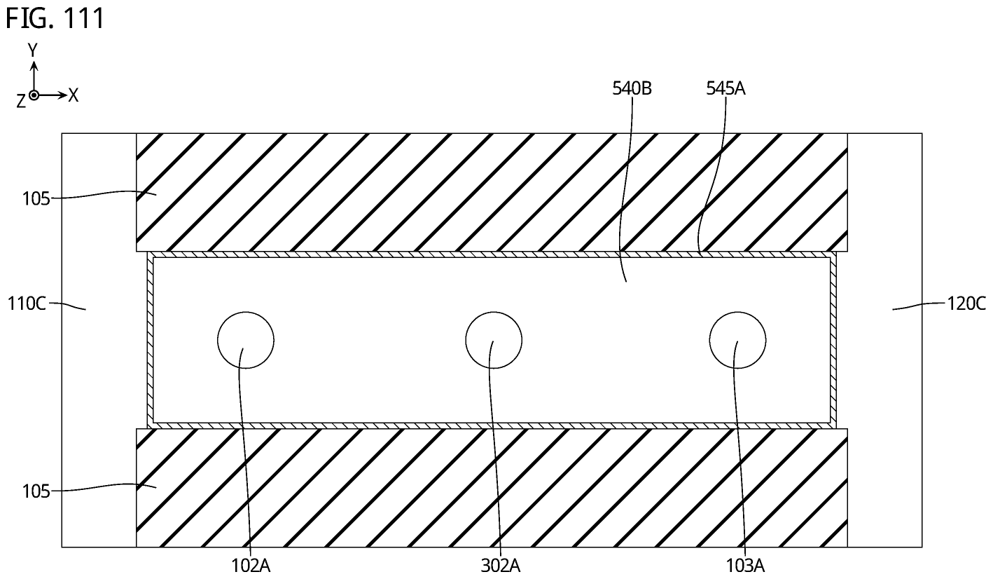

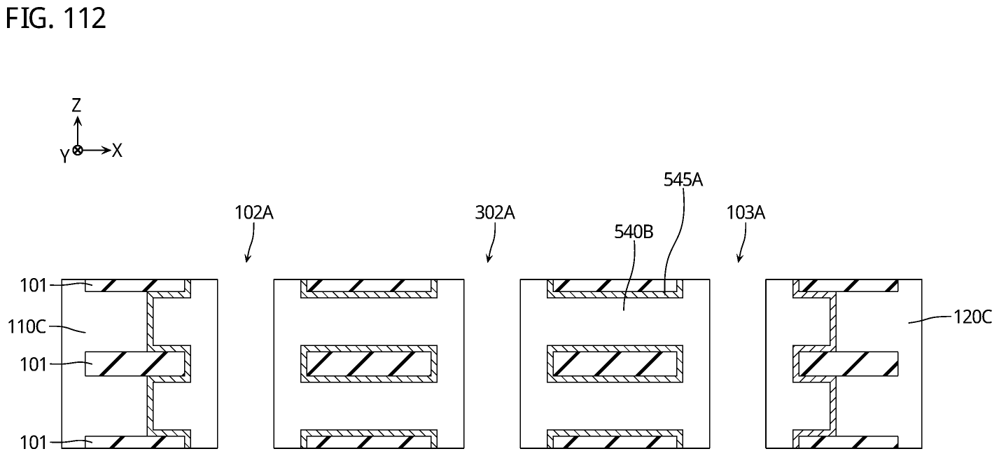

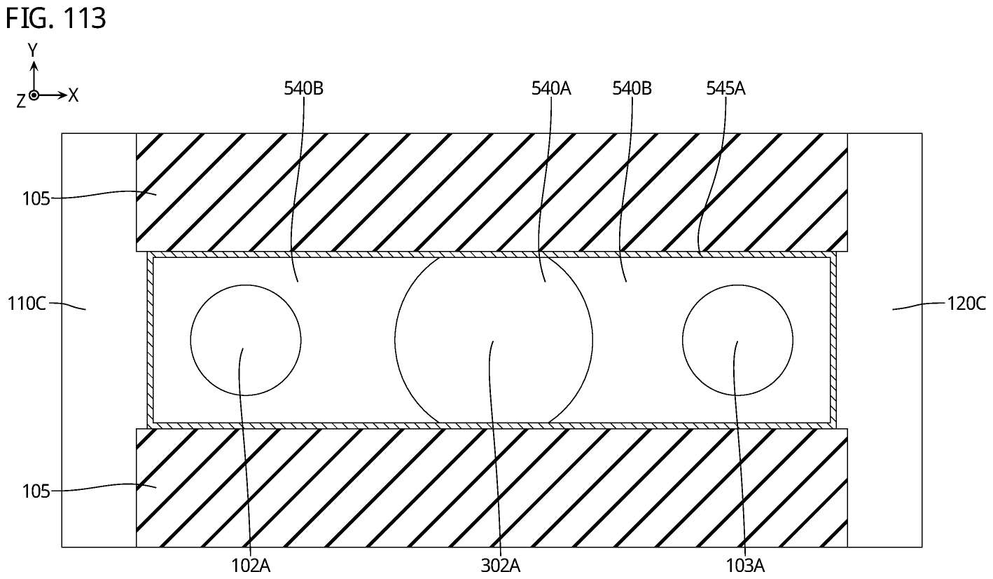

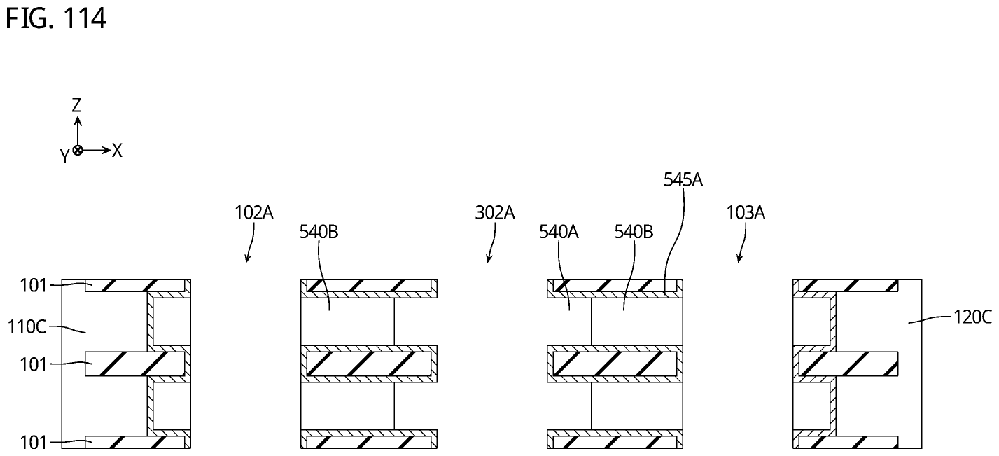

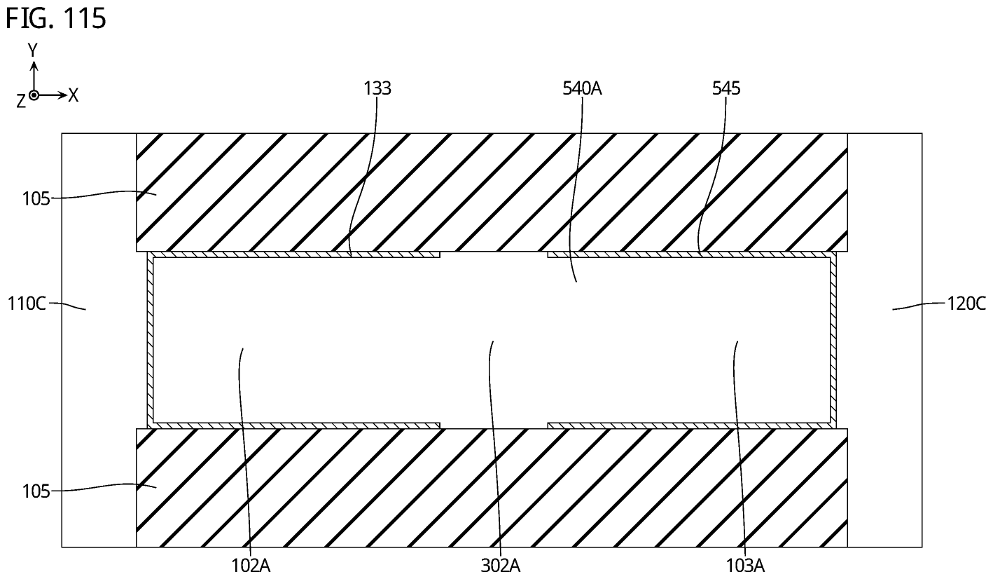

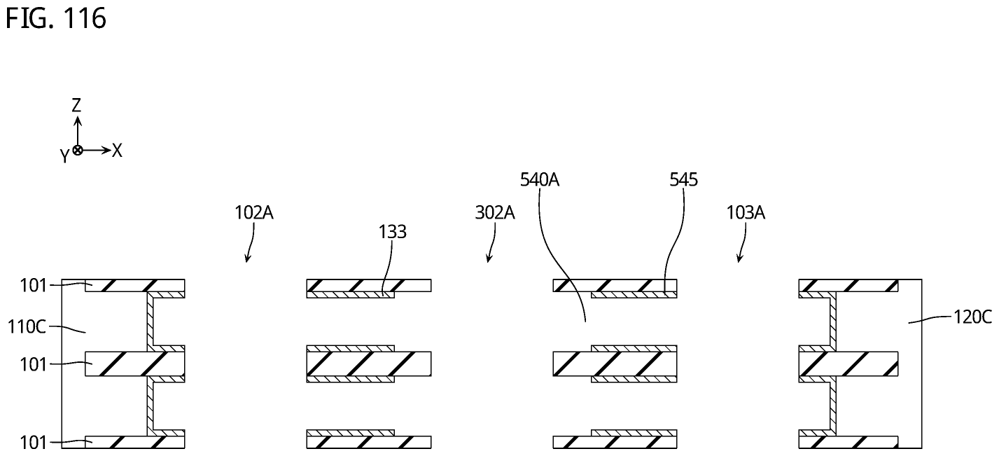

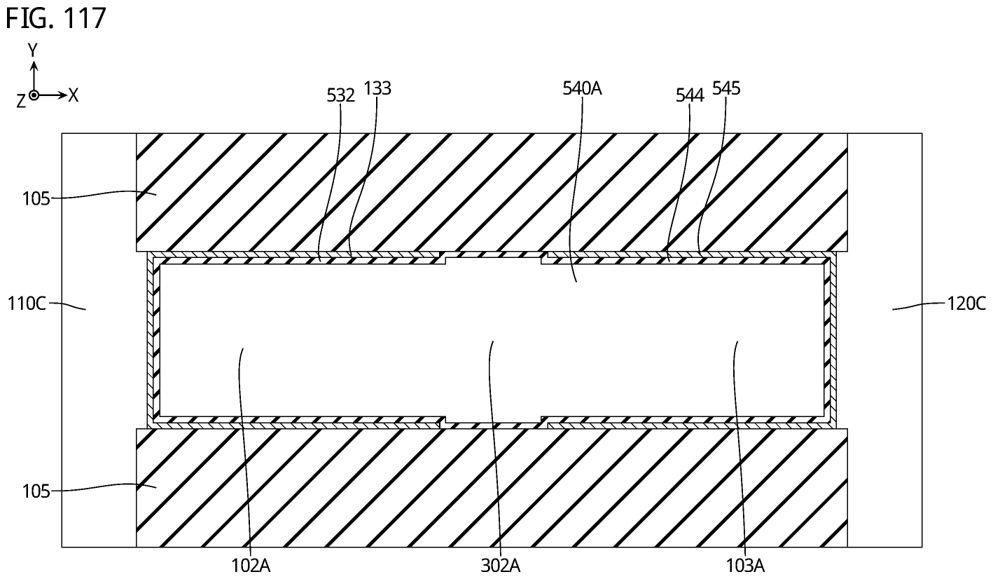

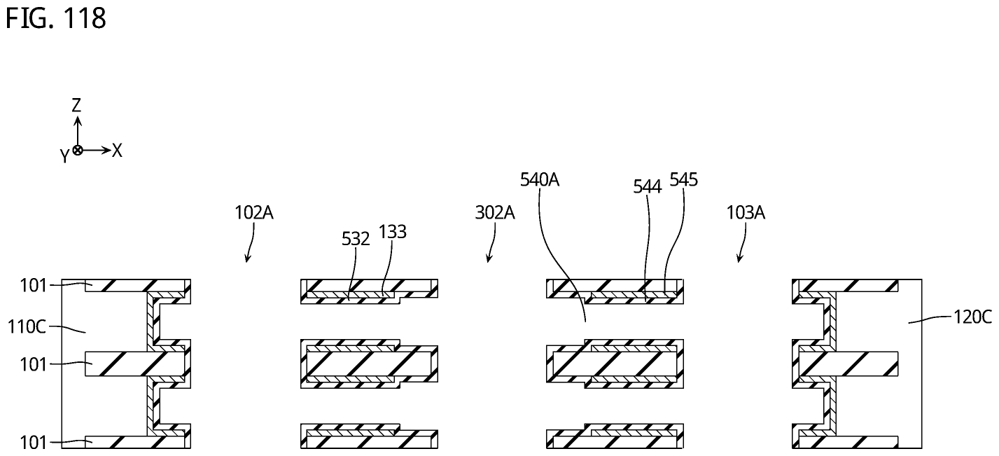

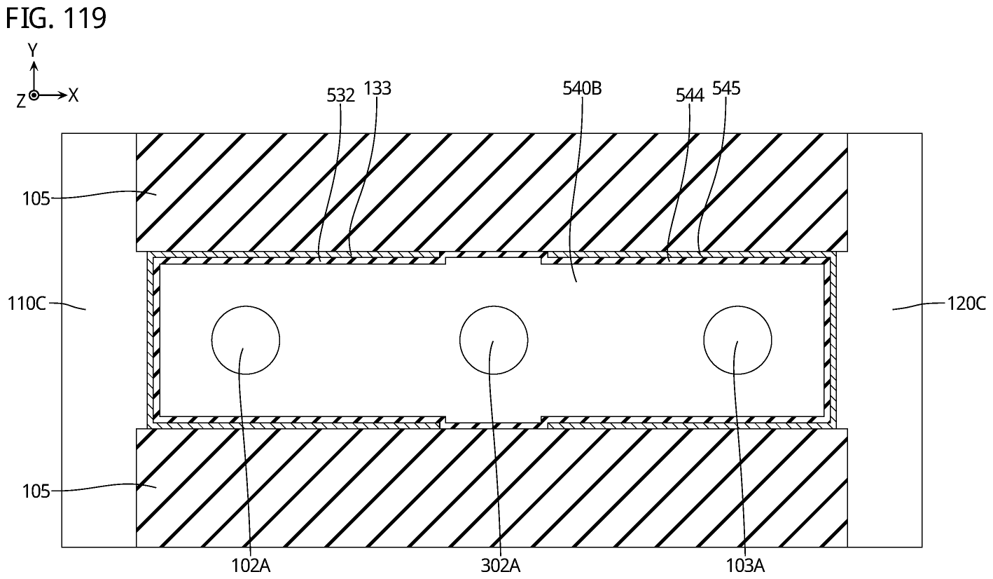

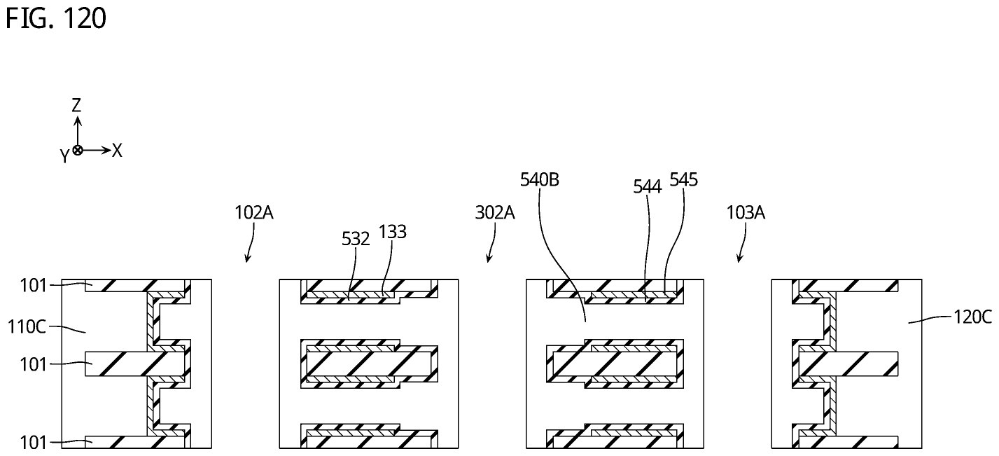

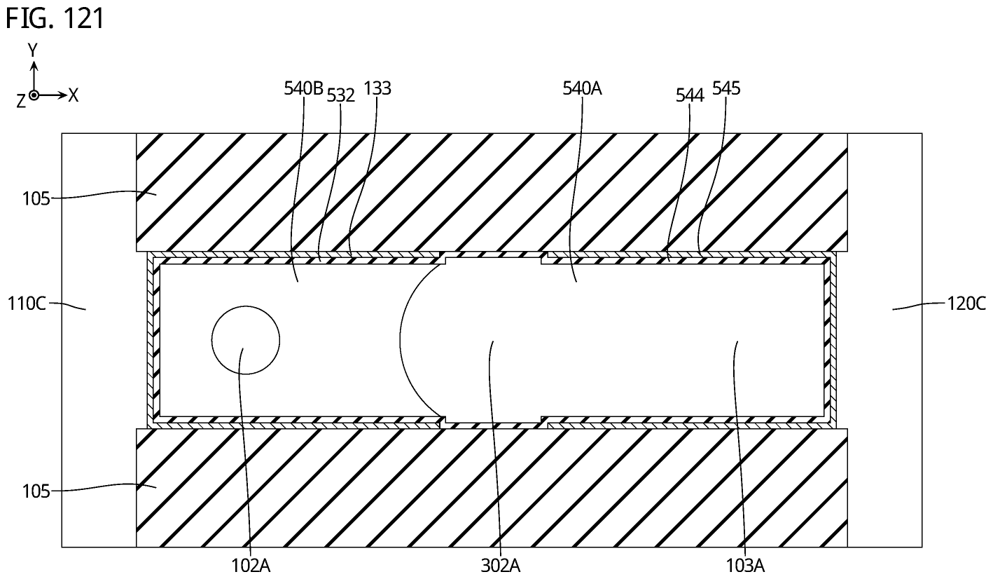

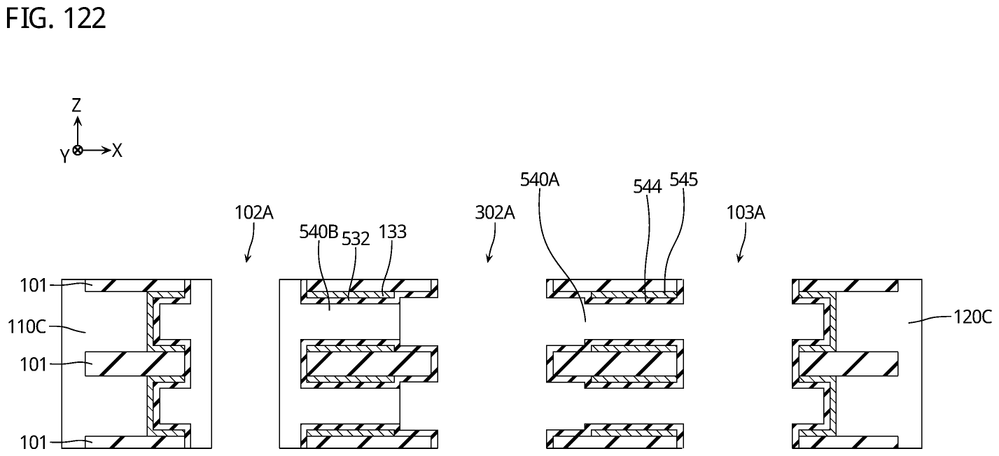

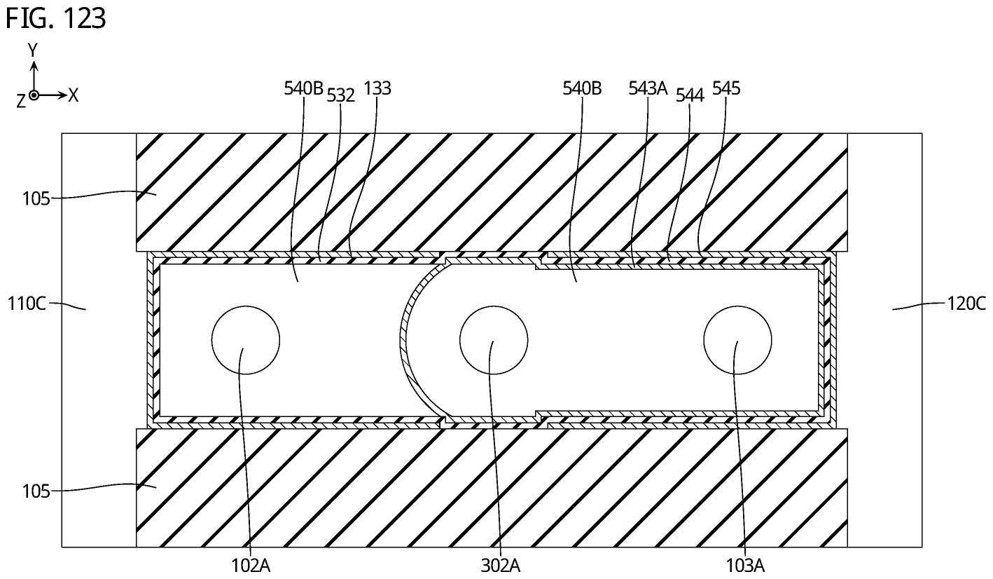

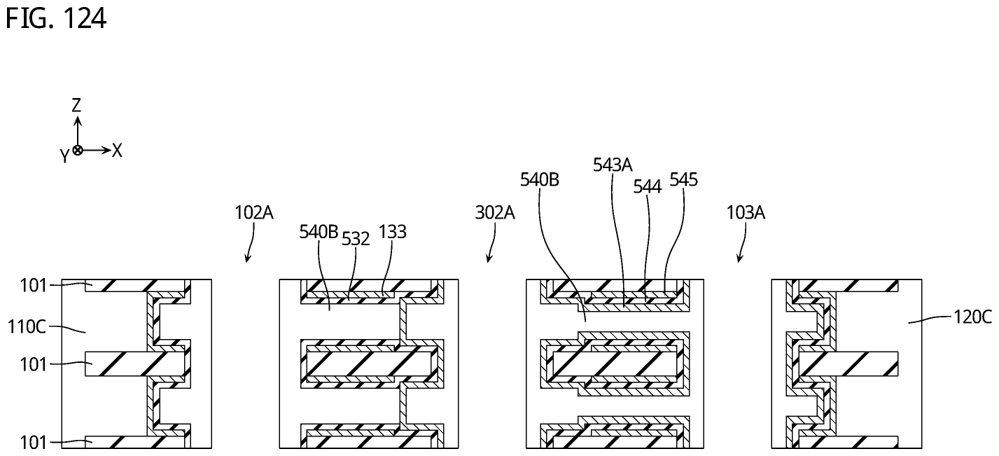

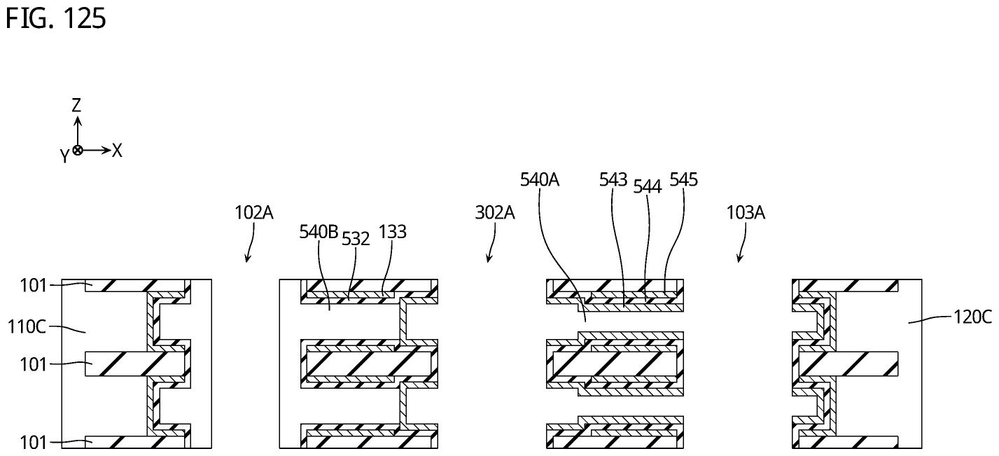

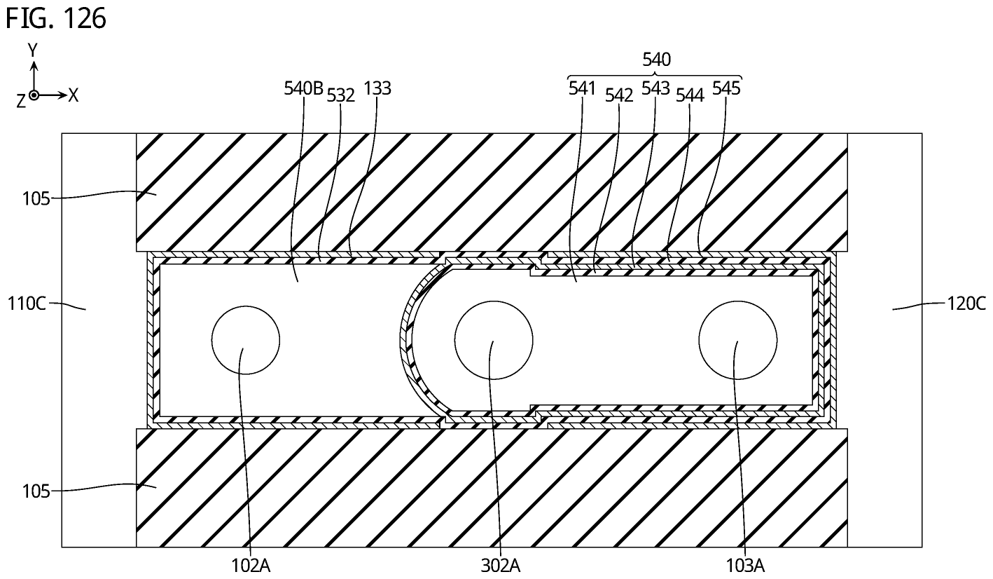

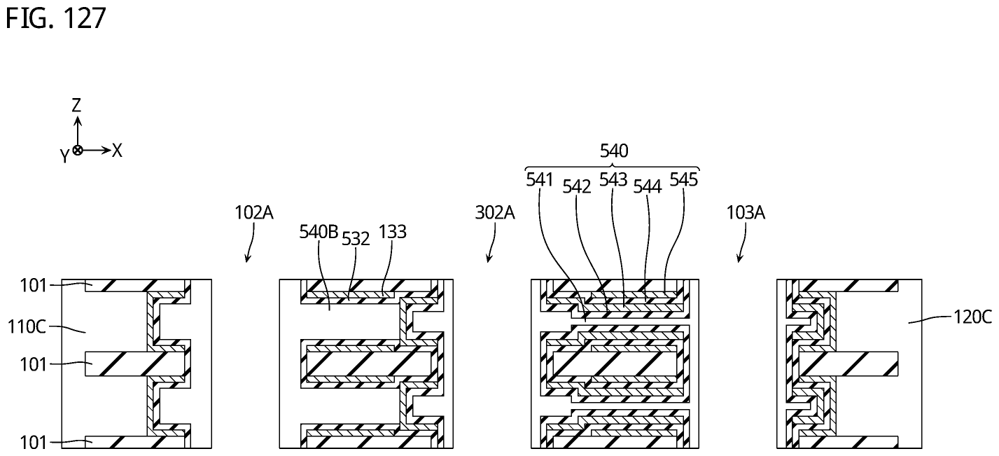

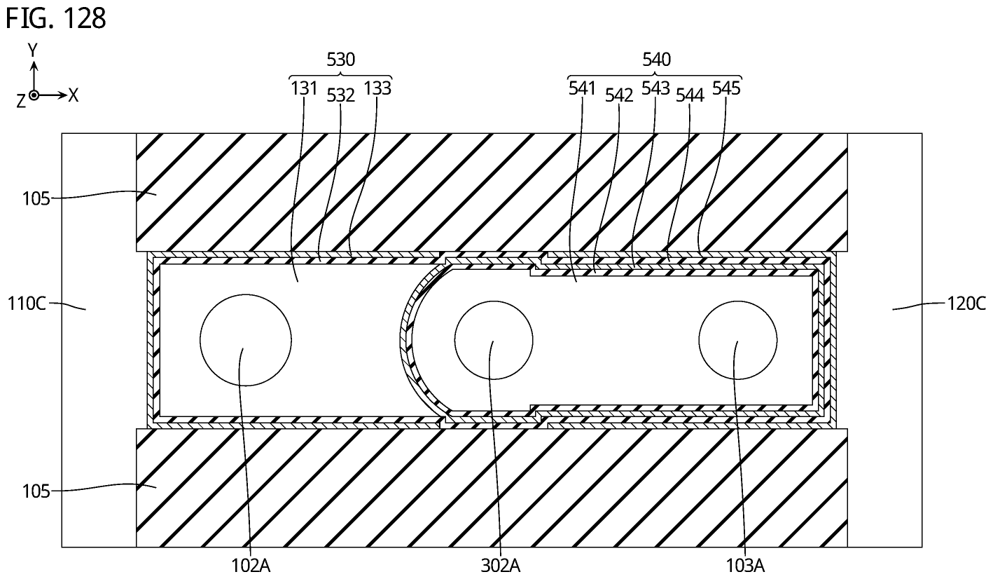

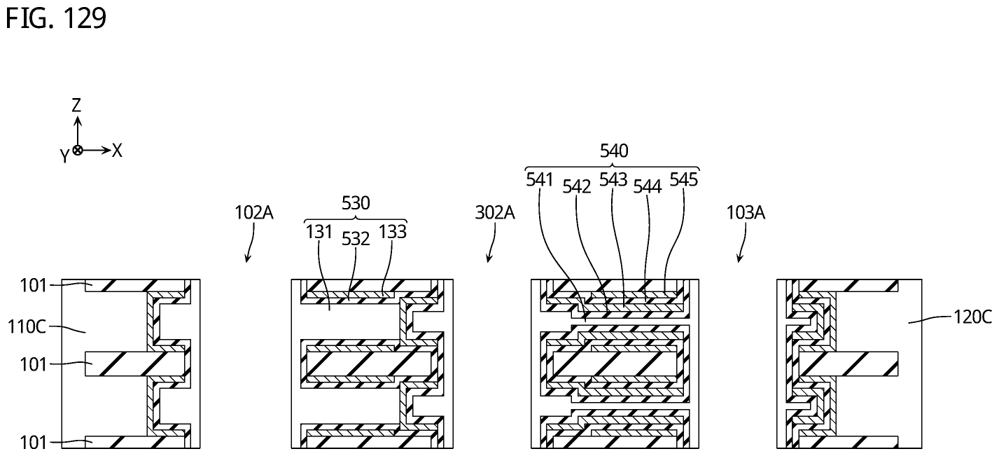

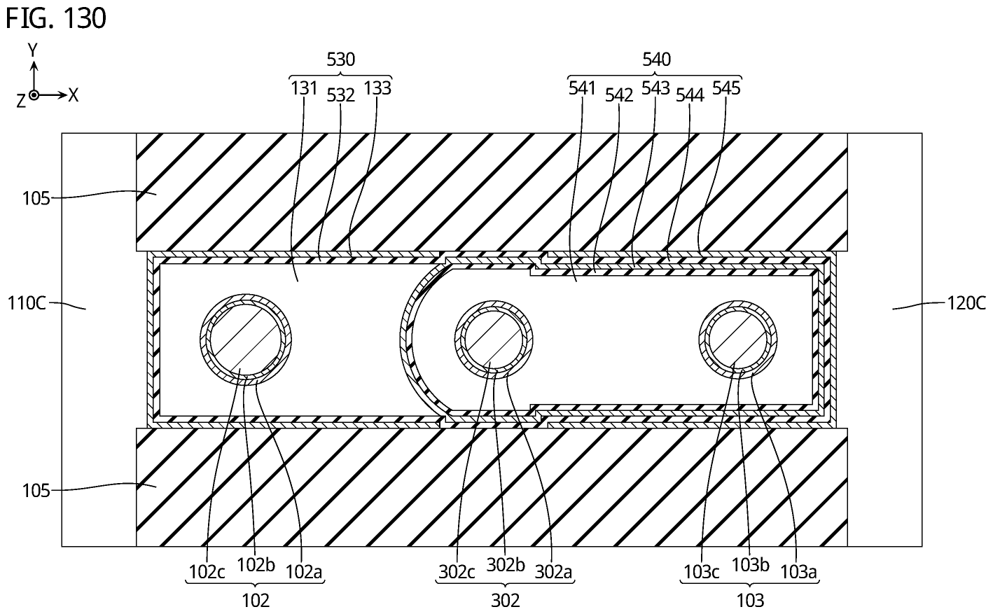

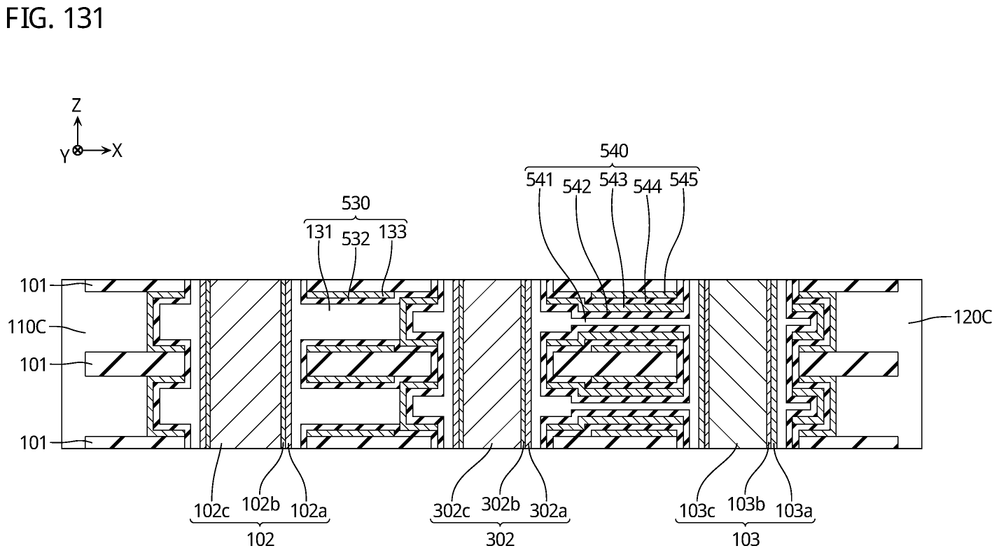

FIG. 107 to FIG. 131 are schematic cross-sectional views for describing a method for manufacturing the semiconductor memory device according to the fifth embodiment. FIG. 107, FIG. 109, FIG. 111, FIG. 113, FIG. 115, FIG. 117, FIG. 119, FIG. 121, FIG. 123, FIG. 126, FIG. 128, and FIG. 130 illustrate cross-sectional surfaces corresponding to FIG. 105. FIG. 108, FIG. 110, FIG. 112, FIG. 114, FIG. 116, FIG. 118, FIG. 120, FIG. 122, FIG. 124, FIG. 125, FIG. 127, FIG. 129, and FIG. 131 illustrate cross-sectional surfaces corresponding to FIG. 106.

In the manufacturing method, for example, the processes up to the process described with reference to FIG. 9 and FIG. 10 in the manufacturing process of the semiconductor memory device according to the first embodiment are performed.

Next, for example, as illustrated in FIG. 107 and FIG. 108, openings 102A, 302A, 103A are formed at positions corresponding to the via-wirings 102, 302, 103. This process is performed by, for example, RIE.

Next, for example, as illustrated in FIG. 109 and FIG. 110, the sacrifice layer MLA is removed to form an opening 540A. This process is performed by, for example, wet etching.

Next, for example, as illustrated in FIG. 111 and FIG. 112, a conductive layer 545A and a sacrifice layer 540B of silicon (Si) or the like are formed inside the openings 540A, 102A, 302A, 103A. The conductive layer 545A and the sacrifice layer 540B are formed at a part of an upper surface, a part of a lower surface, and surfaces exposed to the openings 102A, 302A, 103A of the insulating layer 101, a part of a side surface of the insulating layer 105 in the Y-direction, and a part of side surfaces of the sacrifice layer 110C and the sacrifice layer 120C in the X-direction. The opening 540A is filled with the sacrifice layer 540B, and the openings 102A, 302A, 103A are not filled with the sacrifice layer 540B. This process is performed by, for example, CVD.

Next, for example, as illustrated in FIG. 113 and FIG. 114, parts provided at inner peripheral surfaces of the openings 102A, 302A, 103A and a part provided at the proximity of the opening 302A of the sacrifice layer 540B are removed. This process is performed by, for example, wet etching.

Next, for example, as illustrated in FIG. 115 and FIG. 116, the conductive layers 133, 545 are formed. In this process, for example, parts provided at the inner peripheral surfaces of the openings 102A, 302A, 103A and a part provided at the proximity of the opening 302A of the conductive layer 545A are removed to separate the conductive layer 545A in the Z-direction and the X-direction. The sacrifice layer 540B is removed. This process is performed by, for example, wet etching.

Next, for example, as illustrated in FIG. 117 and FIG. 118, the insulating portions 532, 544 are formed inside the openings 540A, 102A, 302A, 103A. The insulating portions 532, 544 are formed on upper surfaces, lower surfaces, both side surfaces in the X-direction, and both side surfaces in the Y-direction of the conductive layer 133 and the conductive layer 545, a part of the upper surface, a part of the lower surface, and the surfaces exposed to the openings 102A, 302A, 103A of the insulating layer 101, and a part of the side surface of the insulating layer 105 in the Y-direction. This process is performed by, for example, CVD.

Next, for example, as illustrated in FIG. 119 and FIG. 120, the sacrifice layer 540B is formed inside the openings 540A, 102A, 302A, 103A. This process is performed by, for example, CVD. Although not illustrated, after the execution of this process, an upper portion of the opening 102A is closed by an insulating layer or the like.

Next, for example, as illustrated in FIG. 121 and FIG. 122, parts provided at the inner peripheral surfaces of the openings 302A, 103A and a part provided at the proximity of the openings 302A, 103A of the sacrifice layer 540B are removed. This process is performed by, for example, wet etching.

Next, for example, as illustrated in FIG. 123 and FIG. 124, a conductive layer 543A and the sacrifice layer 540B are formed inside the openings 540A, 302A, 103A. This process is performed by, for example, ALD and CVD.

Next, for example, as illustrated in FIG. 125, the conductive layer 543 is formed. In this process, for example, a part of the sacrifice layer 540B provided at the inner peripheral surfaces of the openings 302A, 103A are removed. Subsequently, a part of the conductive layer 543A provided at the inner peripheral surfaces of the openings 302A, 103A are removed to separate the conductive layer 543A in the Z-direction. Further, the sacrifice layer 540B is removed. This process is performed by, for example, wet etching.

Next, for example, as illustrated in FIG. 126 and FIG. 127, the insulating layer 542 and the semiconductor layer 541 are formed inside the openings 540A, 302A, 103A. This process is performed by, for example, CVD and ALD. Although not illustrated, after the execution of this process, upper portions of the openings 302A, 103A are closed by an insulating layer or the like.

Next, for example, as illustrated in FIG. 128 and FIG. 129, the semiconductor layer 131 is formed. In this process, for example, the sacrifice layer 540B is removed via the opening 102A. Further, the semiconductor layer 131 is formed inside the openings 540A, 102A. This process is performed by, for example, wet etching and ALD.

Next, for example, as illustrated in FIG. 130 and FIG. 131, the via-wirings 102, 302, 103 are formed inside the openings 102A, 302A, 103A. This process is performed by, for example, ALD and CVD.

Then, for example, the sacrifice layers 110C, 120C are removed. As illustrated in FIG. 105 and FIG. 106, the wirings 110, 120 are formed inside the openings 110B, 120B. This process is performed by, for example, CVD.

### [Modification]

In the example of FIG. 105 and FIG. 106, the semiconductor layer 131 is directly connected to the conductive layer 543. However, the semiconductor memory device according to the fifth embodiment may include the plurality of conductive members 150 and the insulating member 104, for example, as described with reference to FIG. 2 to FIG. 4. Each of the plurality of semiconductor layers 131 arranged in the Z-direction may be connected to the conductive layer 543 via the conductive member 150.

### Sixth Embodiment

As described above, with the semiconductor memory device according to the fifth embodiment, similarly to the semiconductor memory device according to the third embodiment, the generation of the leakage current IL can be reduced in the read operation. Additionally, in the semiconductor memory device according to the fifth embodiment, the high integration is facilitated compared with the semiconductor memory device according to the third embodiment.

Here, as described with reference to FIG. 106, in the semiconductor memory device according to the fifth embodiment, the conductive layer 543 is disposed at the position overlapping with the semiconductor portion 541b and overlapping with the semiconductor portion 541a when viewed in the Z-direction. Further, the conductive layer 545 is disposed at the position overlapping with the semiconductor portion 541b and not overlapping with the semiconductor portion 541a when viewed in the Z-direction. In such a configuration, parts of the conductive layers 543 covering the upper surfaces and the lower surfaces of the semiconductor portions 541a are adjacent between the memory layers ML5 adjacent in the Z-direction via the insulating layer 101.

Here, the conductive layer 543 functions as the sense node SN. The sense node SN is basically in the floating state except during the execution of the write operation. Therefore, when the voltage of the conductive layer 543 in one memory layer ML5 changes due to the write operation or the like, the voltage of the conductive layer 543 in another memory layer ML5 adjacent in the Z-direction changes. This causes a possibility of failure in appropriate execution of the read operation or the like. Such a voltage change of the sense node SN may occur similarly in the semiconductor memory devices according to the first embodiment to the fourth embodiment.

Therefore, in a semiconductor memory device according to the sixth embodiment, a configuration that functions as the sense node SN is provided inside at least one of the semiconductor layer that functions as the channel region or the gate electrode of the read transistor RTr, thereby reducing an electric field entering the sense node SN to reduce the voltage change of the sense node SN.

The semiconductor memory device according to the sixth embodiment is described below with reference to the drawings. In the following description, the same reference numerals are attached to configurations similar to those in the first embodiment to the fifth embodiment, and the explanation is omitted.

### [Circuit Configuration]

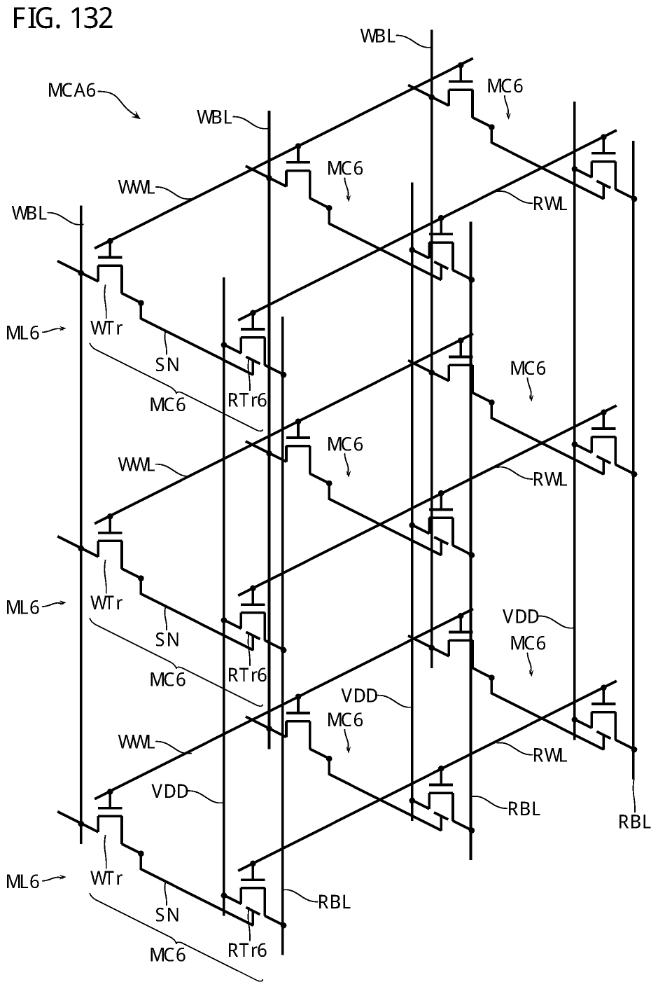

FIG. 132 is a schematic circuit diagram illustrating a configuration of a part of the semiconductor memory device according to the sixth embodiment.

As illustrated in FIG. 132, the semiconductor memory device according to the embodiment includes a memory cell array MCA6. The memory cell array MCA6 includes a plurality of memory layers ML6, a plurality of write bit lines WBL connected to these plurality of memory layers ML6, voltage supply lines VDD that supply the power supply voltage Vdd, and a plurality of read bit lines RBL connected to the plurality of memory layers ML6.

Each of the memory layers ML6 includes a write word line WWL, a read word line RWL, and a plurality of memory cells MC6 connected to these write word line WWL and read word line RWL. Each of the memory cells MC6 includes a write transistor WTr, a sense node SN, and a read transistor RTr6.

The read transistor RTr6 is basically configured similarly to the read transistor RTr5 described with reference to FIG. 104. However, the read transistor RTr6 includes a back gate instead of the floating gate. The back gate of the read transistor RTr6 is connected to the sense node SN.

The write operation of the semiconductor memory device according to the sixth embodiment can be executed similarly to the write operation of the semiconductor memory device according to the first embodiment.

The read operation of the semiconductor memory device according to the sixth embodiment can be executed similarly to the read operation of the semiconductor memory device according to the third embodiment.

### [Structure]

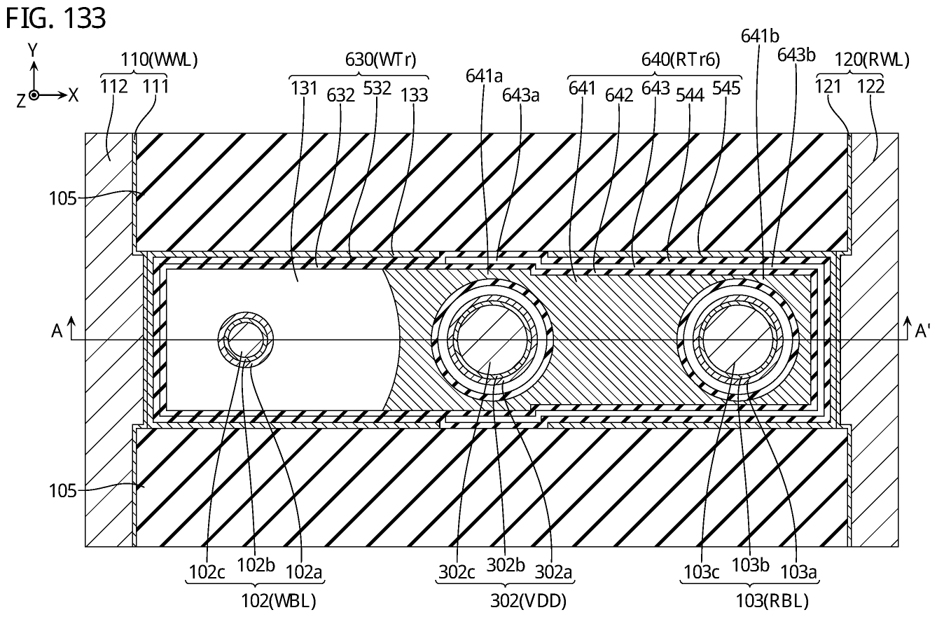

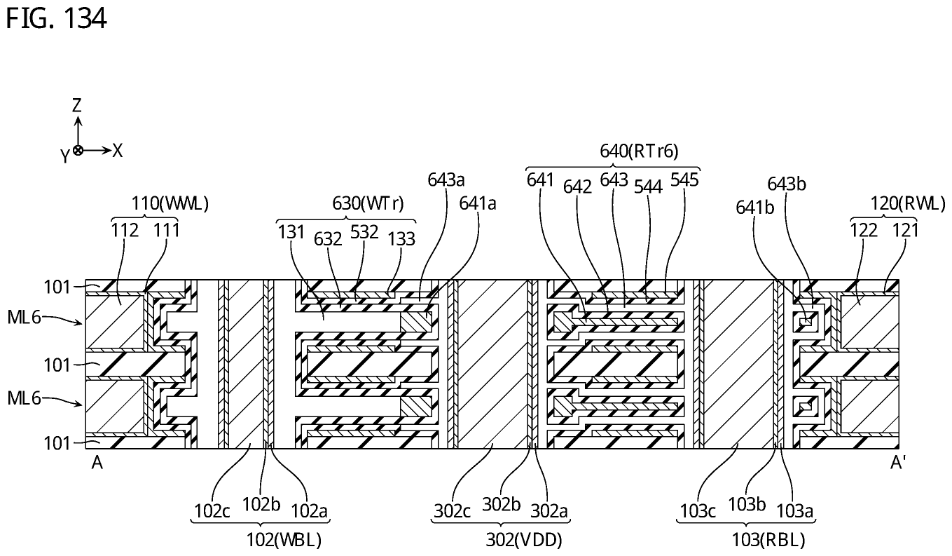

FIG. 133 is a schematic XY cross-sectional view illustrating a configuration of a part of the semiconductor memory device according to the sixth embodiment. FIG. 134 is a schematic cross-sectional view illustrating a configuration of a part of the semiconductor memory device, and illustrates a configuration of the structure illustrated in FIG. 133 taken along the line A-A′ when viewed in the arrow direction.

The memory cell array MCA6 includes a plurality of memory layers ML6 arranged in the Z-direction. Insulating layers 101 of silicon oxide (SiO₂) or the like are each disposed between the plurality of memory layers ML6.

The memory cell array MCA6 includes via-wirings 102, 302, 103. The via-wirings 102, 302, 103 are sequentially arranged in the X-direction, and penetrate the plurality of memory layers ML6 to extend in the Z-direction.

The memory layer ML6 includes wirings 110, 120 arranged in the X-direction and extending in the Y-direction, and transistor structures 630, 640 disposed between these wirings 110, 120. The transistor structure 630 is disposed at a position corresponding to the via-wiring 102. The transistor structure 640 is disposed at a position corresponding to the via-wirings 302, 103.

The transistor structure 630 is basically configured similarly to the transistor structure 130. However, the transistor structure 630 includes an insulating portion 632 and the insulating portion 532 disposed between the semiconductor layer 131 and the conductive layer 133 instead of the insulating layer 132. The insulating portion 632 functions as, for example, a gate insulating film of the write transistor WTr (FIG. 132) together with the insulating portion 532. The insulating portion 632 contains, for example, silicon oxide (SiO₂).

For example, as illustrated in FIG. 134, the transistor structure 640 includes a conductive layer 641 extending in the X-direction, an insulating portion 642 disposed on an upper surface, a lower surface, both side surfaces in the Y-direction, and a side surface on one side (wiring 120 side) in the X-direction of the conductive layer 641, a semiconductor layer 643 disposed on an upper surface, a lower surface, both side surfaces in the Y-direction, and a side surface on one side (wiring 120 side) in the X-direction of the insulating portion 642 and connected to outer peripheral surfaces of the via-wirings 302, 103, an insulating portion 544 disposed on an upper surface, a lower surface, both side surfaces in the Y-direction, and a side surface on one side (wiring 120 side) in the X-direction of the semiconductor layer 643, and a conductive layer 545 disposed on an upper surface, a lower surface, both side surfaces in the Y-direction, and a side surface on one side (wiring 120 side) in the X-direction of the insulating portion 544.

In an XY cross-sectional surface as exemplified in FIG. 133, a side surface of the conductive layer 641 on one side (wiring 110 side) in the X-direction may be formed along a side surface of the semiconductor layer 131 on one side (wiring 120 side) in the X-direction. Additionally, side surfaces of the conductive layer 641, the insulating portion 642, the semiconductor layer 643, the insulating portion 544, and the conductive layer 545 on the other side (wiring 120 side) in the X-direction may be formed in a straight line along a side surface of the wiring 120. Both side surfaces of the conductive layer 641, the insulating portion 642, the semiconductor layer 643, the insulating portion 544, and the conductive layer 545 in the Y-direction may be formed in a straight line along a side surface of the insulating layer 105.

The conductive layer 641 functions as, for example, a back gate of the read transistor RTr6 (FIG. 132) and the sense node SN (FIG. 132). The conductive layer 641 contains, for example, a conductive oxide, such as indium tin oxide (ITO). The conductive layer 641 is connected to the side surface of the semiconductor layer 131 on one side (wiring 120 side) in the X-direction. The conductive layer 641 includes a conductive portion 641a surrounding the outer peripheral surface of the via-wiring 302, and a conductive portion 641b surrounding the outer peripheral surface of the via-wiring 103. In the example of FIG. 134, the conductive portion 641a has a length in the Z-direction larger than a length of the conductive portion 641b in the Z-direction.

The insulating portion 642 functions as, for example, a gate insulating film between the back gate and the channel region of the read transistor RTr6 (FIG. 132). The insulating portion 642 contains, for example, silicon oxide (SiO₂).

The semiconductor layer 643 functions as, for example, a channel region of the read transistor RTr6 (FIG. 132). The semiconductor layer 643, for example, may be a semiconductor containing at least one element of gallium (Ga) or aluminum (Al), and containing indium (In), zinc (Zn), and oxygen (O) or may be other oxide semiconductors. The semiconductor layer 643 is opposed to the upper surface, the lower surface, both side surfaces in the Y-direction, and the side surface on one side (wiring 120 side) in the X-direction of the conductive layer 641 via the insulating portion 642.

The semiconductor layer 643 includes a semiconductor portion 643a connected to the outer peripheral surface of the via-wiring 302, and a semiconductor portion 643b connected to the outer peripheral surface of the via-wiring 103. The semiconductor portion 643a is disposed at a position overlapping with the conductive portion 641a when viewed in the Z-direction. A plurality of the semiconductor portions 643a arranged in the Z-direction are connected to the via-wiring 302 extending in the Z-direction in common. The semiconductor portion 643b is disposed at a position overlapping with the conductive portion 641b when viewed in the Z-direction. A plurality of the semiconductor portions 643b arranged in the Z-direction are connected to the via-wiring 103 extending in the Z-direction in common.

In this embodiment, the conductive layer 545 is disposed at a position overlapping with the conductive portion 641b and the semiconductor portion 643b and not overlapping with the conductive portion 641a or the semiconductor portion 643a when viewed in the Z-direction.

### [Manufacturing Method]

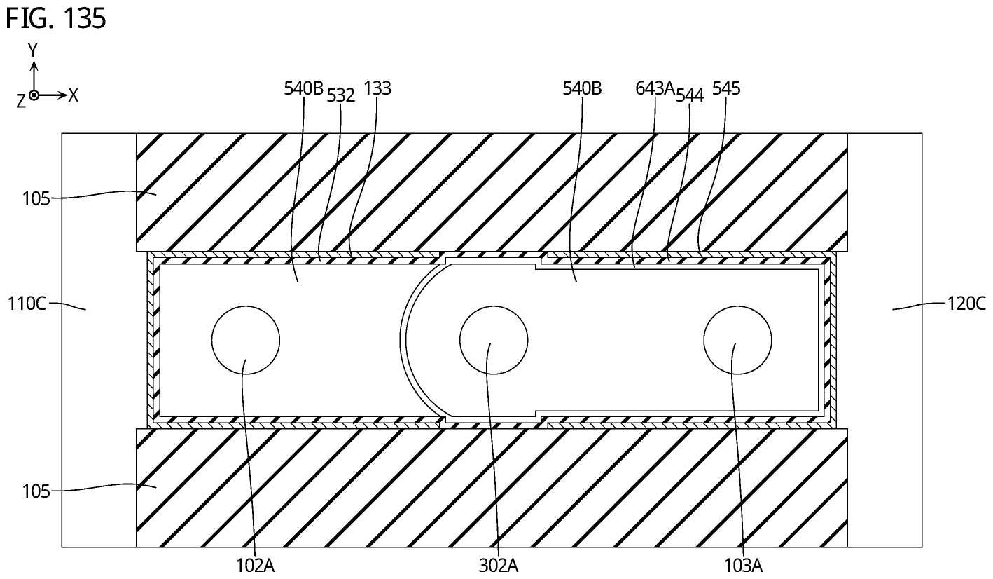

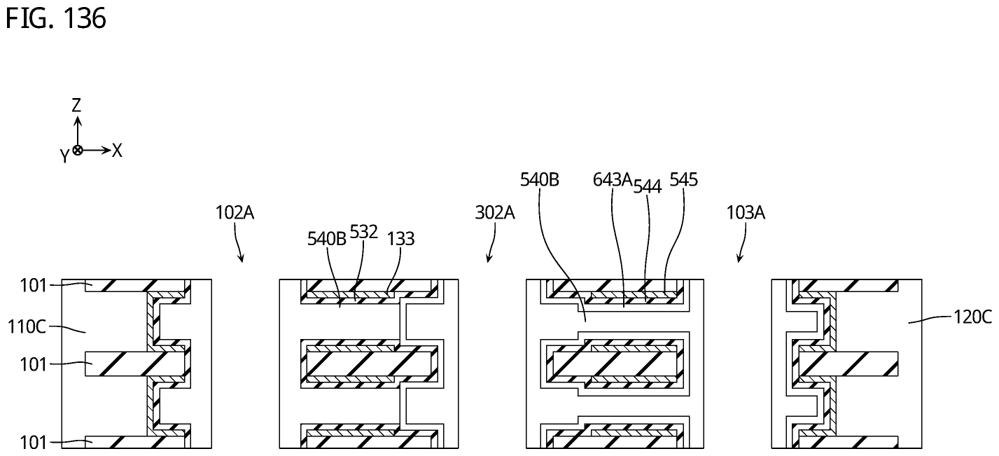

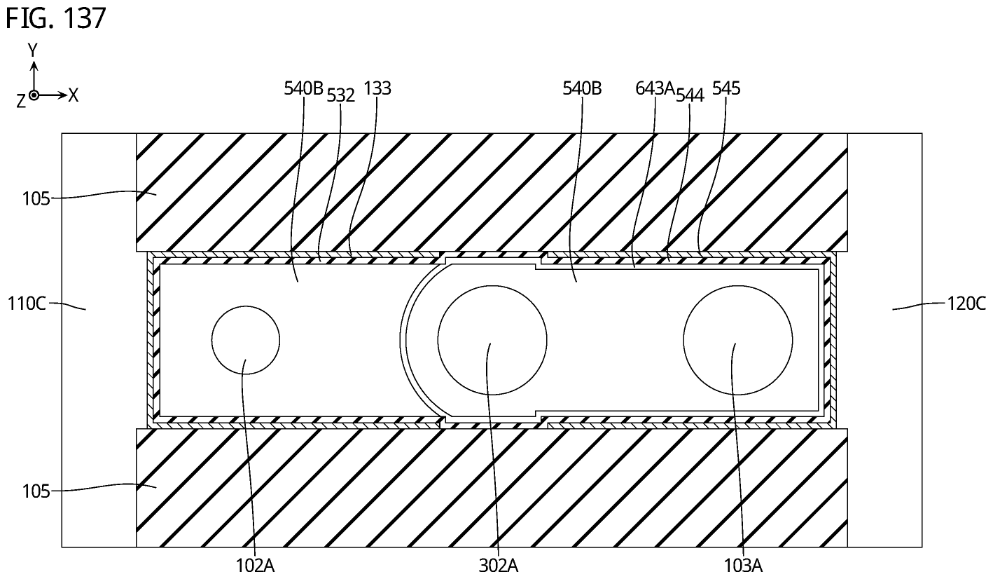

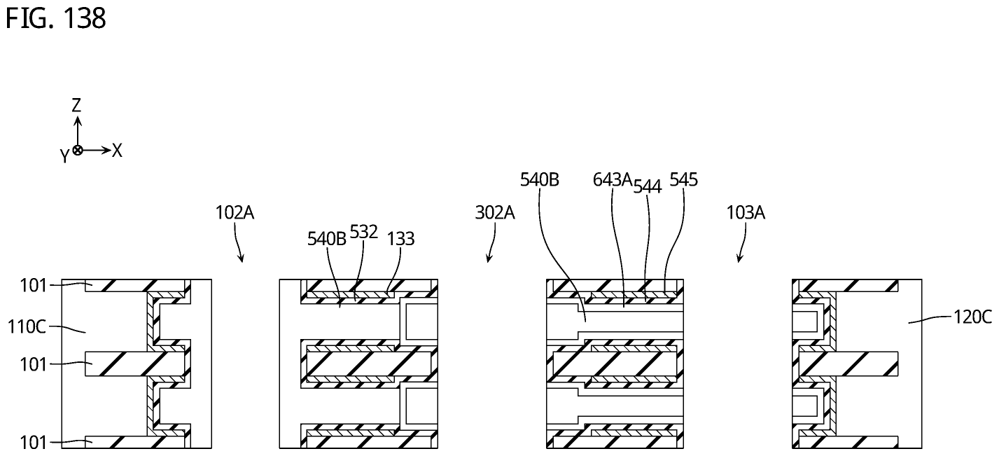

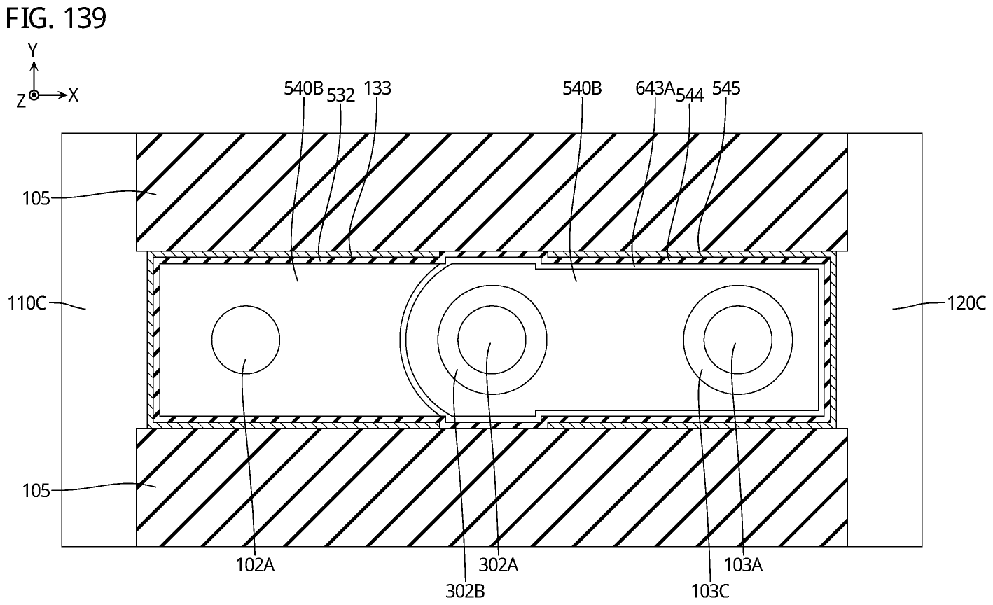

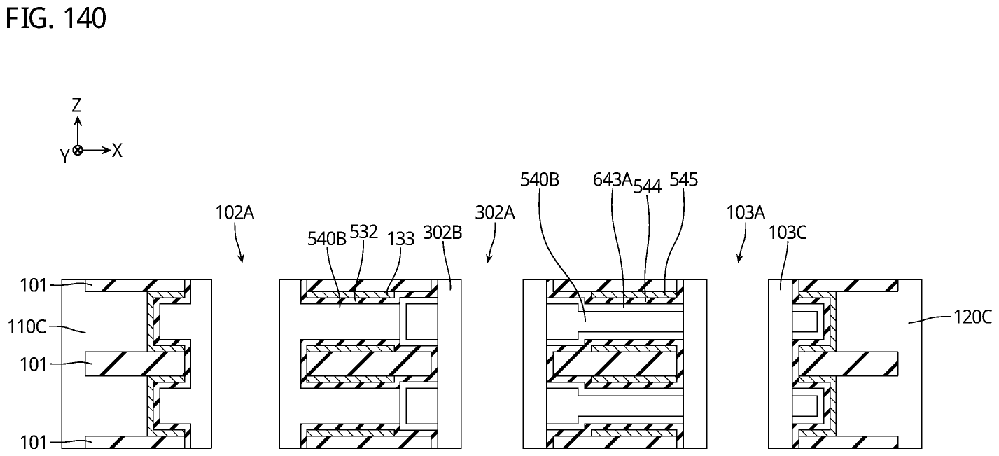

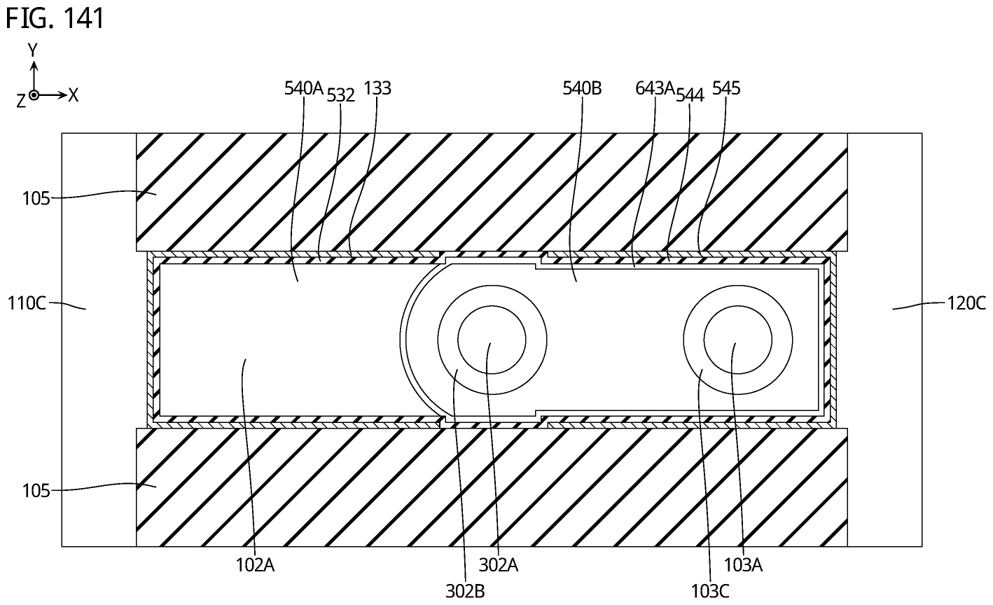

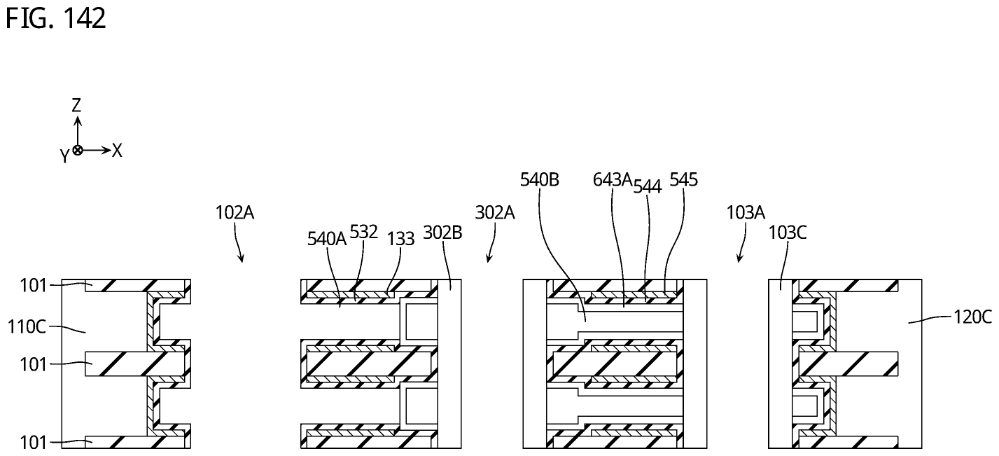

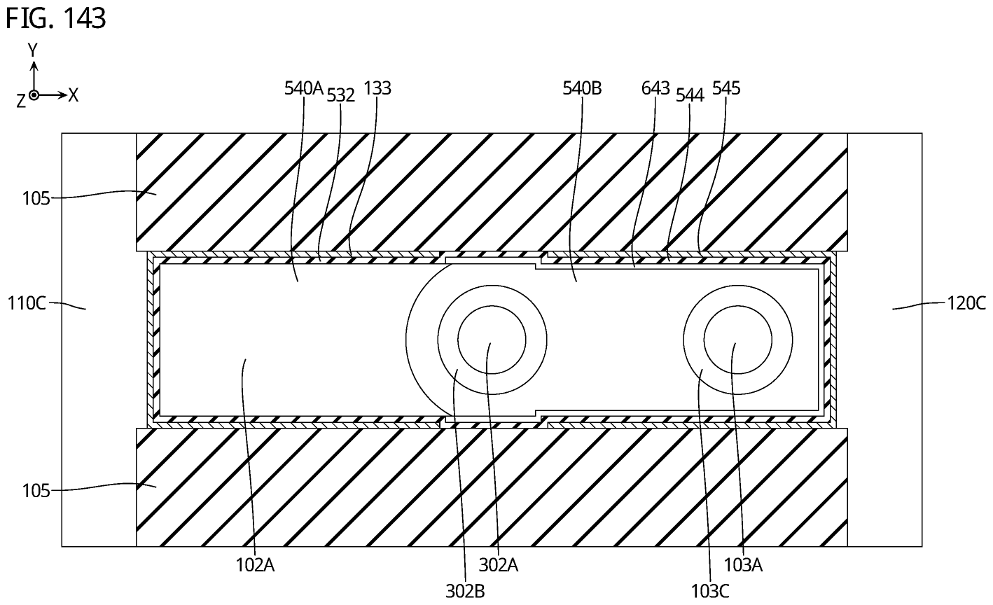

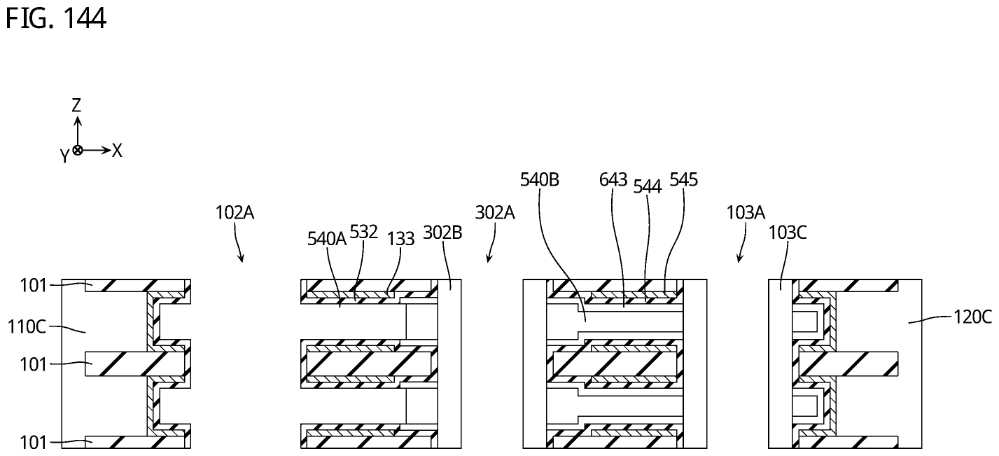

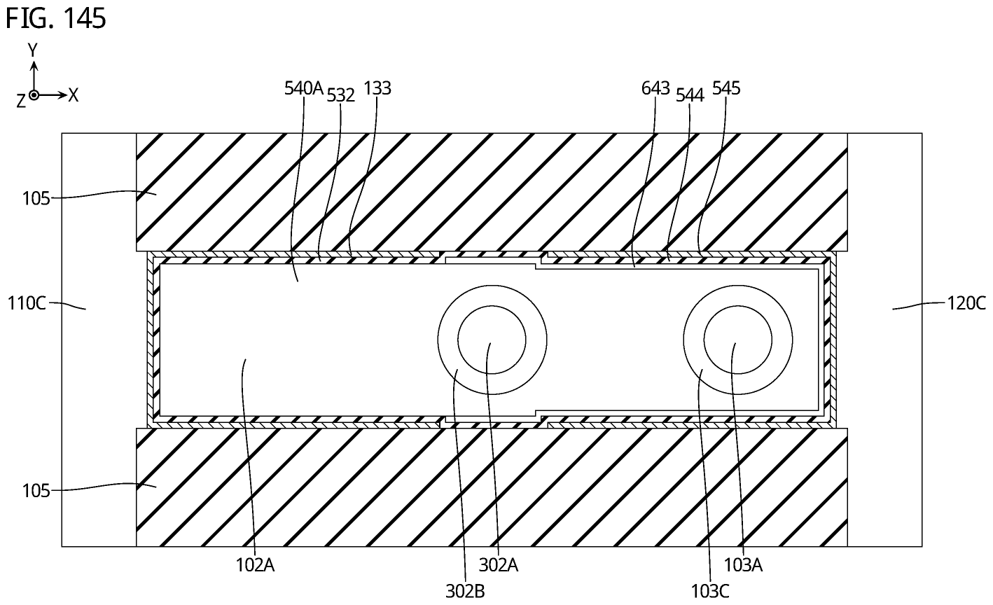

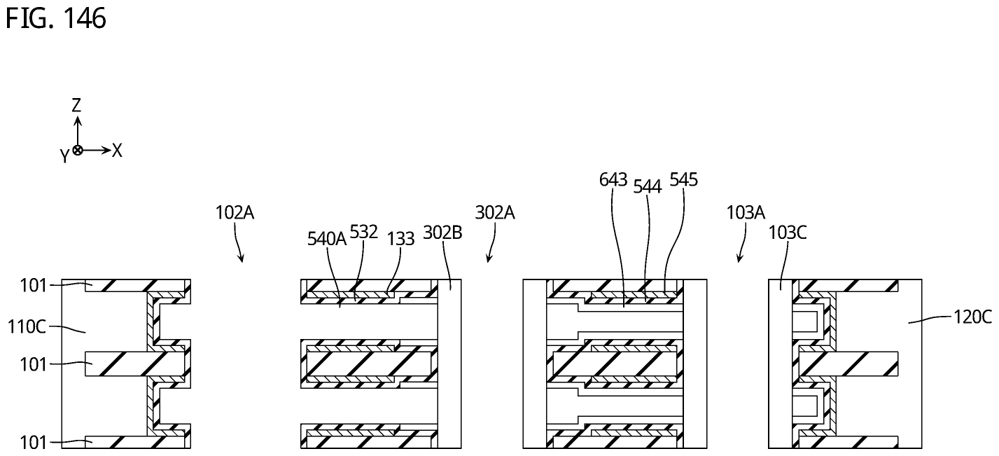

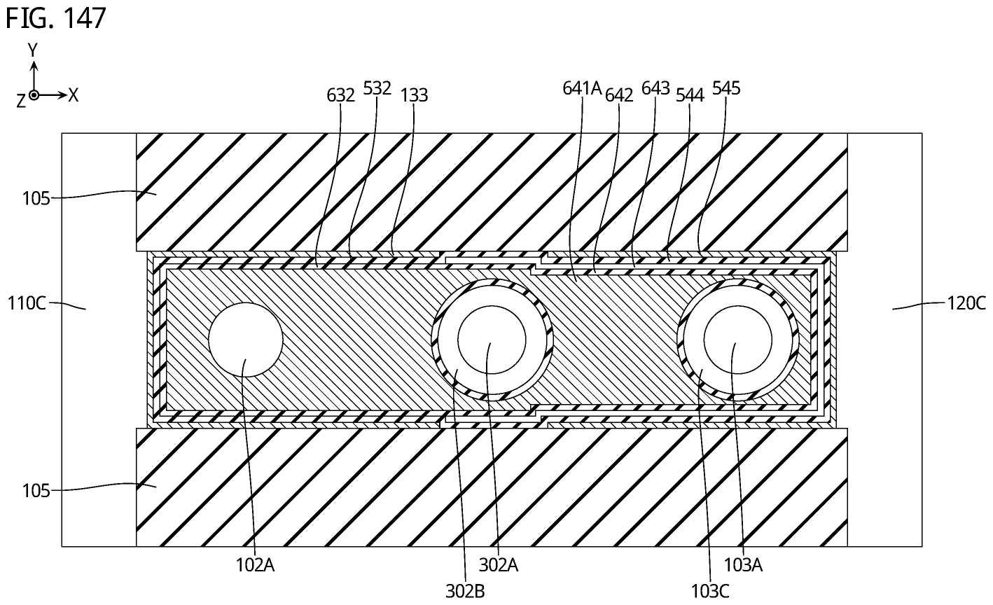

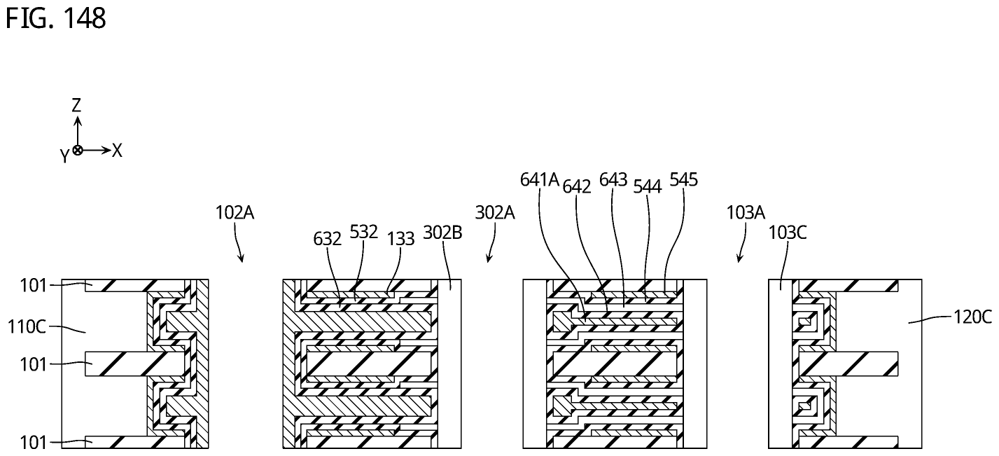

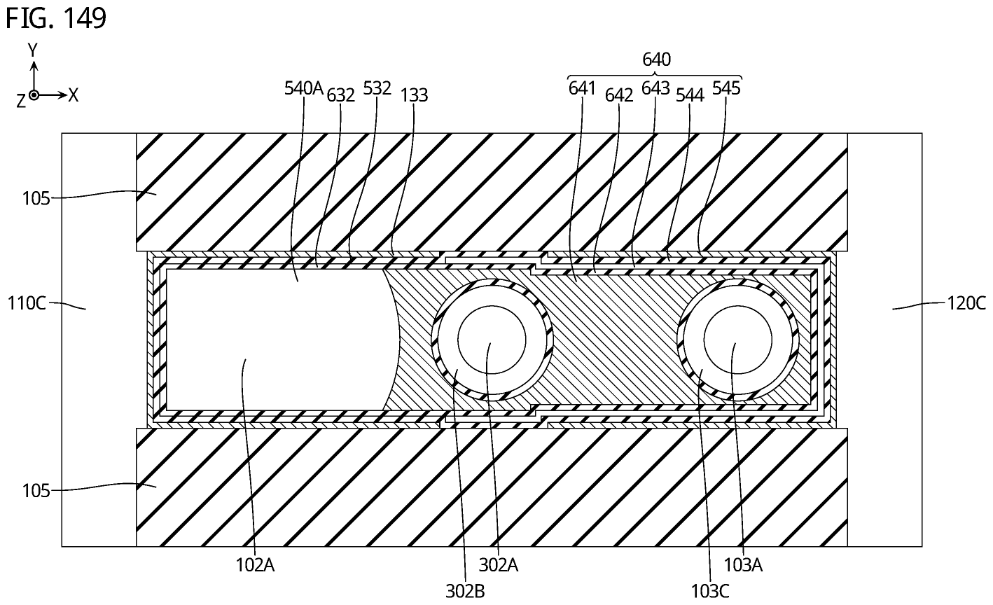

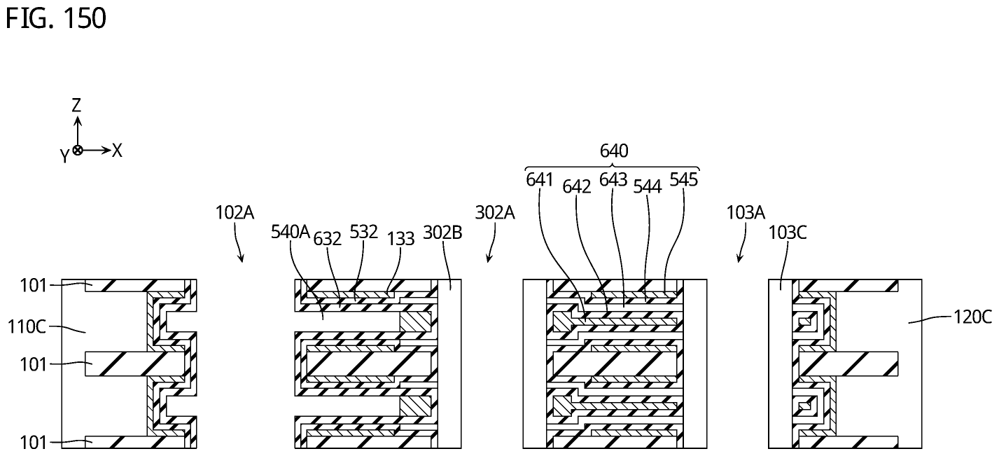

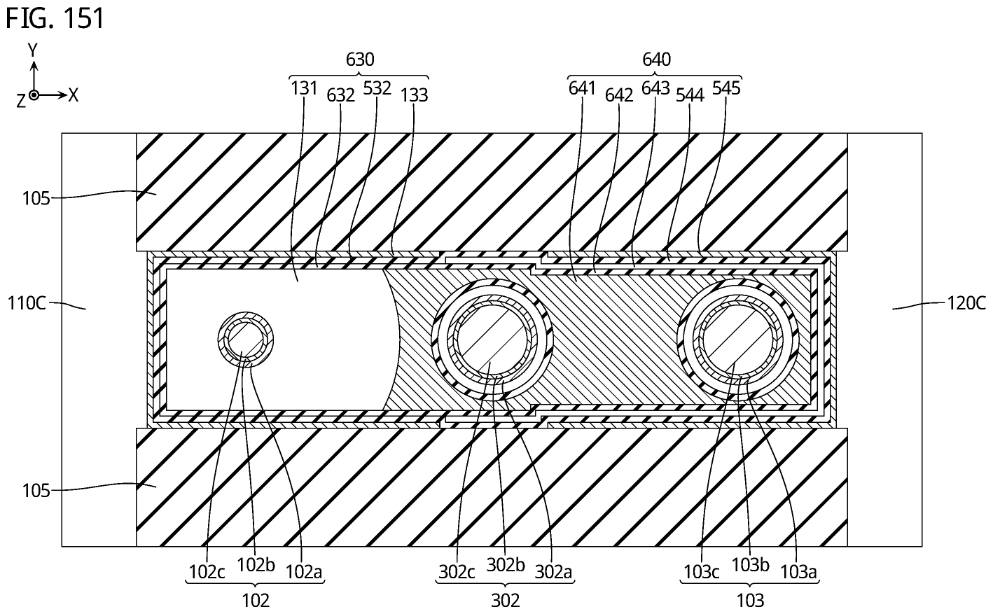

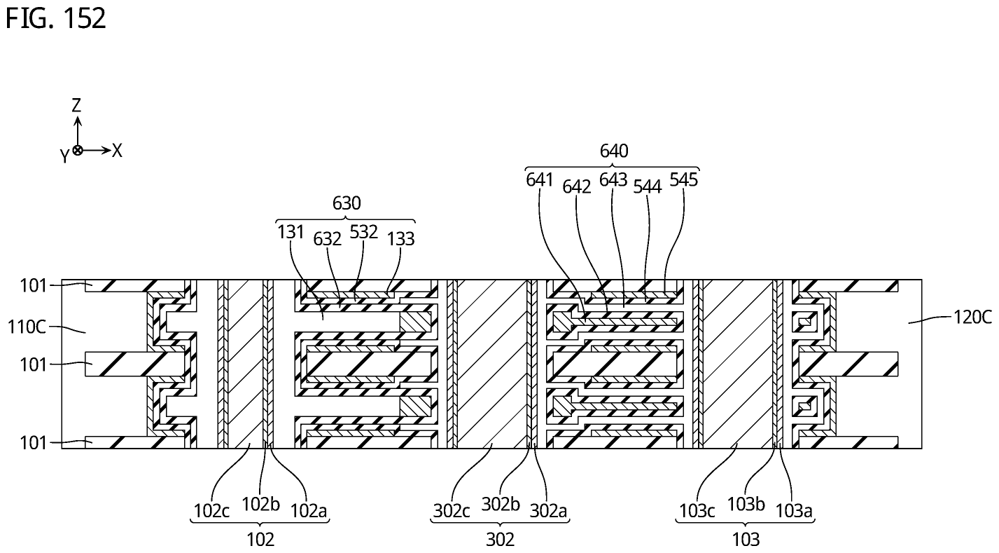

FIG. 135 to FIG. 152 are schematic cross-sectional views for describing a method for manufacturing the semiconductor memory device according to the sixth embodiment. FIG. 135, FIG. 137, FIG. 139, FIG. 141, FIG. 143, FIG. 145, FIG. 147, FIG. 149, and FIG. 151 illustrate cross-sectional surfaces corresponding to FIG. 133. FIG. 136, FIG. 138, FIG. 140, FIG. 142, FIG. 144, FIG. 146, FIG. 148, FIG. 150, and FIG. 152 illustrate cross-sectional surfaces corresponding to FIG. 134.

In the manufacturing method, for example, the processes up to the process described with reference to FIG. 121 and FIG. 122 in the manufacturing process of the semiconductor memory device according to the fifth embodiment are performed.

Next, for example, as illustrated in FIG. 135 and FIG. 136, a semiconductor layer 643A and a sacrifice layer 540B are formed inside the openings 540A, 302A, 103A. This process is performed by, for example, ALD and CVD.

Next, for example, as illustrated in FIG. 137 and FIG. 138, the semiconductor layer 643A is separated in the Z-direction. In this process, for example, a part of the sacrifice layer 540B disposed at inner peripheral surfaces of the openings 302A, 103A is removed. Subsequently, a part of the semiconductor layer 643A disposed at the inner peripheral surfaces of the openings 302A, 103A is removed. This process is performed by, for example, wet etching.

Next, for example, as illustrated in FIG. 139 and FIG. 140, sacrifice layers 302B, 103C are formed inside the openings 302A, 103A. This process is performed by, for example, CVD. Although not illustrated, after the execution of this process, upper portions of the openings 302A, 103A are closed by an insulating layer or the like.

Next, for example, as illustrated in FIG. 141 and FIG. 142, the sacrifice layer 540B is removed via the opening 102A. This process is performed by, for example, wet etching.

Next, for example, as illustrated in FIG. 143 and FIG. 144, the semiconductor layer 643 is formed. In this process, for example, a part of the semiconductor layer 643A covering a side surface of the sacrifice layer 540B on one side (opening 110A side) in the X-direction is removed. This process is performed by, for example, wet etching.

Next, for example, as illustrated in FIG. 145 and FIG. 146, the sacrifice layer 540B is removed. This process is performed by, for example, wet etching.

Next, for example, as illustrated in FIG. 147 and FIG. 148, the insulating portions 642, 632 and a conductive layer 641A are formed inside the openings 540A, 102A. This process is performed by, for example, ALD.

Next, for example, as illustrated in FIG. 149 and FIG. 150, the conductive layer 641 is formed. In this process, for example, a part covering the inner peripheral surface of the opening 102A and a part disposed at a position corresponding to the semiconductor layer 131 of the conductive layer 641A are removed via the opening 102A to separate the conductive layer 641A in the Z-direction. This process is performed by, for example, wet etching.

Next, for example, as illustrated in FIG. 151 and FIG. 152, the semiconductor layer 131 is formed inside the openings 540A, 102A. This process is performed by, for example, CVD.

The sacrifice layers 302B, 103C are removed by a method, such as wet etching, and the via-wirings 102, 302, 103 are formed inside the openings 102A, 302A, 103A by a method, such as ALD and CVD.

Then, for example, the sacrifice layers 110C, 120C are removed. As illustrated in FIG. 133 and FIG. 134, the wirings 110, 120 are formed inside the openings 110B, 120B. This process is performed by, for example, CVD.

### [Modification]

In the example of FIG. 133 and FIG. 134, the semiconductor layer 131 is directly connected to the conductive layer 641. However, the semiconductor memory device according to the sixth embodiment may include the plurality of conductive members 150 and the insulating member 104, for example, as described with reference to FIG. 2 to FIG. 4. Each of the plurality of semiconductor layers 131 arranged in the Z-direction may be connected to the conductive layer 641 via the conductive member 150.

### Seventh Embodiment

Next, a semiconductor memory device according to the seventh embodiment is described. In the following description, the same reference numerals are attached to configurations similar to those in the first embodiment to the sixth embodiment, and the explanation is omitted.

### [Circuit Configuration]

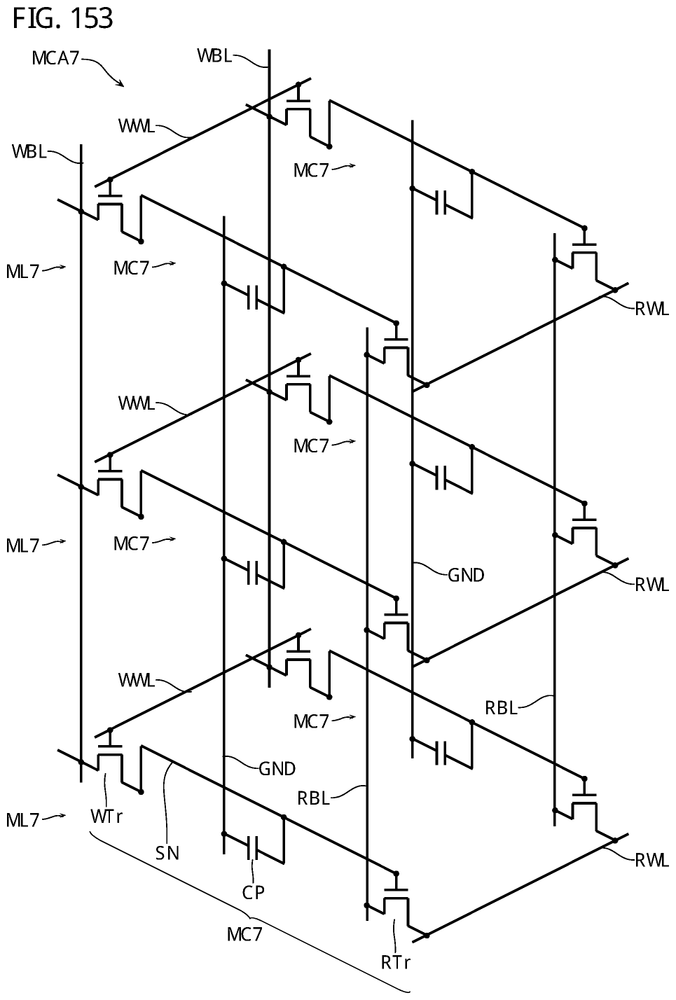

FIG. 153 is a schematic circuit diagram illustrating a configuration of a part of the semiconductor memory device according to the seventh embodiment.

As illustrated in FIG. 153, the semiconductor memory device according to the embodiment includes a memory cell array MCA7. The memory cell array MCA7 includes a plurality of memory layers ML7, a plurality of write bit lines WBL connected to these plurality of memory layers ML7, a plurality of voltage supply lines GND connected to the plurality of memory layers ML7, and a plurality of read bit lines RBL connected to the plurality of memory layers ML7. The voltage supply line GND supplies the ground voltage Vss.

Each of the memory layers ML7 includes a write word line WWL, a read word line RWL, and a plurality of memory cells MC7 connected to these write word line WWL and read word line RWL. Each of the memory cells MC7 includes a write transistor WTr, a sense node SN, a capacitor CP, and a read transistor RTr.

The capacitor CP has one electrode connected to the sense node SN. The capacitor CP has the other electrode connected to the voltage supply line GND.

### [Structure]

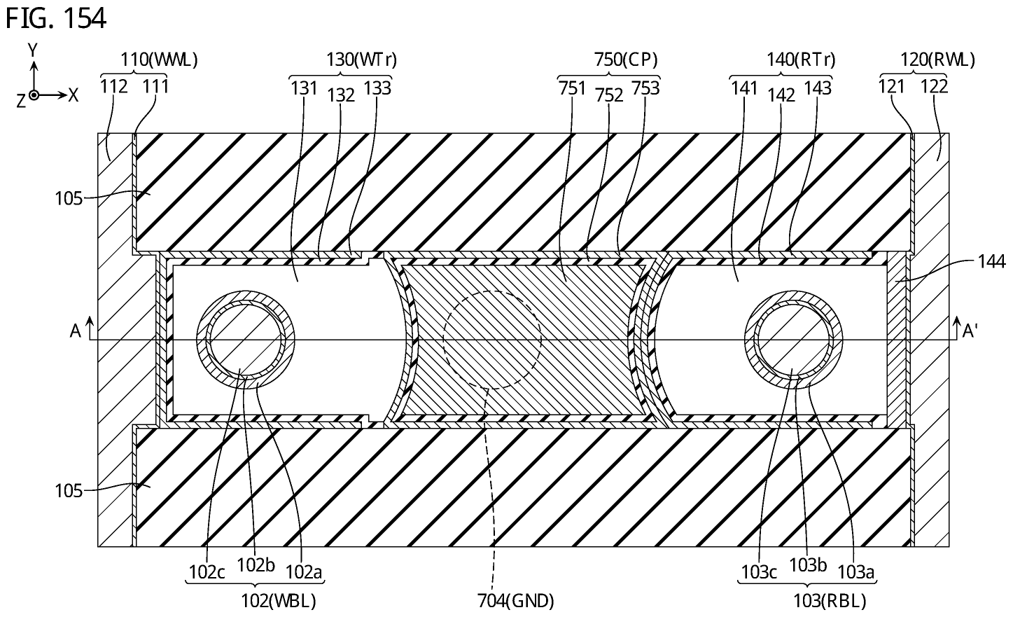

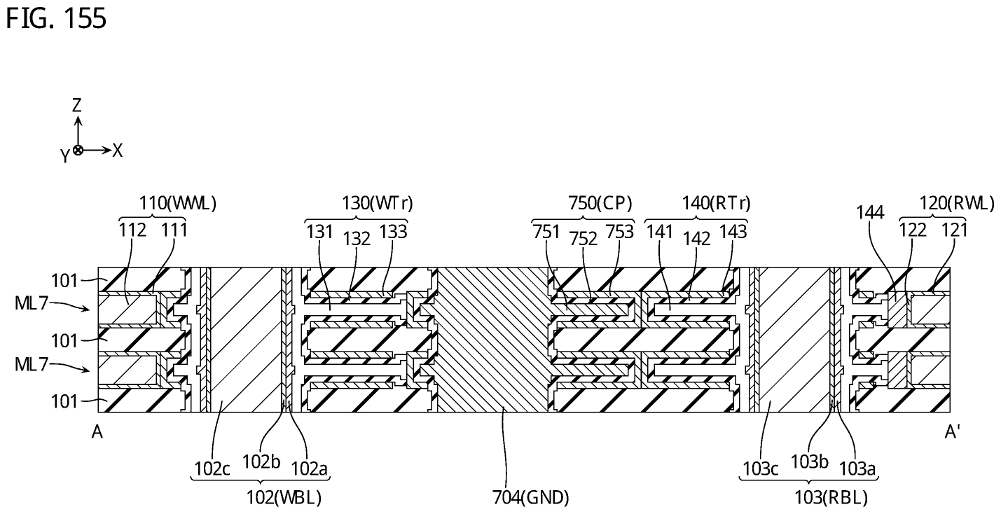

FIG. 154 is a schematic cross-sectional view illustrating a configuration of a part of the semiconductor memory device according to the seventh embodiment. FIG. 155 is a schematic cross-sectional view illustrating a configuration of a part of the semiconductor memory device, and illustrates a configuration of the structure illustrated in FIG. 154 taken along the line A-A′ when viewed in the arrow direction.

The memory cell array MCA7 includes a plurality of memory layers ML7 arranged in the Z-direction. Insulating layers 101 of silicon oxide (SiO₂) or the like are each disposed between the plurality of memory layers ML7.

The memory cell array MCA7 includes via-wirings 102, 704, 103. The via-wiring 704 functions as the voltage supply line GND.

The via-wiring 704 has, for example, an approximately columnar shape extending in the Z-direction as illustrated in FIG. 155. The via-wiring 704 includes, for example, a barrier conductive film of titanium nitride (TiN) or the like and a conductive member of tungsten (W) or the like.

The memory layer ML7 includes wirings 110, 120 arranged in the X-direction and extending in the Y-direction, transistor structures 130, 140 disposed between these wirings 110, 120, and a capacitor structure 750 disposed between these transistor structures 130, 140. The transistor structures 130, 140 are provided at positions corresponding to the via-wirings 102, 103, respectively. The capacitor structure 750 is provided at a position corresponding to the via-wiring 704. In the example of the drawing, the transistor structures 130, 140 and the capacitor structure 750 are arranged in the X-direction.

For example, as illustrated in FIG. 154, the capacitor structure 750 includes a conductive portion 751 connected to an outer peripheral surface of the via-wiring 704 and extending in the X-direction, an insulating layer 752 disposed on an upper surface, a lower surface, both side surfaces in the Y-direction, and both side surfaces in the X-direction of the conductive portion 751, and a conductive layer 753 disposed on an upper surface, a lower surface, both side surfaces in the Y-direction, and both side surfaces in the X-direction of the insulating layer 752.

In an XY cross-sectional surface as exemplified in FIG. 154, side surfaces of the conductive portion 751, the insulating layer 752, and the conductive layer 753 on one side (wiring 110 side) in the X-direction may be formed along a circle with a center position of the via-wiring 102 as its center. Additionally, side surfaces of the conductive portion 751, the insulating layer 752, and the conductive layer 753 on the other side (wiring 120 side) in the X-direction may be formed along a circle with a center position of the via-wiring 103 as its center. Both side surfaces of the conductive portion 751, the insulating layer 752, and the conductive layer 753 in the Y-direction may be formed in a straight line along a side surface of the insulating layer 105.

The conductive portion 751 functions as, for example, one electrode of the capacitor CP (FIG. 153). For example, the conductive portion 751 may contain a barrier conductive film of titanium nitride (TiN) or the like and a conductive member, such as tungsten (W), may contain only titanium nitride (TiN), or may contain another material. A plurality of the conductive portions 751 arranged in the Z-direction are connected to the via-wiring 704 extending in the Z-direction in common. The conductive portion 751 is continuous with the via-wiring 704, and the conductive portion 751 and the via-wiring 704 are directly connected to one another. Each of the plurality of conductive portions 751 and the via-wiring 704 is a part of one conductive member.

The insulating layer 752 functions as, for example, an insulating film between the electrodes of the capacitor CP (FIG. 153). The insulating layer 752 may be, for example, zirconia (Zro₂), alumina (Al₂O₃), or another insulating metal oxide. The insulating layer 752 may be a stacked film of a plurality of insulating metal oxides (for example, a stacked film of zirconia and alumina).

The conductive layer 753 functions as, for example, the other electrode of the capacitor CP (FIG. 153). The conductive layer 753 may contain, for example, a conductive oxide, such as indium tin oxide (ITO). The conductive layer 753 is opposed to the upper surface, the lower surface, both side surfaces in the Y-direction, and both side surfaces in the X-direction of the conductive portion 751 via the insulating layer 752.

### [Modification]

In the seventh embodiment, an example in which the capacitor CP is connected to the sense node SN in the circuit configuration as described with reference to FIG. 1 is described. However, for example, in the circuit configuration as described with reference to FIG. 88, FIG. 104, or FIG. 132, the capacitor CP can be connected to the sense node SN.

For example, in the structure as described with reference to FIG. 89 and FIG. 90, a plurality of the capacitor structures 750 and the via-wiring 704 can be provided instead of the plurality of conductive members 150 and the insulating member 104. For example, in the structure as described with reference to FIG. 91 and FIG. 92, a plurality of the capacitor structures 750 and the via-wiring 704 can be provided between the semiconductor layer 131 and the conductive layer 243. Similarly, in the structure as described with reference to FIG. 105 and FIG. 106, a plurality of the capacitor structures 750 and the via-wiring 704 can be provided between the semiconductor layer 131 and the conductive layer 543. Similarly, in the structure as described with reference to FIG. 133 and FIG. 134, a plurality of the capacitor structures 750 and the via-wiring 704 can be provided between the semiconductor layer 131 and the conductive layer 641.

### Other Embodiments

The semiconductor memory devices according to the first embodiment to the seventh embodiment are described above. However, the semiconductor memory devices according to these embodiments are merely examples, and the specific configuration and the like can be adjusted as necessary. For example, the semiconductor memory devices according to the third embodiment to the sixth embodiment may include the voltage supply line GND instead of the voltage supply line VDD.

In the semiconductor memory devices according to the first embodiment to the seventh embodiment, respective configurations (for example, the transistor structures 130, 140) in the memory cells MC, MC3, MC5, MC6, MC7 (hereinafter referred to as a “memory cell MC or the like”) are arranged in a row in the X-direction, and the wirings 110, 120 and the like extend in the Y-direction. However, for example, the respective configurations in the memory cell MC or the like may be arranged in a row in a direction in which the wirings 110, 120 and the like extend, for example, the Y-direction. The respective configurations in the memory cell MC or the like may be arranged in two rows in the X-direction or the Y-direction, or may be arranged in another aspect.

The methods for manufacturing the semiconductor memory device according to the first embodiment to the seventh embodiment also can be adjusted as necessary. For example, the order of any two of the above-described processes may be changed, or any two of the above-described processes may be simultaneously performed.

### [Others]

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a substrate;
a plurality of first wirings arranged in a first direction intersecting with a surface of the substrate and extending in a second direction intersecting with the first direction;
a plurality of second wirings arranged in the first direction, extending in the second direction, and arranged with the plurality of first wirings in a third direction intersecting with the first direction and the second direction;
a first via-wiring and a second via-wiring disposed between the plurality of first wirings and the plurality of second wirings and extending in the first direction;
a plurality of first semiconductor layers arranged in the first direction and electrically connected to the first via-wiring;
a plurality of second semiconductor layers arranged in the first direction, electrically connected to the second via-wiring, and electrically connected to the plurality of second wirings respectively;
a plurality of first gate electrodes arranged in the first direction, electrically connected to the plurality of first wirings respectively, and opposed to the plurality of first semiconductor layers; and
a plurality of second gate electrodes arranged in the first direction, electrically connected to the plurality of first semiconductor layers respectively, and opposed to the plurality of second semiconductor layers.

2. The semiconductor memory device according to claim 1, wherein
the plurality of first semiconductor layers surround an outer peripheral surface of the first via-wiring, and
the plurality of second semiconductor layers surround an outer peripheral surface of the second via-wiring.

3. The semiconductor memory device according to claim 1, wherein
the plurality of first gate electrodes are opposed to surfaces of the plurality of first semiconductor layers on one side and the other side in the first direction; and
the plurality of second gate electrodes are opposed to surfaces of the plurality of second semiconductor layers on one side and the other side in the first direction.

4. The semiconductor memory device according to claim 1, wherein
the plurality of first wirings are disposed at positions not overlapping with the plurality of first gate electrodes when viewed in the first direction, and
the plurality of second wirings are disposed at positions not overlapping with the plurality of second gate electrodes when viewed in the first direction.

5. The semiconductor memory device according to claim 1, comprising
a plurality of conductive members arranged in the first direction, wherein
the plurality of second gate electrodes are electrically connected to the plurality of first semiconductor layers via the plurality of conductive members respectively.

6. The semiconductor memory device according to claim 1, wherein
the plurality of second gate electrodes are directly connected to the plurality of first semiconductor layers respectively.

7. The semiconductor memory device according to claim 1, comprising:
a voltage supply line disposed between the plurality of first wirings and the plurality of second wirings and extending in the first direction;
a plurality of first electrodes arranged in the first direction, surrounding an outer peripheral surface of the voltage supply line, and electrically connected to the voltage supply line; and
a plurality of second electrodes arranged in the first direction, electrically connected to the plurality of first semiconductor layers respectively and the respective plurality of second gate electrodes respectively, and opposed to the plurality of first electrodes respectively, wherein
the plurality of second electrodes are opposed to surfaces of the plurality of first electrodes on one side and the other side in the first direction.

8. A semiconductor memory device comprising:
a substrate;
a plurality of first wirings arranged in a first direction intersecting with a surface of the substrate and extending in a second direction intersecting with the first direction;
a plurality of second wirings arranged in the first direction, extending in the second direction, and arranged with the plurality of first wirings in a third direction intersecting with the first direction and the second direction;
a first via-wiring, a second via-wiring, and a third via-wiring disposed between the plurality of first wirings and the plurality of second wirings and extending in the first direction;
a plurality of first semiconductor portions arranged in the first direction and electrically connected to the first via-wiring;
a plurality of second semiconductor portions arranged in the first direction and electrically connected to the second via-wiring;
a plurality of third semiconductor portions arranged in the first direction, electrically connected to the third via-wiring, and electrically connected to the plurality of second semiconductor portions respectively;
a plurality of first gate electrodes arranged in the first direction, electrically connected to the plurality of first wirings respectively, and opposed to the plurality of first semiconductor portions;
a plurality of second gate electrodes arranged in the first direction, electrically connected to the plurality of second wirings respectively, and opposed to the plurality of second semiconductor portions; and
a plurality of third gate electrodes arranged in the first direction, electrically connected to the plurality of first semiconductor portions respectively, and opposed to the plurality of third semiconductor portions.

9. The semiconductor memory device according to claim 8, wherein
the plurality of first semiconductor portions surround an outer peripheral surface of the first via-wiring,
the plurality of second semiconductor portions surround an outer peripheral surface of the second via-wiring, and
the plurality third semiconductor portions surround an outer peripheral surface of the third via-wiring.

10. The semiconductor memory device according to claim 8, wherein
the plurality of first gate electrodes are opposed to surfaces of the plurality of first semiconductor portions on one side and the other side in the first direction,
the plurality of second gate electrodes are opposed to surfaces of the plurality of second semiconductor portions on one side and the other side in the first direction, and
the plurality of third gate electrodes are opposed to surfaces of the plurality of third semiconductor portions on one side and the other side in the first direction.

11. The semiconductor memory device according to claim 8, wherein
the plurality of first wirings are disposed at positions not overlapping with the plurality of first gate electrodes when viewed in the first direction, and
the plurality of second wirings are disposed at positions not overlapping with the plurality of second gate electrodes when viewed in the first direction.

12. The semiconductor memory device according to claim 8, comprising
a plurality of first conductive members arranged in the first direction, wherein
the plurality of third gate electrodes are electrically connected to the plurality of first semiconductor portions via the plurality of first conductive members respectively.

13. The semiconductor memory device according to claim 8, wherein
the plurality of third gate electrodes are directly connected to the plurality of first semiconductor portions respectively.

14. The semiconductor memory device according to claim 8, comprising
a plurality of second conductive members arranged in the first direction, wherein
the plurality of third semiconductor portions are electrically connected to the plurality of second semiconductor portions via the plurality of second conductive members respectively.

15. The semiconductor memory device according to claim 8, wherein
the plurality of third semiconductor portions are continuous with the plurality of second semiconductor portions respectively.

16. The semiconductor memory device according to claim 8, wherein
the plurality of second gate electrodes are disposed at positions overlapping with the plurality of second semiconductor portions and not overlapping with the plurality of third semiconductor portions when viewed in the first direction, and
the plurality of third gate electrodes are disposed at positions overlapping with the plurality of third semiconductor portions and not overlapping with the plurality of second semiconductor portions when viewed in the first direction.

17. The semiconductor memory device according to claim 8, wherein
the plurality of second gate electrodes are disposed at positions overlapping with the plurality of second semiconductor portions when viewed in the first direction, and
the plurality of third gate electrodes are disposed at positions overlapping with both of the plurality of second semiconductor portions and the plurality of third semiconductor portions when viewed in the first direction.

18. The semiconductor memory device according to claim 17, wherein
the plurality of third gate electrodes are opposed to surfaces of the plurality of second semiconductor portions and the plurality of third semiconductor portions on one side and the other side in the first direction.

19. The semiconductor memory device according to claim 17, wherein
each of the plurality of second semiconductor portions and the plurality of third semiconductor portions are opposed to surfaces of the plurality of third gate electrodes on one side and the other side in the first direction.
